(19) United States
(12) Patent Application Publication
(10) Pub. No.: US 2026/0333661 A1
(43) Pub. Date: Oct. 22, 2026

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Shunpei YAMAZAKI, Setagaya, Tokyo (JP)

(21) Appl. No.: 19/122,803

(22) PCT Filed: Oct. 27, 2023
(86) PCT No.: PCT/IB2023/060833

§ 371 Date: Apr. 21, 2025

(30) Foreign Application Priority Data
Nov. 3, 2022 (JP) 2022-176808

(51) Int. Cl. H10B 12/00; H10D 30/67; H10D 86/60; H10H 29/32; H10K 59/121

(52) U.S. Cl. CPC H10B 12/00; H10D 30/6728; H10D 30/6731; H10D 30/6735; H10B 12/01; H10D 30/6706; H10D 86/60; H10H 29/32; H10K 59/1213

(57) ABSTRACT

A semiconductor device that can be reduced in size or highly integrated is provided. The semiconductor device includes first to third transistors and first to fourth insulating layers. The first transistor includes first to third conductive layers, a fifth insulating layer, and a first semiconductor layer. The first insulating layer, the third conductive layer, and the second insulating layer over the first conductive layer have a first opening. The fifth insulating layer is in contact with a sidewall of the first opening. The first semiconductor layer is in contact with a bottom portion of the first opening and a side surface of the fifth insulating layer. The second conductive layer is over and in contact with the first semiconductor layer. The second (third) transistor includes second, fourth, and fifth (sixth to eighth) conductive layers, a sixth (seventh) insulating layer, and a second (third) semiconductor layer. The third (fourth) insulating layer and the fourth (seventh) conductive layer over the second (sixth) conductive layer have a second (third) opening. The second (third) semiconductor layer is in contact with a bottom portion and a sidewall of the second (third) opening. The sixth (seventh) insulating layer is over and in contact with the second (third) semiconductor layer. The fifth (eighth) conductive layer is over and in contact with the sixth (seventh) insulating layer.

### TECHNICAL FIELD

One embodiment of the present invention relates to a semiconductor device and a method for manufacturing a semiconductor device. Another embodiment of the present invention relates to a memory device and a method for manufacturing a memory device. Another embodiment of the present invention relates to a transistor and a method for manufacturing a transistor. Another embodiment of the present invention relates to a capacitor and a method for manufacturing a capacitor. Another embodiment of the present invention relates to an electronic appliance.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), an input/output device (e.g., a touch panel), an electronic appliance including any of them, a method for driving any of them, and a method for manufacturing any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic appliance themselves are semiconductor devices and each of them includes a semiconductor device in some cases.

### BACKGROUND ART

In recent years, development of semiconductor devices has been proceeding, and large scale integration circuits (LSI), for example, are used in the semiconductor devices. For example, central processing units (CPUs), memories, and the like are used in the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and a display apparatus. A silicon-based semiconductor material is widely known as a semiconductor thin film usable for the transistor and further, an oxide semiconductor has been attracting attention as another material.

It is known that a transistor including an oxide semiconductor has an extremely low leakage current in a non-conducting state. For example, Patent Document 1 discloses a low-power-consumption CPU utilizing a feature of a low leakage current of the transistor including an oxide semiconductor. For another example, Patent Document 2 discloses a memory device and the like that can retain stored contents for a long time by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulating layer therebetween.

### REFERENCES

### Patent Documents

[Patent Document 1] Japanese Published Patent Application No. 2012-257187

[Patent Document 2] Japanese Published Patent Application No. 2011-151383

[Patent Document 3] PCT International Publication No. 2021/053473

[Patent Document 4] Japanese Published Patent Application No. 2013-211537

### Non-Patent Document

[Non-Patent Document 1]

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device, a memory device, or a transistor that can be reduced in size or highly integrated. Another object of one embodiment of the present invention is to provide a semiconductor device, a memory device, or a transistor that has high reliability. Another object of one embodiment of the present invention is to provide a semiconductor device or a memory device that has high reading accuracy. Another object of one embodiment of the present invention is to provide a transistor with a high on-state current. Another object of one embodiment of the present invention is to provide a transistor with favorable electrical characteristics. Another object of one embodiment of the present invention is to provide an inexpensive semiconductor device or an inexpensive memory device. Another object of one embodiment of the present invention is to provide a semiconductor device or a memory device that has low power consumption. Another object of one embodiment of the present invention is to provide a semiconductor device or a memory device that has high operating speed. Another object of one embodiment of the present invention is to provide a novel semiconductor device, a novel memory device, or a novel transistor.

Another object of one embodiment of the present invention is to provide a method for manufacturing a semiconductor device, a memory device, or a transistor that can be reduced in size or highly integrated. Another object of one embodiment of the present invention is to provide a method for manufacturing a semiconductor device, a memory device, or a transistor that has high reliability. Another object of one embodiment of the present invention is to provide a method for manufacturing a semiconductor device or a memory device that has high reading accuracy. Another object of one embodiment of the present invention is to provide a method for manufacturing a transistor with a high on-state current. Another object of one embodiment of the present invention is to provide a method for manufacturing a transistor with favorable electrical characteristics. Another object of one embodiment of the present invention is to provide a method for manufacturing a semiconductor device or a memory device with high yield. Another object of one embodiment of the present invention is to provide a method for manufacturing a semiconductor device or a memory device that has low power consumption. Another object of one embodiment of the present invention is to provide a method for manufacturing a semiconductor device or a memory device that has high operating speed. Another object of one embodiment of the present invention is to provide a method for manufacturing a novel semiconductor device, a novel memory device, or a novel transistor.

Note that the description of these objects does not preclude the existence of other objects. One embodiment of the present invention does not need to achieve all of these objects. Other objects can be derived from the description of the specification, the drawings, and the claims.

Means for Solving the Problems One embodiment of the present invention is a semiconductor device including a first transistor, a second transistor, a third transistor, a first wiring, a second wiring, a third wiring, a fourth wiring, and a fifth wiring. In each of the first transistor, the second transistor, and the third transistor, a source and a drain are provided at different heights from a substrate surface. The second transistor is provided over the first transistor to overlap with the first transistor. The third transistor is provided over the second transistor to overlap with the second transistor. A gate of the first transistor is electrically connected to the first wiring. One of the source and the drain of the first transistor is electrically connected to a gate of the second transistor. The other of the source and the drain of the first transistor is electrically connected to the second wiring. One of the source and the drain of the second transistor is electrically connected to one of the source and the drain of the third transistor. The other of the source and the drain of the second transistor is electrically connected to the third wiring. A gate of the third transistor is electrically connected to the fourth wiring. The other of the source and the drain of the third transistor is electrically connected to the fifth wiring.

In the above, at least one of the first transistor, the second transistor, and the third transistor preferably includes a metal oxide.

In the above, it is preferable that a node electrically connecting the one of the source and the drain of the first transistor and the gate of the second transistor be included; the first transistor have a function of writing, to the node, data corresponding to a potential supplied from the second wiring when a first potential is supplied from the first wiring, and have a function of retaining the data at the node when a second potential is supplied from the first wiring; the second transistor and the third transistor each have a function of reading the data retained at the node when a fifth potential is supplied to the fourth wiring while a third potential is supplied to the third wiring and a fourth potential is supplied to the fifth wiring; the first potential be a potential at which the first transistor is turned on; the second potential be a potential at which the first transistor is turned off; the fourth potential be higher than the third potential; and the fifth potential be a potential at which the third transistor is turned on.

Another embodiment of the present invention is a semiconductor device including a first transistor, a second transistor, a third transistor, a first wiring, a second wiring, a third wiring, a fourth wiring, and a fifth wiring. In each of the first transistor, the second transistor, and the third transistor, a source and a drain are provided at different heights from a substrate surface. The second transistor is provided over the first transistor to overlap with the first transistor. The third transistor is provided over the second transistor to overlap with the second transistor. In the first transistor, a gate is provided to surround a semiconductor layer in a plan view. In the second transistor, a semiconductor layer is provided to surround a gate in the plan view. In the third transistor, a semiconductor layer is provided to surround a gate in the plan view. The gate of the first transistor is electrically connected to the first wiring. One of the source and the drain of the first transistor is electrically connected to the gate of the second transistor. The other of the source and the drain of the first transistor is electrically connected to the second wiring. One of the source and the drain of the second transistor is electrically connected to one of the source and the drain of the third transistor. The other of the source and the drain of the second transistor is electrically connected to the third wiring. The gate of the third transistor is electrically connected to the fourth wiring. The other of the source and the drain of the third transistor is electrically connected to the fifth wiring.

In the above, the semiconductor layer in at least one of the first transistor, the second transistor, and the third transistor preferably includes a metal oxide.

In the above, it is preferable that a node electrically connecting the one of the source and the drain of the first transistor and the gate of the second transistor be included; the first transistor have a function of writing, to the node, data corresponding to a potential supplied from the second wiring when a first potential is supplied from the first wiring, and have a function of retaining the data at the node when a second potential is supplied from the first wiring; the second transistor and the third transistor each have a function of reading the data retained at the node when a fifth potential is supplied to the fourth wiring while a third potential is supplied to the third wiring and a fourth potential is supplied to the fifth wiring; the first potential be a potential at which the first transistor is turned on; the second potential be a potential at which the first transistor is turned off; the fourth potential be higher than the third potential; and the fifth potential be a potential at which the third transistor is turned on.

Another embodiment of the present invention is a semiconductor device including a first transistor, a second transistor, a third transistor, a first insulating layer, a second insulating layer, a third insulating layer, and a fourth insulating layer. The first transistor, the second transistor, and the third transistor are stacked in this order. The first transistor includes a first conductive layer, a second conductive layer, a third conductive layer, a fifth insulating layer, and a first semiconductor layer. The first insulating layer, the third conductive layer, and the second insulating layer are stacked in this order over the first conductive layer. A first opening reaching the first conductive layer is provided in the first insulating layer, the third conductive layer, and the second insulating layer. The fifth insulating layer is provided in contact with a sidewall of the first opening. The first semiconductor layer is provided in contact with a top surface of the first conductive layer in the first opening, a side surface of the fifth insulating layer in the first opening, and a top surface of the second insulating layer. The second conductive layer is provided in contact with a top surface of the first semiconductor layer to include a region overlapping with the first conductive layer. The second transistor includes the second conductive layer, a fourth conductive layer, a fifth conductive layer, a sixth insulating layer, and a second semiconductor layer. The third insulating layer and the fourth conductive layer are stacked in this order over the second conductive layer. A second opening reaching the second conductive layer is provided in the third insulating layer and the fourth conductive layer. The second semiconductor layer is provided in contact with a top surface of the second conductive layer in the second opening, a side surface of the third insulating layer in the second opening, a side surface of the fourth conductive layer in the second opening, and a top surface of the fourth conductive layer. The sixth insulating layer is provided in contact with a top surface of the second semiconductor layer, a side surface of the second semiconductor layer, the top surface of the fourth conductive layer, a side surface of the fourth conductive layer, and a top surface of the third insulating layer. The fifth conductive layer is provided over and in contact with the sixth insulating layer to fill the second opening. The third transistor includes a sixth conductive layer, a seventh conductive layer, an eighth conductive layer, a seventh insulating layer, and a third semiconductor layer. The sixth conductive layer is provided in contact with a top surface of the fifth conductive layer. The fourth insulating layer and the seventh conductive layer are stacked in this order over the sixth conductive layer. A third opening reaching the sixth conductive layer is provided in the fourth insulating layer and the seventh conductive layer. The third semiconductor layer is provided in contact with a top surface of the sixth conductive layer in the third opening, a side surface of the fourth insulating layer in the third opening, a side surface of the seventh conductive layer in the third opening, and a top surface of the seventh conductive layer. The seventh insulating layer is provided in contact with a top surface of the third semiconductor layer, a side surface of the third semiconductor layer, the top surface of the seventh conductive layer, a side surface of the seventh conductive layer, and a top surface of the fourth insulating layer. The eighth conductive layer is provided over and in contact with the seventh insulating layer to fill the third opening.

In the above, at least one of the first semiconductor layer, the second semiconductor layer, and the third semiconductor layer preferably includes a metal oxide.

In the above, it is preferable that the second conductive layer include a ninth conductive layer and a tenth conductive layer, the ninth conductive layer be provided in contact with the top surface of the first semiconductor layer to include a region overlapping with the first conductive layer, the tenth conductive layer be provided in contact with a top surface of the ninth conductive layer to include a region overlapping with the first conductive layer, and the second semiconductor layer be provided in contact with a top surface of the tenth conductive layer.

In the above, it is preferable that the second conductive layer include a ninth conductive layer, a tenth conductive layer, and an eleventh conductive layer; the ninth conductive layer be provided in contact with the top surface of the first semiconductor layer to include a region overlapping with the first conductive layer; the tenth conductive layer be provided in contact with a top surface of the ninth conductive layer; the eleventh conductive layer be provided in contact with a top surface of the tenth conductive layer to include a region overlapping with the first conductive layer; and the second semiconductor layer be provided in contact with a top surface of the eleventh conductive layer.

In the above, it is preferable that a capacitor be included between the first transistor and the second transistor; the first transistor, the second transistor, the capacitor, and the third transistor be stacked in this order; the capacitor include a ninth conductive layer, a tenth conductive layer, and an eighth insulating layer; the eighth insulating layer include a region in contact with a side surface of the ninth conductive layer; the tenth conductive layer cover at least part of the side surface of the ninth conductive layer with the eighth insulating layer therebetween; the ninth conductive layer be provided in contact with the top surface of the fifth conductive layer; and the sixth conductive layer be provided in contact with a top surface of the ninth conductive layer.

Another embodiment of the present invention is a semiconductor device including a first transistor, a second transistor, a third transistor, a first insulating layer, a second insulating layer, a third insulating layer, and a fourth insulating layer. The first transistor, the second transistor, and the third transistor are stacked in this order. The first transistor includes a first conductive layer, a second conductive layer, a third conductive layer, a fifth insulating layer, and a first semiconductor layer. The first insulating layer, the third conductive layer, and the second insulating layer are stacked in this order over the first conductive layer. A first opening reaching the first conductive layer is provided in the first insulating layer, the third conductive layer, and the second insulating layer. The fifth insulating layer is provided in contact with a sidewall of the first opening. The first semiconductor layer is provided in contact with a top surface of the first conductive layer in the first opening, a side surface of the fifth insulating layer in the first opening, and a top surface of the second insulating layer. The second conductive layer is provided in contact with a top surface of the first semiconductor layer to include a region overlapping with the first conductive layer. The third conductive layer is provided to surround the first semiconductor layer with the fifth insulating layer therebetween in a plan view. The second transistor includes the second conductive layer, a fourth conductive layer, a fifth conductive layer, a sixth insulating layer, and a second semiconductor layer. The third insulating layer and the fourth conductive layer are stacked in this order over the second conductive layer. A second opening reaching the second conductive layer is provided in the third insulating layer and the fourth conductive layer. The second semiconductor layer is provided in contact with a top surface of the second conductive layer in the second opening, a side surface of the third insulating layer in the second opening, a side surface of the fourth conductive layer in the second opening, and a top surface of the fourth conductive layer and to surround the fifth conductive layer with the sixth insulating layer therebetween in the plan view. The sixth insulating layer is provided in contact with a top surface of the second semiconductor layer, a side surface of the second semiconductor layer, the top surface of the fourth conductive layer, a side surface of the fourth conductive layer, and a top surface of the third insulating layer. The fifth conductive layer is provided over and in contact with the sixth insulating layer to fill the second opening. The third transistor includes a sixth conductive layer, a seventh conductive layer, an eighth conductive layer, a seventh insulating layer, and a third semiconductor layer. The sixth conductive layer is provided in contact with a top surface of the fifth conductive layer. The fourth insulating layer and the seventh conductive layer are stacked in this order over the sixth conductive layer. A third opening reaching the sixth conductive layer is provided in the fourth insulating layer and the seventh conductive layer. The third semiconductor layer is provided in contact with a top surface of the sixth conductive layer in the third opening, a side surface of the fourth insulating layer in the third opening, a side surface of the seventh conductive layer in the third opening, and a top surface of the seventh conductive layer and to surround the eighth conductive layer with the seventh insulating layer therebetween in the plan view. The seventh insulating layer is provided in contact with a top surface of the third semiconductor layer, a side surface of the third semiconductor layer, the top surface of the seventh conductive layer, a side surface of the seventh conductive layer, and a top surface of the fourth insulating layer. The eighth conductive layer is provided over and in contact with the seventh insulating layer to fill the third opening.

In the above, at least one of the first semiconductor layer, the second semiconductor layer, and the third semiconductor layer preferably includes a metal oxide.

In the above, it is preferable that the second conductive layer include a ninth conductive layer and a tenth conductive layer, the ninth conductive layer be provided in contact with the top surface of the first semiconductor layer to include a region overlapping with the first conductive layer, the tenth conductive layer be provided in contact with a top surface of the ninth conductive layer to include a region overlapping with the first conductive layer, and the second semiconductor layer be provided in contact with a top surface of the tenth conductive layer.

In the above, it is preferable that the second conductive layer include a ninth conductive layer, a tenth conductive layer, and an eleventh conductive layer; the ninth conductive layer be provided in contact with the top surface of the first semiconductor layer to include a region overlapping with the first conductive layer; the tenth conductive layer be provided in contact with a top surface of the ninth conductive layer; the eleventh conductive layer be provided in contact with a top surface of the tenth conductive layer to include a region overlapping with the first conductive layer; and the second semiconductor layer be provided in contact with a top surface of the eleventh conductive layer.

In the above, it is preferable that a capacitor be included between the first transistor and the second transistor; the first transistor, the second transistor, the capacitor, and the third transistor be stacked in this order; the capacitor include a ninth conductive layer, a tenth conductive layer, and an eighth insulating layer; the eighth insulating layer include a region in contact with a side surface of the ninth conductive layer; the tenth conductive layer cover at least part of the side surface of the ninth conductive layer with the eighth insulating layer therebetween; the ninth conductive layer be provided in contact with the top surface of the fifth conductive layer; and the sixth conductive layer be provided in contact with a top surface of the ninth conductive layer.

Another embodiment of the present invention is a method for manufacturing a semiconductor device, including: forming a first conductive layer; forming a first insulating layer over the first conductive layer; forming a second conductive layer over the first insulating layer; forming a second insulating layer over the first insulating layer and the second conductive layer; processing the second conductive layer and the second insulating layer, thereby forming a first opening reaching the first conductive layer; forming a first insulating film in contact with a top surface of the first conductive layer in the first opening, a side surface of the first insulating layer in the first opening, a side surface of the second conductive layer in the first opening, a side surface of the second insulating layer in the first opening, and a top surface of the second insulating layer; processing the first insulating film, thereby exposing the top surface of the first conductive layer in the first opening and the top surface of the second insulating layer and forming a third insulating layer in contact with the side surface of the first insulating layer in the first opening, the side surface of the second conductive layer in the first opening, and the side surface of the second insulating layer in the first opening; forming a first metal oxide film in contact with a top surface of the first conductive layer, a side surface of the third insulating layer, a top surface of the third insulating layer, and the top surface of the second insulating layer; processing the first metal oxide film, thereby forming a first semiconductor layer including a region overlapping with the first opening; forming a third conductive layer in contact with a top surface of the first semiconductor layer; forming a fourth insulating layer over the third conductive layer and the second insulating layer; forming a first conductive film over the fourth insulating layer; processing the first conductive film and the fourth insulating layer, thereby forming a second opening reaching the third conductive layer; forming a second metal oxide film in contact with a top surface of the third conductive layer in the second opening, a side surface of the fourth insulating layer in the second opening, a side surface of the first conductive film in the second opening, and a top surface of the first conductive film; processing the second metal oxide film, thereby forming a second semiconductor layer including a region overlapping with the second opening; processing the first conductive film, thereby forming a fourth conductive layer including a region overlapping with the third conductive layer; forming a fifth insulating layer over the second semiconductor layer, the fourth conductive layer, and the fourth insulating layer; forming a second conductive film over the fifth insulating layer; processing the second conductive film, thereby forming a fifth conductive layer including a region overlapping with the second semiconductor layer; forming a sixth insulating layer over the fifth conductive layer and the fifth insulating layer; processing a top surface of the sixth insulating layer and a top surface of the fifth conductive layer to be substantially equal in height from a substrate surface; forming a sixth conductive layer in contact with the top surface of the fifth conductive layer; forming a seventh insulating layer over the fifth conductive layer and the sixth insulating layer; forming a third conductive film over the seventh insulating layer; processing the third conductive film and the seventh insulating layer, thereby forming a third opening reaching the sixth conductive layer; forming a third metal oxide film in contact with a top surface of the sixth conductive layer in the third opening, a side surface of the seventh insulating layer in the third opening, a side surface of the third conductive film in the third opening, and a top surface of the third conductive film; processing the third metal oxide film, thereby forming a third semiconductor layer including a region overlapping with the third opening; processing the third conductive film, thereby forming a seventh conductive layer including a region overlapping with the sixth conductive layer; forming an eighth insulating layer over the third semiconductor layer, the seventh conductive layer, and the seventh insulating layer; forming a fourth conductive film over the eighth insulating layer; and processing the fourth conductive film, thereby forming an eighth conductive layer including a region overlapping with the third semiconductor layer.

### Effect of the Invention

One embodiment of the present invention can provide a semiconductor device, a memory device, or a transistor that can be reduced in size or highly integrated. Another embodiment of the present invention can provide a semiconductor device, a memory device, or a transistor that has high reliability. Another embodiment of the present invention can provide a semiconductor device or a memory device that has high reading accuracy. Another embodiment of the present invention can provide a transistor with a high on-state current. Another embodiment of the present invention can provide a transistor with favorable electrical characteristics. Another embodiment of the present invention can provide an inexpensive semiconductor device or an inexpensive memory device. Another embodiment of the present invention can provide a semiconductor device or a memory device that has low power consumption. Another embodiment of the present invention can provide a semiconductor device or a memory device that has high operating speed. Another embodiment of the present invention can provide a novel semiconductor device, a novel memory device, or a novel transistor.

Another embodiment of the present invention can provide a method for manufacturing a semiconductor device, a memory device, or a transistor that can be reduced in size or highly integrated. Another embodiment of the present invention can provide a method for manufacturing a semiconductor device, a memory device, or a transistor that has high reliability. Another embodiment of the present invention can provide a method for manufacturing a semiconductor device or a memory device that has high reading accuracy. Another embodiment of the present invention can provide a method for manufacturing a transistor with a high on-state current. Another embodiment of the present invention can provide a method for manufacturing a transistor with favorable electrical characteristics. Another embodiment of the present invention can provide a method for manufacturing a semiconductor device or a memory device with high yield. Another embodiment of the present invention can provide a method for manufacturing a semiconductor device or a memory device that has low power consumption. Another embodiment of the present invention can provide a method for manufacturing a semiconductor device or a memory device that has high operating speed. Another embodiment of the present invention can provide a method for manufacturing a novel semiconductor device, a novel memory device, or a novel transistor.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a block diagram illustrating a structure example of a semiconductor device. FIG. 1B and FIG. 1C are circuit diagrams each illustrating a structure example of a memory cell.

FIG. 2A and FIG. 2B are circuit diagrams each illustrating a structure example of a memory cell.

FIG. 3A is a block diagram illustrating a structure example of a semiconductor device. FIG. 3B and FIG. 3C are circuit diagrams each illustrating a structure example of a memory cell.

FIG. 4A is a plan view illustrating a structure example of a semiconductor device. FIG. 4B and FIG. 4C are cross-sectional views illustrating the structure example of the semiconductor device.

FIG. 5A is a plan view illustrating a structure example of a semiconductor device. FIG. 5B and FIG. 5C are cross-sectional views illustrating the structure example of the semiconductor device.

FIG. 6A and FIG. 6B are cross-sectional views illustrating a structure example of a transistor.

FIG. 7A is a plan view illustrating a structure example of a semiconductor device. FIG. 7B and FIG. 7C are cross-sectional views illustrating the structure example of the semiconductor device.

FIG. 8A is a plan view illustrating a structure example of a semiconductor device. FIG. 8B and FIG. 8C are cross-sectional views illustrating the structure example of the semiconductor device.

FIG. 9A is a plan view illustrating a structure example of a semiconductor device. FIG. 9B and FIG. 9C are cross-sectional views illustrating the structure example of the semiconductor device.

FIG. 10A is a plan view illustrating a structure example of a semiconductor device. FIG. 10B and FIG. 10C are cross-sectional views illustrating the structure example of the semiconductor device.

FIG. 11A is a plan illustrating a structure example of a semiconductor device. FIG. 11B and FIG. 11C are cross-sectional views illustrating the structure example of the semiconductor device.

FIG. 12A is a plan view illustrating a structure example of a semiconductor device. FIG. 12B and FIG. 12C are cross-sectional views illustrating the structure example of the semiconductor device.

FIG. 13A to FIG. 13C are plan views illustrating structure examples of a semiconductor device.

FIG. 14A to FIG. 14C are plan views illustrating structure examples of a semiconductor device.

FIG. 15A to FIG. 15C are plan views illustrating structure examples a semiconductor device.

FIG. 16A and FIG. 16B are cross-sectional views illustrating a structure example of a semiconductor device.

FIG. 17A and FIG. 17B are cross-sectional views illustrating a structure example of a semiconductor device.

FIG. 18A and FIG. 18B are cross-sectional views illustrating a structure example of a semiconductor device.

FIG. 19A and FIG. 19B are cross-sectional views illustrating a structure example of a semiconductor device.

FIG. 20A and FIG. 20B are cross-sectional views illustrating a structure example of a semiconductor device.

FIG. 21A and FIG. 21B are cross-sectional views illustrating a structure example of a semiconductor device.

FIG. 22A and FIG. 22B are cross-sectional views illustrating a structure example of a semiconductor device.

FIG. 23A and FIG. 23B are cross-sectional views illustrating a structure example of a semiconductor device.

FIG. 24A and FIG. 24B are cross-sectional views illustrating a structure example of a semiconductor device.

FIG. 25A is a block diagram illustrating a structure example of a display apparatus. FIG. 25B is a plan view illustrating a structure example of a pixel. FIG. 25C is a circuit diagram illustrating a structure example of a pixel.

FIG. 26A and FIG. 26B are plan views illustrating a structure example of a semiconductor device.

FIG. 27 is a cross-sectional view illustrating a structure example of a semiconductor device.

FIG. 28 is a cross-sectional view illustrating a structure example of a semiconductor device.

FIG. 29A and FIG. 29B are plan views illustrating a structure example of a semiconductor device.

FIG. 30A and FIG. 30B are plan views illustrating a structure example of a semiconductor device.

FIG. 31A and FIG. 31B are plan views illustrating a structure example of a semiconductor device.

FIG. 32A and FIG. 32B are plan views illustrating a structure example of a semiconductor device.

FIG. 33A and FIG. 33B are plan views illustrating a structure example of a semiconductor device.

FIG. 34A is a plan view illustrating an example of a method for manufacturing a semiconductor device. FIG. 34B and FIG. 34C are cross-sectional views illustrating the example of the method for manufacturing a semiconductor device.

FIG. 35A is a plan view illustrating an example of a method for manufacturing a semiconductor device. FIG. 35B and FIG. 35C are cross-sectional views illustrating the example of the method for manufacturing a semiconductor device.

FIG. 36A is a plan view illustrating an example of a method for manufacturing a semiconductor device. FIG. 36B and FIG. 36C are cross-sectional views illustrating the example of the method

FIG. 37A is a plan view illustrating an example of a method for manufacturing a semiconductor device. FIG. 37B and FIG. 37C are cross-sectional views illustrating the example of the method for manufacturing a semiconductor device.

FIG. 38A is a plan view illustrating an example of a method for manufacturing a semiconductor device. FIG. 38B and FIG. 38C are cross-sectional views illustrating the example of the method for manufacturing a semiconductor device.

FIG. 39A is a plan view illustrating an example of a method for manufacturing a semiconductor device. FIG. 39B and FIG. 39C are cross-sectional views illustrating the example of the method for manufacturing a semiconductor device.

FIG. 40A is a plan view illustrating an example of a method for manufacturing a semiconductor device. FIG. 40B and FIG. 40C are cross-sectional views illustrating the example of the method for manufacturing a semiconductor device.

FIG. 41A is a plan view illustrating an example of a method for manufacturing a semiconductor device. FIG. 41B and FIG. 41C are cross-sectional views illustrating the example of the method for manufacturing a semiconductor device.

FIG. 42A is a plan view illustrating an example of a method for manufacturing a semiconductor device. FIG. 42B and FIG. 42C are cross-sectional views illustrating the example of the method for manufacturing a semiconductor device.

FIG. 43A is a plan view illustrating an example of a method for manufacturing a semiconductor device. FIG. 43B and FIG. 43C are cross-sectional views illustrating the example of the method for manufacturing a semiconductor device.

FIG. 44A is a plan view illustrating an example of a method for manufacturing a semiconductor device. FIG. 44B and FIG. 44C are cross-sectional views illustrating the example of the method for manufacturing a semiconductor device.

FIG. 45A is a plan view illustrating an example of a method for manufacturing a semiconductor device. FIG. 45B and FIG. 45C are cross-sectional views illustrating the example of the method for manufacturing a semiconductor device.

FIG. 46A is a plan view illustrating an example of a method for manufacturing a semiconductor device. FIG. 46B and FIG. 46C are cross-sectional views illustrating the example of the method for manufacturing a semiconductor device.

FIG. 47A is a plan view illustrating an example of a method for manufacturing a semiconductor device. FIG. 47B and FIG. 47C are cross-sectional views illustrating the example of the method for manufacturing a semiconductor device.

FIG. 48A is a plan view illustrating an example of a method for manufacturing a semiconductor device. FIG. 48B and FIG. 48C are cross-sectional views illustrating the example of the method for manufacturing a semiconductor device.

FIG. 49A is a plan view illustrating an example of a method for manufacturing a semiconductor device. FIG. 49B and FIG. 49C are cross-sectional views illustrating the example of the method for manufacturing a semiconductor device.

FIG. 50A is a plan view illustrating an example of a method for manufacturing a semiconductor device. FIG. 50B and FIG. 50C are cross-sectional views illustrating the example of the method for manufacturing a semiconductor device.

FIG. 51A is a plan view illustrating an example of a method for manufacturing a semiconductor device. FIG. 51B and FIG. 51C are cross-sectional views illustrating the example of the method for manufacturing a semiconductor device.

FIG. 52A is a plan view illustrating an example of a method for manufacturing a semiconductor device. FIG. 52B and FIG. 52C are cross-sectional views illustrating the example of the method for manufacturing a semiconductor device.

FIG. 53A is a plan view illustrating an example of a method for manufacturing a semiconductor device. FIG. 53B and FIG. 53C are cross-sectional views illustrating the example of the method for manufacturing a semiconductor device.

FIG. 54A is a plan view illustrating an example of a method for manufacturing a semiconductor device. FIG. 54B and FIG. 54C are cross-sectional views illustrating the example of the method for manufacturing a semiconductor device.

FIG. 55A is a plan view illustrating an example of a method for manufacturing a semiconductor device. FIG. 55B and FIG. 55C are cross-sectional views illustrating the example of the method for manufacturing a semiconductor device.

FIG. 56 is a perspective view illustrating a structure example of a semiconductor device.

FIG. 57 is a cross-sectional view illustrating a structure example of a semiconductor device.

FIG. 58 is a cross-sectional view illustrating a structure example of a semiconductor device.

FIG. 59A and FIG. 59B are diagrams each illustrating an example of an electronic component.

FIG. 60A and FIG. 60B are diagrams each illustrating an example of an electronic appliance. FIG. 60C to FIG. 60E are diagrams illustrating an example of a large computer.

FIG. 61 is a diagram illustrating an example of space equipment.

FIG. 62 is a diagram illustrating an example of a storage system that can be used in a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is applied to portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings. For example, in the actual manufacturing process, a layer, a resist mask, or the like might be unintentionally reduced in size by treatment such as etching, which might not be reflected in the drawings for easy understanding.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

A transistor is a kind of semiconductor element and can achieve a function of amplifying a current or a voltage, a switching operation for controlling conduction or non-conduction, and the like. A transistor in this specification includes, in its category, an IGFET (Insulated Gate Field Effect Transistor) and a thin film transistor (TFT).

In this specification and the like, a transistor is an element having at least three terminals including a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % can be regarded as an impurity. When an impurity is contained, the density of defect states in a semiconductor increases or the crystallinity decreases in some cases, for example. In the case where the semiconductor is an oxide semiconductor, examples of impurities that change the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material that contains more oxygen than nitrogen in its composition. A nitride oxide refers to a material that contains more nitrogen than oxygen in its composition.

The contents of elements included in films, such as hydrogen, oxygen, carbon, and nitrogen, can be analyzed using secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

In this specification and the like, the terms “film” and “layer” can be interchanged with each other depending on the situation. For example, the term “conductive layer” can be changed into the term “conductive film” in some cases, and the term “conductive film” can be changed into the term “conductive layer” in some cases. For example, the term “insulating film” can be changed into the term “insulating layer” in some cases, and the term “insulating layer” can be changed into the term “insulating film” in some cases. For example, the term “semiconductor film” can be changed into the term “semiconductor layer” in some cases, and the term “semiconductor layer” can be changed into the term “semiconductor film” in some cases.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, the term “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (a high power supply potential), VSS (a low power supply potential), GND (a ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are located between X and Y, X and Y are not defined as being electrically connected. Note that in the case where a gate and a drain of a transistor are located between X and Y, X and Y are not defined as being electrically connected. That is, in the case where a drain and a source of a transistor are located between X and Y, X and Y are defined as being electrically connected. Note that in the case where a capacitor is provided between X and Y, X and Y are defined as being electrically connected in some cases and not defined as such in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit), a signal converter circuit (e.g., a digital-analog converter circuit, an analog-digital converter circuit, or a gamma correction circuit), a potential level converter circuit (e.g., a power supply circuit such as a step-up circuit or a step-down circuit, or a level shifter circuit for changing the potential level of a signal), a voltage source, a current source, a switching circuit, an amplifier circuit (e.g., a circuit that can increase signal amplitude, the amount of current, or the like, an operational amplifier, a differential amplifier circuit, a source follower circuit, or a buffer circuit), a signal generation circuit, a memory circuit, or a control circuit) can be connected between X and Y. For instance, even if another circuit is placed between X and Y, X and Y are regarded as being functionally connected when a signal output from X is transmitted to Y.

For example, the expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, the expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0 Ω or a wiring having a resistance value higher than 0 Ω. Therefore, in this specification and the like, a “resistor” includes a wiring having a resistance value, a transistor in which a current flows between a source and a drain, a diode, and a coil. Thus, the term “resistor” can sometimes be replaced with the term “resistance”, “load”, or “region having a resistance value”. Conversely, the term “resistance”, “load”, or “region having a resistance value” can sometimes be replaced with the term “resistor”. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. As another example, the resistance value may be higher than or equal to 1 Ω and lower than or equal to 1×10⁹ Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is placed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. Channel formation regions are connected in series in the multi-gate structure, which is equivalent to a structure where a plurality of transistors are connected in series. Thus, with the multi-gate structure, the amount of off-state current can be reduced, and the breakdown voltage of the transistor can be increased (the reliability can be improved). Alternatively, with the multi-gate structure, a drain-source current does not change much even if a drain-source voltage changes at the time of operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, “voltage” and “potential” can be replaced with each other as appropriate. A “voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean particular potentials. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with positive charge moves, and the amount of the current is expressed as a positive value. In other words, the direction in which a carrier with negative charge moves is opposite to the direction of current, and the amount of the current is expressed as a negative value. Thus, in the case where the polarity of current (or the direction of current) is not specified in this specification and the like, the description “a current flows from element A to element B” can be rephrased as “a current flows from element B to element A”. The description “a current is input to element A” can be rephrased as “a current is output from element A”.

Unless otherwise specified, an off-state current in this specification and the like refers to a leakage current between a source and a drain of a transistor in an off state (also referred to as a non-conducting state or a cut-off state). Unless otherwise specified, the off state refers to a state where a voltage V_{gs} between a gate and a source is lower than a threshold voltage Vₜₕ in an n-channel transistor (higher than Vₜₕ in a p-channel transistor).

In this specification and the like, a top-view shape of a component means the contour shape of the component in a plan view. A plan view means that the component is observed from a normal direction of a surface where the component is formed or from a normal direction of a surface of a support (e.g., a substrate) where the component is formed.

Note that in this specification and the like, a tapered shape refers to a shape such that at least a part of the side surface of a component is inclined with respect to a substrate surface or a formation surface. For example, a tapered shape refers to a shape including a region where the angle formed by the inclined side surface and the substrate surface or the formation surface (also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, terms for describing arrangement, such as “over”, “under”, “left”, and “right”, are used for convenience in describing a positional relation between components with reference to drawings. The positional relation between components is changed as appropriate in accordance with the direction in which the components are described. Thus, without limitation to terms described in this specification, the description can be changed appropriately depending on the situation.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that a metal oxide containing nitrogen is also referred to as a metal oxide in some cases. Furthermore, a metal oxide containing nitrogen may be referred to as a metal oxynitride.

### EMBODIMENT 1

In this embodiment, a semiconductor device of one embodiment of the present invention will be described with reference to drawings. In this embodiment, a memory device will be mainly exemplified as the semiconductor device of one embodiment of the present invention.

One embodiment of the present invention relates to a memory device including a memory portion in which memory cells are arranged in a matrix. The memory cells each include a first transistor, a second transistor, and a third transistor. In the memory device, the first transistor has a function of writing data to the memory cell. The second transistor and the third transistor each have a function of reading data retained in the memory cell.

In the memory device of one embodiment of the present invention, two transistors, i.e., the second transistor and the third transistor that is connected in series to the second transistor, are used to read data retained in the memory cell. The memory device of one embodiment of the present invention including the third transistor allows data retained in the memory cell to be read stably as compared with the case of not including the third transistor. Thus, the memory device can achieve high reading accuracy.

In the memory device of one embodiment of the present invention, the first transistor, the second transistor, and the third transistor are placed to overlap with each other. Thus, the area occupied by the memory cell in a plan view can be reduced. Accordingly, the memory cells can be reduced in size and highly integrated; hence, a memory device that can be reduced in size and increased in resolution can be provided.

Each of the first transistor, the second transistor, and the third transistor in the memory device of one embodiment of the present invention has a structure in which a source electrode and a drain electrode are provided at different heights from the substrate surface to overlap with each other and a drain current flows in the height direction (vertical direction). Thus, these transistors can be reduced in size as compared with a transistor having a structure in which a source electrode and a drain electrode are provided on the same plane. By including the transistor having the above-described structure, the memory device of one embodiment of the present invention can be further reduced in size and increased in resolution.

### <Structure Example 1 of Semiconductor Device>

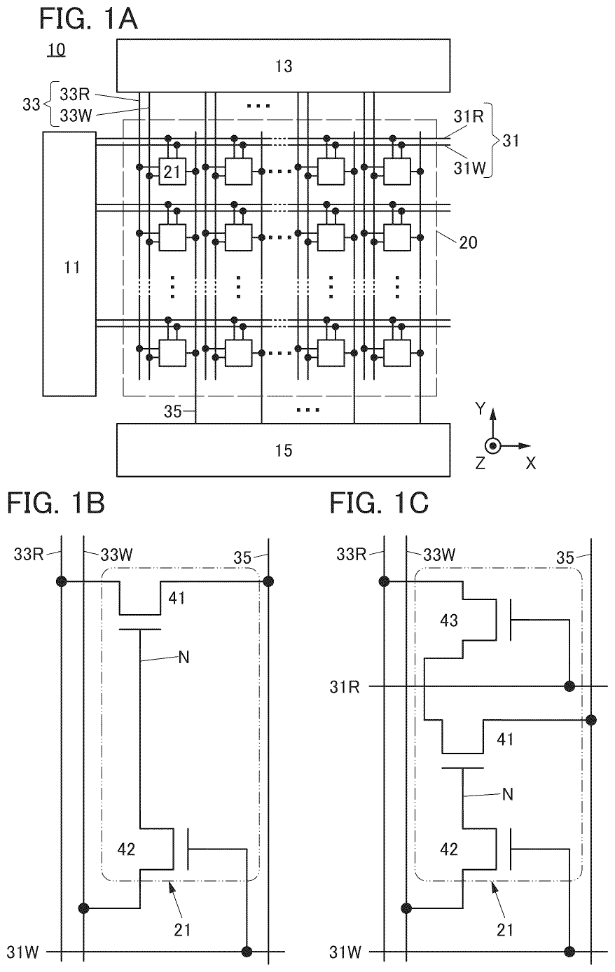

FIG. 1A is a block diagram illustrating a structure example of a semiconductor device 10. The semiconductor device 10 can be a memory device.

The semiconductor device 10 includes a memory portion 20, a word line driver circuit 11, a bit line driver circuit 13, and a power supply circuit 15. The memory portion 20 includes a plurality of memory cells 21 arranged in a matrix. Note that the power supply circuit 15 may be provided outside the semiconductor device 10.

The word line driver circuit 11 is electrically connected to the memory cells 21 through wirings 31. The wirings 31 extend in the row direction of the matrix, for example. The wirings 31 function as word lines. FIG. 1A illustrates a wiring 31R and a wiring 31W as the wirings 31.

The bit line driver circuit 13 is electrically connected to the memory cells 21 through wirings 33. The wirings 33 extend in the column direction of the matrix, for example. The wirings 33 function as bit lines. FIG. 1A illustrates a wiring 33R and a wiring 33W as the wirings 33.

In FIG. 1A, the direction in which the wirings 31 functioning as the word lines extend is the X direction and the direction in which the wirings 33 functioning as the bit lines extend is the Y direction, as shown in the diagram. As described above, the wirings 31 extend in the row direction of the matrix, and the wirings 33 extend in the column direction of the matrix. Thus, the X direction can be the row direction and the Y direction can be the column direction. The X direction and the Y direction can intersect with each other and, specifically, can be perpendicular to each other. In addition, the direction intersecting with both of the X direction and the Y direction, specifically, the direction perpendicular to both of the X direction and the Y direction can be the Z direction. Note that in the following drawings, the directions are represented by the X direction, the Y direction, and the Z direction, and the definitions of the directions may be the same as or different from those in FIG. 1A. In FIG. 1A, the X direction, Y direction, and Z direction are shown by arrows; the forward direction and the reverse direction are not distinguished from each other unless otherwise specified. The same applies to the following drawings.

The power supply circuit 15 is electrically connected to the memory cells 21 through wirings 35. FIG. 1A illustrates an example in which the wirings 35 extend in the column direction of the matrix. The wirings 35 function as power supply lines.

In FIG. 1A, the wirings 31, the wirings 33, and the wirings 35 are shown by straight lines; however, one straight line does not necessarily mean one wiring and may represent a plurality of wirings. In the following block diagrams, circuit diagrams, and the like, a plurality of wirings may be represented by one straight line. As for wirings other than the wirings 31, the wirings 33, and the wirings 35, a plurality of wirings may be represented by one straight line.

The word line driver circuit 11 has a function of selecting, row by row, the memory cells 21 to which data is to be written. Moreover, the word line driver circuit 11 has a function of selecting, row by row, the memory cells 21 from which data is to be read, specifically, the memory cells 21 from which data is to be output to the wirings 33. By supplying a signal to the wiring 31, the word line driver circuit 11 can select the memory cell 21 to which data is to be written or the memory cell 21 from which data is to be read. Specifically, the word line driver circuit 11 has a function of selecting the memory cell 21 to which data is written by supplying a signal to the wiring 31W. Moreover, the word line driver circuit 11 has a function of selecting the memory cell 21 from which data is to be read, specifically, the memory cell 21 from which data is to be output to the wiring 33R by supplying a signal to the wiring 31R. Here, the wiring 31W is also referred to as a write word line, and the wiring 31R is also referred to as a read word line. A signal supplied from the word line driver circuit 11 to the wiring 31W is also referred to as a write signal, and a signal supplied therefrom to the wiring 31R is also referred to as a read signal.

In the above manner, the word line driver circuit 11 has a function of controlling writing of data to the memory cell 21 by supplying a write signal to the wiring 31W. The word line driver circuit 11 also has a function of controlling reading of data from the memory cell 21 by supplying a read signal to the wiring 31R.

The bit line driver circuit 13 has a function of writing data through the wiring 33 to the memory cell 21 selected by the word line driver circuit 11. The bit line driver circuit 13 also has a function of reading data retained in the memory cell 21 by amplifying data output from the memory cell 21 to the wiring 33 and outputting the data to, for example, the outside of the semiconductor device 10. Furthermore, the bit line driver circuit 13 has a function of precharging the wiring 33 before data is read from the memory cell 21.

Specifically, the bit line driver circuit 13 has a function of writing data through the wiring 33W to the memory cell 21 selected by the word line driver circuit 11 using a write signal. The bit line driver circuit 13 also has a function of reading data retained in the memory cell 21 by amplifying data output from the memory cell 21 to the wiring 33R and outputting the data to, for example, the outside of the semiconductor device 10. Furthermore, the bit line driver circuit 13 has a function of precharging the wiring 33R before data is read from the memory cell 21. Here, the wiring 33W is also referred to as a write bit line, and the wiring 33R is also referred to as a read bit line.

In the above manner, the bit line driver circuit 13 has a function of writing data to the memory cell 21 through the wiring 33W. In addition, the bit line driver circuit 13 has a function of reading the data through the wiring 33R.

The power supply circuit 15 has a function of supplying a power supply potential to the wiring 35, specifically, a function of supplying a constant potential to the wiring 35. The power supply circuit 15 has a function of generating a high potential or a low potential and supplying it to the wiring 35, for example. Note that the power supply circuit 15 may have a function of supplying a power supply potential to one or both of the word line driver circuit 11 and the bit line driver circuit 13.

FIG. 1B is a circuit diagram illustrating a structure example of the memory cell 21 of one embodiment of the present invention. The memory cell 21 having this structure includes a transistor 41 and a transistor 42.

One of a source and a drain of the transistor 41 is electrically connected to the wiring 33R. The other of the source and the drain of the transistor 41 is electrically connected to the wiring 35. A gate of the transistor 41 is electrically connected to one of a source and a drain of the transistor 42. The other of the source and the drain of the transistor 42 is electrically connected to the wiring 33W. A gate of the transistor 42 is electrically connected to the wiring 31W. Here, a node to which the gate of the transistor 41 and the one of the source and the drain of the transistor 42 are electrically connected is referred to as a node N.

The transistor 42 has a function of writing data to the memory cell 21. The transistor 41 has a function of reading data retained in the memory cell 21. Note that the memory cell 21 illustrated in FIG. 1B does not include a capacitor for retaining data. In the memory cell 21, data is written to the node N. For example, when an OS transistor is used as the transistor 42, a low leakage current of the OS transistor allows data to be retained at the node N for a longer time than in the case of using a transistor including silicon in its semiconductor layer (also referred to as a Si transistor). Thus, the memory cell can be composed of only two transistors (Tr) without including a capacitor (C); hence, the manufacturing process of the memory cell can be simplified. Note that the memory cell with the above structure can be referred to as a 2Tr0C memory cell.

As a memory cell with a simple structure, a DRAM (Dynamic Random Access Memory), which is a 1Tr1C memory cell composed of one transistor and one capacitor, is well known. However, owing to its structure, the DRAM needs to perform data writing and data reading by using the same transistor and thus has a problem in that the retained data is lost through the transistor at the time of reading the retained data (at the time of turning on the transistor to read the data) (i.e., destructive reading).

In contrast, in the memory cell 21 illustrated in FIG. 1B, the transistor for data writing (the transistor 42) and the transistor for data reading (the transistor 41) are provided separately. Thus, the transistor for data writing (the transistor 42) does not need to be turned on at the time of data reading, so that non-destructive reading is possible.

Specifically, potentials with different levels are supplied to the wiring 33R and the wiring 35, whereby a potential difference is generated between the source and the drain of the transistor 41. At this time, a potential with a level corresponding to data written to the node N is applied to the gate of the transistor 41. Accordingly, whether the transistor 41 is turned on or off depends on the magnitude relation between the threshold voltage of the transistor 41 and the data written to the node N (i.e., the potential applied to the gate of the transistor 41). In the case where the memory cell 21 is a binary memory cell that retains data with a value of either “0” or “1”, when the transistor 41 is in the on state, current flows between the source and the drain of the transistor 41; thus, the current is output to the wiring 33R and it can be detected that data “1” has been written to the node N. Meanwhile, when the transistor 41 is in the off state, current does not flow between the source and the drain of the transistor 41; thus, current is not output to the wiring 33R and it can be detected that data “0” has been written to the node N.

However, in the case of the above-described data reading method, potentials need to be applied to the wiring 33R and the wiring 35 at the time of data reading; hence, the applied potentials are applied to the node N through parasitic capacitance (e.g., a capacitance component included in the transistor 41) every time data reading is performed. Thus, there is an inherent problem in that the level of data that has been originally written varies in all the memory cells 21 connected to the wiring 33R and the wiring 35 to which the potentials are applied (including the memory cells 21 that are not subjected to data reading).

In view of the above, in the memory cell of one embodiment of the present invention, a transistor 43 connected in series to the transistor 41 is provided as illustrated in FIG. 1C. Specifically, one of the source and the drain of the transistor 41 and one of a source and a drain of the transistor 43 are electrically connected to each other. The other of the source and the drain of the transistor 43 is electrically connected to the wiring 33R. A gate of the transistor 43 is electrically connected to the wiring 31R. The description of the memory cell 21 illustrated in FIG. 1B can be referred to for the structure other than the above.

In the memory cell 21 of one embodiment of the present invention illustrated in FIG. 1C, the transistor 42 has a function of writing data. The transistor 41 and the transistor 43 each have a function of reading data retained in the memory cell 21.

Although some portions overlap with the above description of the memory cell 21 illustrated in FIG. 1B, an operation method of the memory cell 21 of one embodiment of the present invention illustrated in FIG. 1C will be described in detail.

The transistor 42 has a function of a switch for writing data to the memory cell 21. For example, in the case where the transistor 42 is an n-channel transistor, the transistor 42 can be turned on by setting the potential of the wiring 31W to a high potential (a potential with which the potential between the source and the gate of the transistor 42 becomes higher than or equal to the threshold voltage), and the transistor 42 can be turned off by setting the potential of the wiring 31W to a low potential (a potential with which the potential between the source and the gate of the transistor 42 becomes lower than the threshold voltage). The transistor 42 has a function of controlling electrical continuity and discontinuity between the wiring 33W and the node N on the basis of the potential of the wiring 31W. When the transistor 42 is turned on, data is written to the memory cell 21 through the wiring 33W, and when the transistor 42 is turned off, the written data is retained. Specifically, when the transistor 42 is turned on, charge corresponding to data is accumulated at the node N, and when the transistor 42 is turned off, the charge at the node N is retained. Note that during the series of operations (at the time of writing data to the memory cell 21 and during data retention), a constant potential (GND (a ground potential) or a low potential) is assumed to be constantly applied to the wiring 35.

The description will be given below assuming that the transistor 41, the transistor 42, and the transistor 43 are n-channel transistors; by appropriately inverting the potential levels, for example, the following description can apply also to the case where any one or two or all of the transistor 41, the transistor 42, and the transistor 43 are p-channel transistors.

The transistor 41 and the transistor 43 each have a function of controlling reading of data retained in the memory cell 21. A method for reading data retained in the memory cell 21 is described below. In the memory cell 21, binary data having a value “0” or “1” is retained as the potential of the node N, and “1” is represented by a potential higher than that for “0”.

To read data retained in the memory cell 21, first, the wiring 33R is precharged to a high potential. The potential of the wiring 35 is set to a constant potential (GND or a low potential) as in the case of the above-described data writing and data retention. Furthermore, the potential of the wiring 31R is set to a high potential (i.e., the transistor 43 is turned on), so that electrical continuity is established between the wiring 33R and the one of the source and the drain of the transistor 41.

At this time, a high potential is applied to the one of the source and the drain of the transistor 41, and GND or a low potential is applied to the other of the source and the drain of the transistor 41. A potential with a level corresponding to data retained in the memory cell 21 (i.e., data written to the node N) is applied to the gate of the transistor 41. That is, whether the transistor 41 is turned on or off is determined depending on the kind of the data.

Here, in the case where data retained in the memory cell 21 is “0”, the difference between the gate potential and the source potential of the transistor 41 is lower than the threshold voltage of the transistor 41. In the case where data retained in the memory cell 21 is “1”, the difference between the gate potential and the source potential of the transistor 41 is higher than the threshold voltage of the transistor 41. In this case, when the data retained in the memory cell 21 is “0”, the transistor 41 is turned off and the transistor 43 is turned on, so that current does not flow from the wiring 33R to the wiring 35. On the other hand, when the data retained in the memory cell 21 is “1”, both the transistor 43 and the transistor 41 are turned on, so that current flows from the wiring 33R to the wiring 35. Accordingly, the bit line driver circuit 13 can read the data retained in the memory cell 21 from the current flowing through the wiring 33R or the potential of the wiring 33R. Note that the difference between the gate potential and the source potential of the transistor 41 may be higher than the threshold voltage of the transistor 41 regardless of whether the data retained in the memory cell 21 is “0” or “1”. Also in this case, the bit line driver circuit 13 can read the data retained in the memory cell 21 by reading the amount of current flowing through the wiring 33R, for example.

As described above, in the memory cell 21 illustrated in FIG. 1C of one embodiment of the present invention, the potential of the wiring 35 is always fixed to a certain level (GND or a low potential) in all the operations of data writing, data retention, and data reading. At the time of data reading (the time of applying a high potential to the wiring 33R), only the transistor 43 included in the memory cell 21 subjected to data reading can be turned on through the wiring 31R. Meanwhile, since the transistor 43 in the memory cell 21 that is not subjected to data reading is in the off state, application of a potential from the wiring 33R to the node N can be inhibited, thereby preventing a change in the level of data retained in the memory cell 21. Thus, the data retained in the memory cell 21 illustrated in FIG. 1C of one embodiment of the present invention can be read more stably than the data retained in the aforementioned memory cell 21 illustrated in FIG. 1B; hence, the memory cell 21 illustrated in FIG. 1C enables a memory device with high reading accuracy.

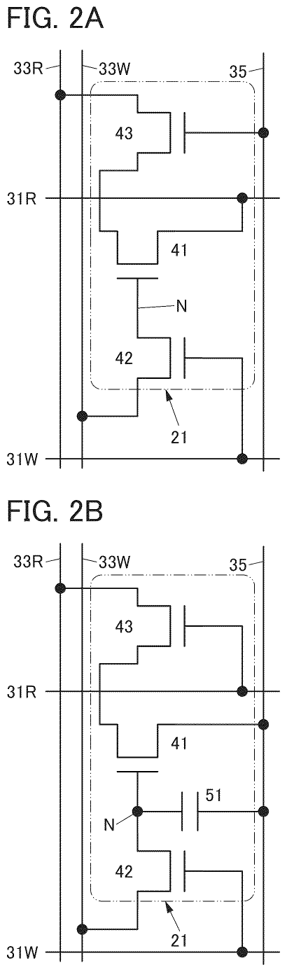

FIG. 2A illustrates a variation example of the memory cell 21 illustrated in FIG. 1C, and illustrate an example in which the wiring 31R is electrically connected to the other of the source and the drain of the transistor 41 and the wiring 35 is electrically connected to the gate of the transistor 43. In the memory cell 21 illustrated in FIG. 2A, data writing and data retention can be performed by methods similar to those for the memory cell 21 illustrated in FIG. 1C. Data reading can be performed in such a way that the description of the wiring 35 in the memory cell 21 illustrated in FIG. 1C is applied to the wiring 31R in the memory cell 21 illustrated in FIG. 2A, the description of the wiring 31R in the memory cell 21 illustrated in FIG. 1C is applied to the wiring 35 in the memory cell 21 illustrated in FIG. 2A, and the function of the power supply circuit 15 and the function of the word line driver circuit 11 in the semiconductor device 10 illustrated in FIG. 1A are interchanged with each other.

The memory cells 21 illustrated in FIG. 1C and FIG. 2A do not include a capacitor and are each a 3Tr0C memory cell composed of three transistors. Thus, for example, OS transistors are preferably used as the transistor 41, the transistor 42, and the transistor 43. It is particularly preferable to use an OS transistor as the transistor 42 whose off-state current amount affects the data retention period of the memory cell 21. Examples of a metal oxide included in a channel formation region of an OS transistor include indium oxide, gallium oxide, and zinc oxide.

Transistors other than OS transistors may be used as the transistor 41 and the transistor 43. For example, Si transistors including silicon in channel formation regions can be used as the transistor 41 and the transistor 43. As the silicon, single crystal silicon, amorphous silicon (sometimes referred to as hydrogenated amorphous silicon), microcrystalline silicon, or polycrystalline silicon (including low-temperature polycrystalline silicon) can be used, for example. A Si transistor has a higher on-state current and higher field-effect mobility than an OS transistor. Accordingly, when Si transistors are used as the transistor 41 and the transistor 43, the memory cell 21 with high data reading speed can be achieved.

As the transistor 41 and the transistor 43, transistors having the same structure or different structures may be used. For example, the transistor 41 and the transistor 43 may each be an OS transistor; alternatively, the transistor 41 may be a Si transistor and the transistor 43 may be an OS transistor. Alternatively, the transistor 41 may be an OS transistor and the transistor 43 may be a Si transistor.

FIG. 2B shows a variation example of the memory cell 21 illustrated in FIG. 1C, which is different from the memory cell 21 illustrated in FIG. 1C in that a capacitor 51 is included.

In the memory cell 21 illustrated in FIG. 2B, one electrode of the capacitor 51 is electrically connected to the other of the source and the drain of the transistor 42 and the gate of the transistor 41. The other electrode of the capacitor 51 is electrically connected to the wiring 35. Here, a node to which the gate of the transistor 41, the other of the source and the drain of the transistor 42, and the one electrode of the capacitor 51 are electrically connected is referred to as the node N. The description of the memory cell 21 illustrated in FIG. 1C can be referred to for the other structure of the memory cell 21 illustrated in FIG. 2B.

The memory cell 21 illustrated in FIG. 2B can perform any of the operations of data writing, data retention, and data reading by a method similar to that for the memory cell 21 illustrated in FIG. 1C. Owing to the capacitor 51, the memory cell 21 illustrated in FIG. 2B can retain data written to the node N more stably than the memory cell 21 illustrated in FIG. 1C. Thus, long-term data retention can be performed more stably than in the memory cell 21 without the capacitor 51 that is illustrated in FIG. 1C.

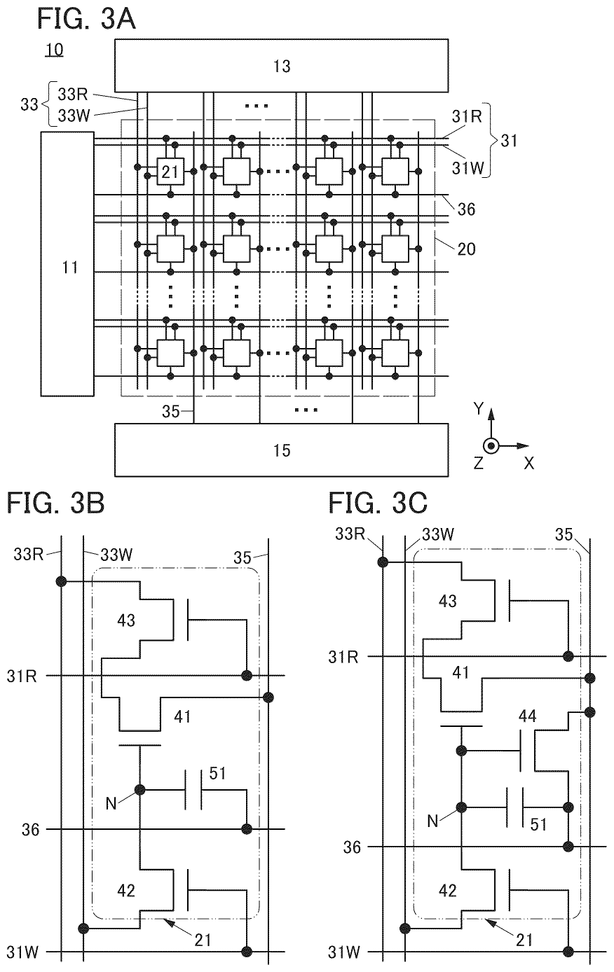

FIG. 3A is a block diagram illustrating a structure example of the semiconductor device 10 different from that in FIG. 1A. The semiconductor device 10 illustrated in FIG. 3A is different from the semiconductor device 10 illustrated in FIG. 1A in including a wiring 36.

The memory cells 21 arranged in the same row are electrically connected to the word line driver circuit 11 through the common wiring 36. The wiring 36 functions as a capacitor line.

The description of the semiconductor device 10 illustrated in FIG. 1A can be referred to for the other components of the semiconductor device 10 illustrated in FIG. 3A.

FIG. 3B is a circuit diagram illustrating a structure example of the memory cell 21 included in the semiconductor device 10 illustrated in FIG. 3A. The memory cell 21 with this structure is different from the memory cell 21 illustrated in FIG. 1B in including the capacitor 51 in addition to the wiring 36.

In the memory cell 21 illustrated in FIG. 3B, one electrode of the capacitor 51 is electrically connected to the other of the source and the drain of the transistor 42 and the gate of the transistor 41. The other electrode of the capacitor 51 is electrically connected to the wiring 36. Here, a node to which the gate of the transistor 41, the other of the source and the drain of the transistor 42, and the one electrode of the capacitor 51 are electrically connected is referred to as the node N. The description of the memory cell 21 illustrated in FIG. 1C can be referred to for the other structure of the memory cell 21 illustrated in FIG. 3B.

The memory cell 21 illustrated in FIG. 3B can perform any of the operations of data writing, data retention, and data reading by a method similar to that for the memory cell 21 illustrated in FIG. 1C. Note that during the series of operations, the wiring 36 is assumed to be constantly supplied with a constant potential, that is, GND (a ground potential) or a low potential, like the wiring 35.

FIG. 3C shows a variation example of the memory cell 21 illustrated in FIG. 3B, which is different from the memory cell 21 illustrated in FIG. 3B in that a transistor 44 is included.

In the memory cell 21 illustrated in FIG. 3C, one of a source and a drain of the transistor 44 is electrically connected to the wiring 35. The other of the source and the drain of the transistor 44 is electrically connected to the other electrode of the capacitor 51. A gate of the transistor 44 is electrically connected to the gate of the transistor 41 and one electrode of the capacitor 51. The description of the memory cell 21 illustrated in FIG. 3B can be referred to for the other components of the memory cell 21 illustrated in FIG. 3C.

The memory cell 21 illustrated in FIG. 3C can perform any of the operations of data writing, data retention, and data reading by a method similar to that for the memory cell 21 illustrated in FIG. 3B. Note that during the series of operations, the wiring 36 is assumed to be constantly supplied with a constant potential identical to the constant potential supplied to the wiring 35, i.e., GND (a ground potential) or a low potential.

The memory cells 21 illustrated in FIG. 2B and FIG. 3B are each a 3Tr1C memory cell composed of three transistors and one capacitor. The memory cell 21 illustrated in FIG. 3C is a 4Tr1C memory cell composed of four transistors and one capacitor. OS transistors or Si transistors may be used as the transistors included in these memory cells.

Regarding the memory cells 21 illustrated in FIG. 2B, FIG. 3B, and FIG. 3C, a memory cell configured to use OS transistors as the transistors is also referred to as a NOSRAM (registered trademark) (Nonvolatile Oxide Semiconductor Random Access Memory).

As described above, the off-state current of an OS transistor is extremely low. Thus, when an OS transistor is used as the transistor 42 included in each of the memory cells 21 illustrated in FIG. 1C, FIG. 2A, FIG. 2B, FIG. 3B, and FIG. 3C of one embodiment of the present invention, charge accumulated at the node N can be retained for a long period. Data written to the memory cell 21 can be retained for a long period and therefore the frequency of the refresh operation (data rewriting to the memory cell 21) can be reduced. Thus, power consumption of the semiconductor device 10 can be reduced.

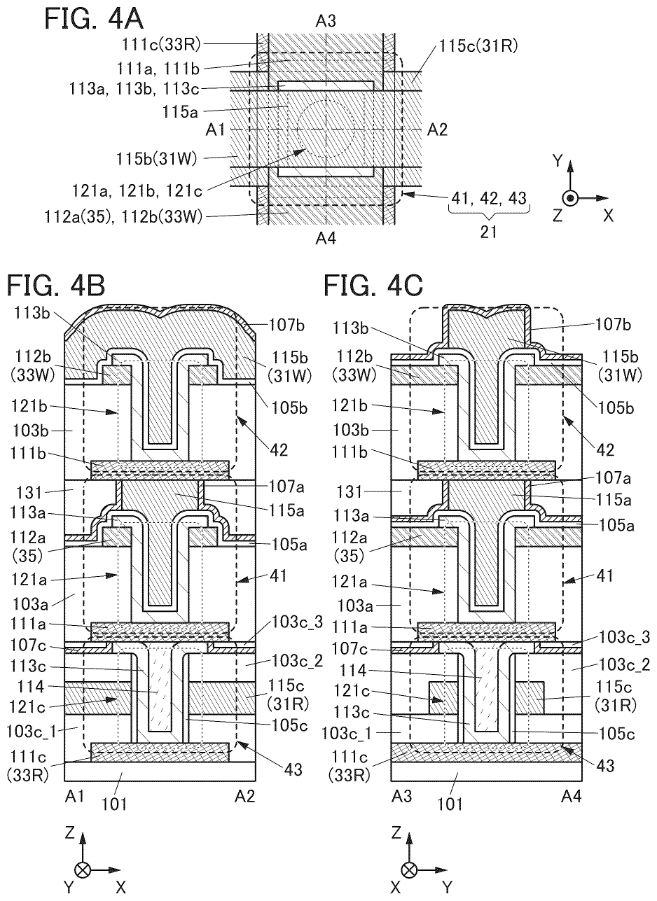

FIG. 4A is a plan view illustrating a structure example of part of the semiconductor device 10, which is the semiconductor device of one embodiment of the present invention. FIG. 4A includes the structure example of the memory cell 21 illustrated in FIG. 1C. For clarity of the drawing, some components, including insulating layers, are omitted in FIG. 4A. Some components are omitted also in the following plan views. FIG. 4B is a cross-sectional view along the dashed-dotted line A1-A2 in FIG. 4A, and FIG. 4C is a cross-sectional view along the dashed-dotted line A3-A4 in FIG. 4A.

The semiconductor device of one embodiment of the present invention includes an insulating layer 101 over a substrate (not illustrated) and the memory cell 21 over the insulating layer 101. The memory cell 21 includes the transistor 43, the transistor 41 over the transistor 43, and the transistor 42 over the transistor 41.

The semiconductor device of one embodiment of the present invention also includes an insulating layer 103c_1 over the insulating layer 101; an insulating layer 103c_2 over the insulating layer 103c_1; an insulating layer 107c over the transistor 43, the insulating layer 103c_1, and the insulating layer 103c_2; an insulating layer 103c_3 over the insulating layer 107c; the transistor 41 and an insulating layer 103a over the insulating layer 103c_3; an insulating layer 107a over the transistor 41 and the insulating layer 103a; an insulating layer 131 over the insulating layer 107a; the transistor 42 and an insulating layer 103b over the transistor 41 and the insulating layer 131; and an insulating layer 107b over the transistor 42 and the insulating layer 103b. Here, the insulating layer 101, the insulating layer 103c_1, the insulating layer 103c_2, the insulating layer 103a, the insulating layer 131, and the insulating layer 103b function as interlayer insulating layers and are preferably planarized. Note that a structure where the insulating layers functioning as interlayer insulating layers are not planarized may alternatively be employed.

The transistor 43 includes a conductive layer 111c, a conductive layer 111a, a semiconductor layer 113c, an insulating layer 105c, and a conductive layer 115c.

The conductive layer 111c functions as one of the source electrode and the drain electrode of the transistor 43 and functions as the wiring 33R. The conductive layer 111a functions as the other of the source electrode and the drain electrode of the transistor 43. The insulating layer 105c functions as a gate insulating layer of the transistor 43. The conductive layer 115c functions as the gate electrode of the transistor 43 and functions as the wiring 31R. The conductive layer 111c functioning as the wiring 33R includes a region extending in the Y direction. The conductive layer 115c functioning as the wiring 31R includes a region extending in the X direction.

The conductive layer 111c is provided over the insulating layer 101, the insulating layer 103c_1 is provided over the insulating layer 101 and the conductive layer 111c, the conductive layer 115c is provided over the insulating layer 103c_1, and the insulating layer 103c_2 is provided over the insulating layer 103c_1 and the conductive layer 115c. The insulating layer 103c_1, the conductive layer 115c, and the insulating layer 103c_2 have an opening 121c reaching the conductive layer 111c. FIG. 4A illustrates an example in which the opening 121c is circular in a plan view. When the top-surface shape of the opening 121c is a circle, the processing accuracy at the time of forming the opening 121c can be increased and the opening 121c having a minute size can be formed. Note that the top-surface shape of the opening 121c may be an ellipse or a polygon such as a quadrangle, for example.

The insulating layer 105c functioning as the gate insulating layer of the transistor 43 is provided to include, in the opening 121c, a region in contact with part of the top surface of the conductive layer 111c, a side surface of the insulating layer 103c_1, a side surface of the conductive layer 115c, and a side surface of the insulating layer 103c_2.

The semiconductor layer 113c is provided to cover the opening 121c with the insulating layer 105c therebetween and to include a region positioned in the opening 121c. An upper end portion of the insulating layer 105c has a curved shape. The semiconductor layer 113c includes a region in contact with the top surface of the insulating layer 103c_2, a region in contact with the curved portion of the insulating layer 105c, a region in contact with a side surface of the insulating layer 105c, and a region in contact with the top surface of the conductive layer 111c. The semiconductor layer 113c has a shape along the top surface of the insulating layer 103c_2, the curved portion of the insulating layer 105c, the side surface of the insulating layer 105c, and the top surface of the conductive layer 111c. Thus, the semiconductor layer 113c defines a concave portion at the position overlapping with the opening 121c. A layer 114 is provide to be embedded in the concave portion. The layer 114 has functions of filling the concave portion and planarizing the top surface. Note that the layer 114 does not need to be provided in the case where the concave portion does not affect the coverage with an upper layer formed later or in the case where the concave portion itself is not formed.

Although the semiconductor layer 113c has a single-layer structure in FIG. 4B and FIG. 4C, one embodiment of the present invention is not limited thereto. The semiconductor layer 113c may have a stacked-layer structure of two or more layers.

The insulating layer 107c is provided to cover a side surface of a side end portion of the semiconductor layer 113c and the top surface of the insulating layer 103c_2. The insulating layer 107c has a function of inhibiting diffusion of impurities into the transistor 43, for example, a function of inhibiting diffusion of impurities into the semiconductor layer 113c. The insulating layer 103c_3 is provided over the insulating layer 107c. The uppermost surfaces of the semiconductor layer 113c, the insulating layer 107c, and the insulating layer 103c_3 are preferably substantially equal in height from the substrate surface. In that case, the formation surface of an upper layer to be formed later (e.g., the conductive layer 111a) can be flat, so that the coverage with the upper layer can be favorable. Note that the insulating layer 103c_3 is not necessarily provided in the case where the thickness of the insulating layer 107c is substantially equal to the thickness of the semiconductor layer 113c (i.e., the case where the top surface of the insulating layer 107c is substantially level with the uppermost surface of the semiconductor layer 113c).

The conductive layer 111a functioning as the other of the source electrode and the drain electrode of the transistor 43 is provided in contact with the uppermost surface of the semiconductor layer 113c, the top surface of the layer 114, the uppermost surface of the insulating layer 107c, and the top surface of the insulating layer 103c_3. Moreover, the conductive layer 111a is provided to include a region overlapping with the conductive layer 111c functioning as the one of the source electrode and the drain electrode of the transistor 43.

An end portion of the conductive layer 111a is preferably substantially aligned with an end portion of the semiconductor layer 113c or positioned beyond the end portion of the semiconductor layer 113c. In such a case, the contact area between the conductive layer 111a and the semiconductor layer 113c can be increased, so that the contact resistance between the conductive layer 111a and the semiconductor layer 113c can be reduced.

In the transistor 43, the source electrode, the drain electrode, and the gate electrode are provided at different heights from the substrate surface to overlap with each other. The gate electrode is sandwiched between the source electrode and the drain electrode. Thus, in the transistor 43, the channel length direction corresponds to the direction along the side surface of the insulating layer 105c in a cross-sectional view, and a drain current flows in this direction.

In the case where the transistor 43 has the above-described structure, the channel length of the transistor 43 can be controlled by adjusting the thickness of the layers positioned between the source electrode and the drain electrode in a cross-sectional view (the insulating layer 103c_1, the conductive layer 115c, and the insulating layer 103c_2). Thus, the channel length of the transistor 43 can be smaller than the resolution limit of a light-exposure apparatus. Furthermore, the area occupied by the transistor in a plan view can be smaller than that occupied by a transistor having a structure in which a source electrode and a drain electrode are provided on the same plane.

In the transistor 43, the gate electrode (the conductive layer 115c) is provided to surround the opening 121c (the semiconductor layer 113c and the insulating layer 105c) in a plan view. Thus, all regions of the semiconductor layer 113c in the opening 121c that face the conductive layer 115c with the insulating layer 105c therebetween can serve as a channel formation region of the transistor 43. In this case, the channel width direction of the transistor 43 is parallel to the XY plane, and the channel width of the transistor 43 corresponds to the length of the outer perimeter of the opening 121c in FIG. 4A.

The transistor 41 includes the conductive layer 111a, a conductive layer 112a, a semiconductor layer 113a, an insulating layer 105a, and a conductive layer 115a.

The conductive layer 111a has a function of one of the source electrode and the drain electrode of the transistor 41. The conductive layer 112a functions as the other of the source electrode and the drain electrode of the transistor 41 and functions as the wiring 35. The insulating layer 105a functions as a gate insulating layer of the transistor 41. The conductive layer 115a functions as the gate electrode of the transistor 41. The conductive layer 112a functioning as the wiring 35 includes a region extending in the Y direction.

As described above, the conductive layer 111a functions also as the other of the source electrode and the drain electrode of the transistor 43. Thus, in the semiconductor device illustrated in FIG. 4A to FIG. 4C, the conductive layer 111a has both a function of the other of the source electrode and the drain electrode of the transistor 43 and a function of the one of the source electrode and the drain electrode of the transistor 41.

The conductive layer 111a is provided over the semiconductor layer 113c, the layer 114, the insulating layer 107c, and the insulating layer 103c_3; the insulating layer 103a is provided over the insulating layer 103c_3 and the conductive layer 111a; and the conductive layer 112a is provided over the insulating layer 103a. The conductive layer 111a and the conductive layer 112a have an overlapping region with the insulating layer 103a therebetween. The insulating layer 103a and the conductive layer 112a have an opening 121a reaching the conductive layer 111a. In the example illustrated in FIG. 4A and FIG. 4B, in the X direction, a side end portion of the conductive layer 111a is positioned beyond a side end portion that is of the conductive layer 112a and does not face the opening 121a, i.e., the side end portion of the conductive layer 112a that does not face the opening 121a overlaps with the conductive layer 111a and the side end portion of the conductive layer 111a does not overlap with the conductive layer 112a; however, one embodiment of the present invention is not limited thereto. For example, the side end portion of the conductive layer 111a may be positioned within the side end portion of the conductive layer 112a that does not face the opening 121a.

FIG. 4(A) illustrates an example in which the opening 121a is circular in a plan view. When the top-surface shape of the opening 121a is a circle, the processing accuracy at the time of forming the opening 121a can be increased and the opening 121a having a minute size can be formed. Note that the top-surface shape of the opening 121a may be an ellipse or a polygon such as a quadrangle, for example.

The semiconductor layer 113a is provided to cover the opening 121a and to include a region positioned in the opening 121a. The semiconductor layer 113a includes a region in contact with the top surface of the conductive layer 112a, a region in contact with a side surface of the conductive layer 112a, a region in contact with a side surface of the insulating layer 103a, and a region in contact with the top surface of the conductive layer 111a. The semiconductor layer 113a has a shape along the top surface of the conductive layer 112a, the side surface of the conductive layer 112a, the side surface of the insulating layer 103a, and the top surface of the conductive layer 111a. Thus, the semiconductor layer 113a defines a concave portion at the position overlapping with the opening 121a.

The semiconductor layer 113a preferably covers a side end portion of the conductive layer 112a on the opening 121a side. For example, FIG. 4B and FIG. 4C illustrate a structure where a side end portion of the semiconductor layer 113a is positioned over the conductive layer 112a. In other words, a lower end portion of the semiconductor layer 113a is in contact with the top surface of the conductive layer 112a. In the example illustrated in FIG. 4A to FIG. 4C, the side end portion of the semiconductor layer 113a is positioned within the side end portion that is of the conductive layer 112a and does not face the opening 121a; i.e., the entire semiconductor layer 113a overlaps with the conductive layer 112a or the opening 121a. Furthermore, in the example illustrated in FIG. 4A to FIG. 4C, the side end portion of the semiconductor layer 113a is positioned within the side end portion of the conductive layer 111a; i.e., the entire semiconductor layer 113a overlaps with the conductive layer 111a.

In this specification and the like, an upper end portion refers to the uppermost portion of a side end portion, and a lower end portion refers to the lowermost portion of a side end portion. That is, the upper end portion and the lower end portion are each part of the side end portion.

Although the semiconductor layer 113a has a single-layer structure in FIG. 4B and FIG. 4C, one embodiment of the present invention is not limited thereto. The semiconductor layer 113a may have a stacked-layer structure of two or more layers.

The insulating layer 105a functioning as the gate insulating layer of the transistor 41 is provided to cover the opening 121a and to include a region positioned in the opening 121a. The insulating layer 105a is provided over the semiconductor layer 113a, the conductive layer 112a, and the insulating layer 103a. The insulating layer 105a includes a region in contact with the top surface of the semiconductor layer 113a, a region in contact with a side surface of the semiconductor layer 113a, a region in contact with the top surface of the conductive layer 112a, a region in contact with the side surface of the conductive layer 112a, and a region in contact with the top surface of the insulating layer 103a. The insulating layer 105a has a shape along the top surface of the semiconductor layer 113a, the side surface of the semiconductor layer 113a, the top surface of the conductive layer 112a, the side surface of the conductive layer 112a, and the top surface of the insulating layer 103a. Thus, the semiconductor layer 105a defines a concave portion at the position overlapping with the opening 121a.

The conductive layer 115a functioning as the gate electrode of the transistor 41 is provided over the insulating layer 105a and includes a region in contact with the top surface of the insulating layer 105a. The conductive layer 115a includes a region overlapping with the semiconductor layer 113a with the insulating layer 105a therebetween. Here, the semiconductor layer 113a can cover a side surface and the bottom surface of the conductive layer 115a with the insulating layer 105a therebetween in the opening 121a. For example, in the opening 121a, the insulating layer 105a includes a region in contact with the side surface of the semiconductor layer 113a, a region in contact with the top surface of the concave portion of the semiconductor layer 113a, a region in contact with the side surface of the conductive layer 115a, and a region in contact with the bottom surface of the conductive layer 115a.

As described above, in the transistor 41 illustrated in FIG. 4B and FIG. 4C, the semiconductor layer, the gate insulating layer, and the gate electrode are provided in the opening formed in the interlayer insulating layers. In other words, in the transistor 41, the semiconductor layer is provided to surround the gate electrode with the gate insulating layer therebetween in a plan view. Thus, the channel length direction of the transistor 41 can be a direction along the side surface of the insulating layer 103a in the opening 121a in a cross-sectional view. Accordingly, the channel length is not influenced by the performance of a light exposure apparatus used for manufacturing the transistor 41; hence, the channel length can have a value smaller than the resolution limit of the light exposure apparatus. Consequently, the transistor 41 can be reduced in size. For example, the opening 121a entirely includes a region overlapping with the conductive layer 111a, the semiconductor layer 113a, and the conductive layer 115a in the example illustrated in FIG. 4A; part of the opening 121a may not overlap with at least one of the conductive layer 111a, the semiconductor layer 113a, and the conductive layer 115a.

The transistor 41 is what is called a top-gate transistor including the gate electrode above the semiconductor layer 113a. Furthermore, since the bottom surface of the semiconductor layer 113a (the surface on the insulating layer 101 side) is in contact with the source electrode and the drain electrode, the transistor 41 can be referred to as a TGBC (Top Gate Bottom Contact) transistor.

As illustrated in FIG. 4B and FIG. 4C and the like, part of the insulating layer 105a is positioned outside the opening 121a, that is, over the conductive layer 112a and the insulating layer 103a. Here, the insulating layer 105a preferably covers the side end portion of the semiconductor layer 113a. This can prevent a short circuit between the conductive layer 115a and the semiconductor layer 113a. Moreover, the insulating layer 105a preferably covers the side end portion of the conductive layer 112a. This can prevent a short circuit between the conductive layer 115a and the conductive layer 112a.

Furthermore, as illustrated in FIG. 4B and FIG. 4C and the like, part of the conductive layer 115a is positioned outside the opening 121a, that is, over the conductive layer 112a and the insulating layer 103a. Although FIG. 4B and FIG. 4C and the like illustrate an example in which the side end portion of the conductive layer 115a is positioned within the side end portion of the semiconductor layer 113a, one embodiment of the present invention is not limited thereto. The side end portion of the conductive layer 115a may be positioned beyond the side end portion of the semiconductor layer 113a.

The insulating layer 107a is provided in contact with the top surface of the insulating layer 105a and the side surface of the conductive layer 115a. The insulating layer 131 is provided over the insulating layer 107a. The top surface of the conductive layer 115a, the uppermost surface of the insulating layer 107a, and the top surface of the insulating layer 131 are substantially equal in height from the substrate surface.

The insulating layer 107a has a function of inhibiting diffusion of impurities into the transistor 41, for example, a function of inhibiting diffusion of impurities into the semiconductor layer 113a. The insulating layer 131 functions as an interlayer insulating layer as described above.

The transistor 42 includes a conductive layer 111b, a conductive layer 112b, a semiconductor layer 113b, an insulating layer 105b, and a conductive layer 115b.

The conductive layer 111b functions as one of the source electrode and the drain electrode of the transistor 42. The conductive layer 112b functions as the other of the source electrode and the drain electrode of the transistor 42 and functions as the wiring 33W. The insulating layer 105b functions as a gate insulating layer of the transistor 42. The conductive layer 115b functions as the gate electrode of the transistor 42 and functions as the wiring 31W. The conductive layer 112b functioning as the wiring 33W includes a region extending in the Y direction. The conductive layer 115b functioning as the wiring 31W includes a region extending in the X direction.

As described above, the conductive layer 111b functions also as the other of the source electrode and the drain electrode of the transistor 41. Thus, in the semiconductor device illustrated in FIG. 4A to FIG. 4C, the conductive layer 111b has both a function of the other of the source electrode and the drain electrode of the transistor 41 and a function of the one of the source electrode and the drain electrode of the transistor 42.

The conductive layer 111b is provided over the conductive layer 115a, the insulating layer 107a, and the insulating layer 131. The conductive layer 111b includes at least a region in contact with the top surface of the conductive layer 115a. The insulating layer 103b is provided over the insulating layer 131 and the conductive layer 111b. The conductive layer 112b is provided over the insulating layer 103b. The conductive layer 111b and the conductive layer 112b have an overlapping region with the insulating layer 103b therebetween.

The insulating layer 103b and the conductive layer 112b have an opening 121b reaching the conductive layer 111b. FIG. 4A illustrates an example in which the opening 121b is circular in a plan view. Note that the shape of the opening 121b can be similar to the shape that the opening 121a can have.

The structure of the transistor 42 can be similar to the structure of the transistor 41 described above. The description of the structure of the transistor 41 can be referred to for the description of the structure of the transistor 42 by replacing the transistor 41, the insulating layer 103a, the insulating layer 105a, the conductive layer 111a, the conductive layer 112a, the semiconductor layer 113a, and the conductive layer 115a with the transistor 42, the insulating layer 103b, the insulating layer 105b, the conductive layer 111b, the conductive layer 112b, the semiconductor layer 113b, and the conductive layer 115b, respectively, and appropriately replacing words or sentences as necessary.

In this specification and the like, the insulating layer 103a, the insulating layer 103b, the insulating layer 103c_1, the insulating layer 103c_2, the insulating layer 103c_3, and the like may be collectively referred to as an insulating layer 103. The insulating layer 105a, the insulating layer 105b, and the insulating layer 105c may be collectively referred to as an insulating layer 105. The insulating layer 107a, the insulating layer 107b, and the insulating layer 107c may be collectively referred to as an insulating layer 107. The conductive layer 111a, the conductive layer 111b, and the conductive layer 111c may be collectively referred to as a conductive layer 111. The conductive layer 112a and the conductive layer 112b may be collectively referred to as a conductive layer 112. The semiconductor layer 113a, the semiconductor layer 113b, and the semiconductor layer 113c may be collectively referred to as a semiconductor layer 113. The conductive layer 115a, the conductive layer 115b, and the conductive layer 115c may be collectively referred to as a conductive layer 115. The opening 121a, the opening 121b, and the opening 121c may be collectively referred to as an opening 121.

The insulating layer 107b is provided over the conductive layer 115b and the insulating layer 105b. The insulating layer 107b can be provided to cover the top surface and a side surface of the conductive layer 115b. The insulating layer 107b has a function of inhibiting diffusion of impurities into the transistor 42, for example, a function of inhibiting diffusion of impurities into the semiconductor layer 113b.

As described above, in the semiconductor device of one embodiment of the present invention, the transistor 43, the transistor 41, and the transistor 42 are provided to be stacked in this order. In the transistor 43, the source electrode, the drain electrode, and the gate electrode are provided at different heights from the substrate surface to include an overlapping region, and the gate insulating layer and the semiconductor layer are provided such that the channel length direction is in the height direction. In each of the transistor 41 and the transistor 42, the semiconductor layer, the gate insulating layer, and the gate electrode are provided in the opening formed in the interlayer insulating layer, one of the source electrode and the drain electrode is provided under the opening, and the other of the source electrode and the drain electrode is provided over the interlayer insulating layer. Thus, the area occupied by the memory cell 21 in a plan view can be reduced. Accordingly, the memory cells can be reduced in size and highly integrated. Consequently, one embodiment of the present invention can provide a semiconductor device that can be reduced in size and increased in resolution.

In the cross-sectional views shown in FIG. 4B and FIG. 4C, boundaries of the layers cannot be clearly recognized in some cases. For example, a boundary between two insulating layers that are in contact with each other cannot be clearly recognized in some cases. A boundary between two conductive layers that are in contact with each other cannot be clearly recognized in some cases. A boundary between two semiconductor layers that are in contact with each other cannot be clearly recognized in some cases.

### <Structure Example 2 of Semiconductor Device>

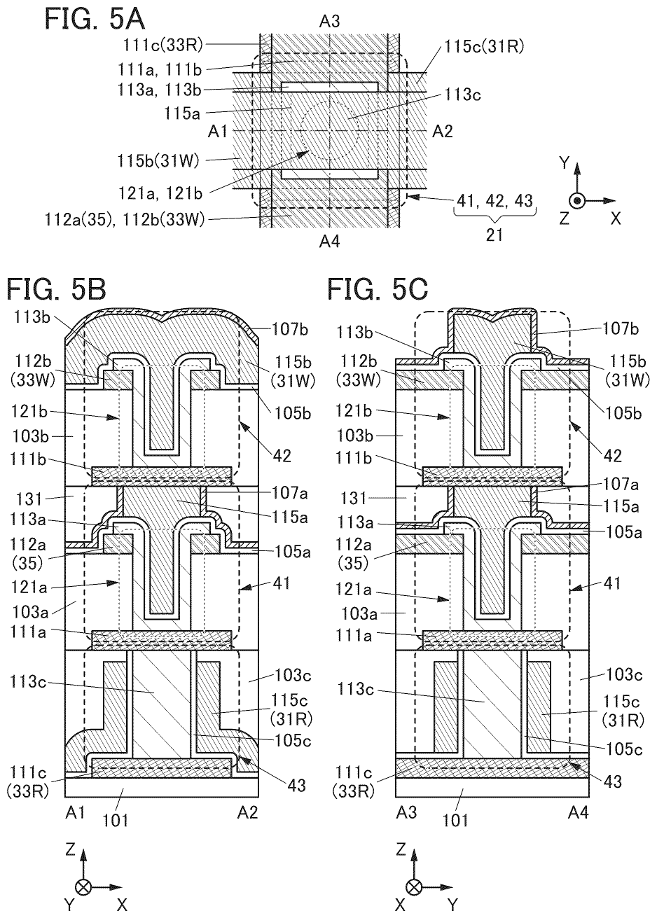

FIG. 5A to FIG. 5C illustrate another structure example of the semiconductor device 10 of one embodiment of the present invention, which is different from that illustrated in FIG. 4A to FIG. 4C. FIG. 5A is a plan view illustrating a structure example of part of the semiconductor device 10. FIG. 5B is a cross-sectional view along the dashed-dotted line A1-A2 in FIG. 5A, and FIG. 5C is a cross-sectional view along the dashed-dotted line A3-A4 in FIG. 5A.

The semiconductor device 10 illustrated in FIG. 5A to FIG. 5C is different from the semiconductor device 10 illustrated in FIG. 4A to FIG. 4C in the structure of the transistor 43.

The transistor 43 included in the semiconductor device 10 illustrated in FIG. 5A to FIG. 5C includes the conductive layer 111c, the conductive layer 111a, the semiconductor layer 113c, the insulating layer 105c, and the conductive layer 115c.

The conductive layer 111c has a function of one of the source electrode and the drain electrode of the transistor 43 and functions as the wiring 33R. The conductive layer 111a functions as the other of the source electrode and the drain electrode of the transistor 43. The insulating layer 105c functions as the gate insulating layer of the transistor 43. The conductive layer 115c functions as the gate electrode of the transistor 43 and functions as the wiring 31R. The conductive layer 111c functioning as the wiring 33R includes a region extending in the Y direction. The conductive layer 115c functioning as the wiring 31R includes a region extending in the X direction.

The conductive layer 111c is provided over the insulating layer 101, the insulating layer 105c is provided over the insulating layer 101 and the conductive layer 111c, the conductive layer 115c is provided over the insulating layer 105c, and the insulating layer 103c is provided over the insulating layer 105c and the conductive layer 115c. The semiconductor layer 113c is provided over the conductive layer 111c to have a columnar shape as illustrated in FIG. 5A to FIG. 5C. Although FIG. 5A illustrates an example in which the semiconductor layer 113c is circular in a plan view, one embodiment of the present invention is not limited thereto. The top-surface shape of the semiconductor layer 113c may be an ellipse or a polygon such as a quadrangle, for example.

The insulating layer 105c functioning as the gate insulating layer of the transistor 43 includes a region in contact with the side surface of the semiconductor layer 113c, the side surface and the bottom surface of the conductive layer 115c, the top surface and the side surface of the conductive layer 111c, and the side surface of the insulating layer 103c. The semiconductor layer 113c and the conductive layer 115c are provided to face each other with the insulating layer 105c therebetween in a cross-sectional view.

The conductive layer 115c functioning as the gate electrode of the transistor 43 is provided to cover the columnar semiconductor layer 113c with the insulating layer 105c therebetween. With this structure, a gate electric field (an electric field from the conductive layer 115c) can be applied to the semiconductor layer 113c from any direction in the XY plane.

The insulating layer 103c is provided to include a region in contact with the side surface of the conductive layer 115c, the top surface of the conductive layer 115c, the top surface of the insulating layer 105c, and the side surface of the insulating layer 105c.

The top surface of the semiconductor layer 113c, the uppermost surface of the insulating layer 105c, and the top surface of the insulating layer 103c are substantially equal in height from the substrate surface.

The conductive layer 111a functioning as the other of the source electrode and the drain electrode of the transistor 43 is provided in contact with the top surface of the semiconductor layer 113c, the uppermost surface of the insulating layer 105c, and the top surface of the insulating layer 103c. Moreover, the conductive layer 111a is provided to include a region overlapping with the conductive layer 111c functioning as the one of the source electrode and the drain electrode of the transistor 43.

The end portion of the conductive layer 111a is preferably substantially aligned with the end portion of the semiconductor layer 113c or positioned beyond the end portion of the semiconductor layer 113c. In such a case, the contact area between the conductive layer 111a and the semiconductor layer 113c can be increased, so that the contact resistance between the conductive layer 111a and the semiconductor layer 113c can be reduced.

In the transistor 43 illustrated in FIG. 5A to FIG. 5C, the source electrode, the drain electrode, and the gate electrode are provided at different heights from the substrate surface to overlap with each other, as in the transistor 43 illustrated in FIG. 4A to FIG. 4C. The gate electrode is sandwiched between the source electrode and the drain electrode. Thus, in the transistor 43, the channel length direction corresponds to the direction along the side surface of the insulating layer 105c in a cross-sectional view, and a drain current flows in this direction.

In the case where the transistor 43 has the above-described structure, the channel length of the transistor 43 can be controlled by adjusting the thickness of the semiconductor layer 113c positioned between the source electrode and the drain electrode in a cross-sectional view. Thus, the channel length of the transistor 43 can be smaller than the resolution limit of a light-exposure apparatus. Furthermore, the area occupied by the transistor in a plan view can be smaller than that occupied by a transistor having a structure in which a source electrode and a drain electrode are provided on the same plane.

As described above, in the transistor 43 illustrated in FIG. 5A to FIG. 5C, the gate electrode (the conductive layer 115c) is provided to surround the semiconductor layer 113c in a plan view. Thus, all regions of the semiconductor layer 113c that face the conductive layer 115c with the insulating layer 105c therebetween can serve as the channel formation region of the transistor 43. In this case, the channel width direction of the transistor 43 is parallel to the XY plane, and the channel width of the transistor 43 corresponds to the length of the outer perimeter of the semiconductor layer 113c in FIG. 5A.

The transistor 43 illustrated in FIG. 4A to FIG. 4C has a structure in which the semiconductor layer 113c is provided to cover the opening provided in the insulating layer, whereas the transistor 43 illustrated in FIG. 5A to FIG. 5C has a structure in which the semiconductor layer 113c is provided in a columnar shape. Thus, the transistor 43 having the structure illustrated in FIG. 5A to FIG. 5C can be referred to as a FIN-type transistor. In this manner, the transistor 43 included in the semiconductor device 10 of one embodiment of the present invention can have a variety of structures.

The description of the semiconductor device 10 illustrated in FIG. 4A to FIG. 4C can be referred to for the semiconductor device 10 illustrated in FIG. 5A to FIG. 5C other than the above-described differences (e.g., for the structures of the transistor 41 and the transistor 42).

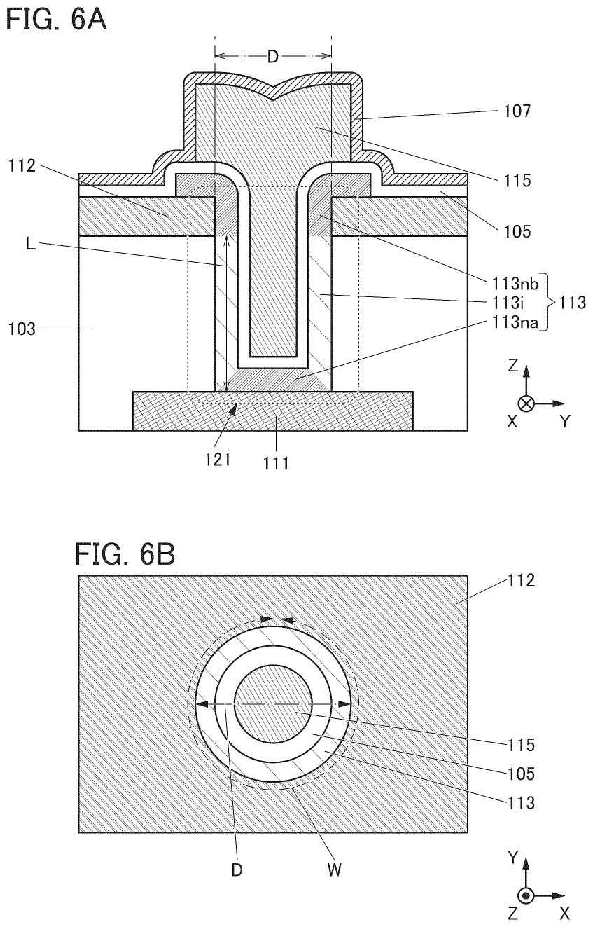

FIG. 6A is an enlarged view of the transistor 42 illustrated in FIG. 4C and the vicinity thereof. FIG. 6B is a cross-sectional view of the transistor illustrated in FIG. 6A cut along the XY plane to include the semiconductor layer 113 and the conductive layer 112. The structure illustrated in FIG. 6A and FIG. 6B can be applied to not only the transistor 42 but also the transistor 41.

As illustrated in FIG. 6A, the semiconductor layer 113 includes a region 113i, and a region 113na and a region 113nb provided such that the region 113i is sandwiched therebetween.

The region 113na is a region of the semiconductor layer 113 that is in contact with the conductive layer 111. At least part of the region 113na functions as one of the source region and the drain region of the transistor. The region 113nb is a region of the semiconductor layer 113 that is in contact with the conductive layer 112. At least part of the region 113nb functions as the other of the source region and the drain region of the transistor. As illustrated in FIG. 6B, the conductive layer 112 is in contact with the entire outer perimeter of the semiconductor layer 113. Thus, the other of the source region and the drain region of the transistor can be formed in the entire outer perimeter of a portion of the semiconductor layer 113 that is formed in the same layer as the conductive layer 112.

The region 113i is a region of the semiconductor layer 113 that is between the region 113na and the region 113nb. At least part of the region 113i functions as the channel formation region of the transistor. That is, the channel formation region of the transistor is positioned in a region of the semiconductor layer 113 that is between the conductive layer 111 and the conductive layer 112. It can be said that the channel formation region of the transistor is positioned in a region in contact with the insulating layer 103 or a region in the vicinity thereof in the semiconductor layer 113.

The channel length of the transistor is the distance between the source region and the drain region. In other words, the channel length of the transistor is determined by the thickness of the insulating layer 103 over the conductive layer 111. In FIG. 6A, a channel length L of the transistor is indicated by a solid double-headed arrow. In a cross-sectional view, the channel length L is the distance between an end portion of the region where the semiconductor layer 113 is in contact with the conductive layer 111 and an end portion of the region where the semiconductor layer 113 is in contact with the conductive layer 112. That is, the channel length L corresponds to the length of a side surface of the insulating layer 103 on the opening 121 side in a cross-sectional view.

In a planar transistor, the channel length is determined by the light exposure limit of photolithography, for example. Meanwhile, in the present invention, the channel length can be determined by the thickness of the insulating layer 103. Thus, the transistor can have an extremely small channel length less than or equal to the light exposure limit of photolithography (e.g., greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, or greater than or equal to 5 nm and less than or equal to 10 nm). Accordingly, the transistor can have a higher on-state current and improved frequency characteristics. This can increase the read speed and the write speed of the memory cell, thereby providing a semiconductor device with high operating speed.

Although the details will be described later, an OS transistor has higher resistance against a short-channel effect than a Si transistor. Furthermore, as described above, the transistor having the structure illustrated in FIG. 6A and FIG. 6B, for example, can have a shorter channel length than a planar transistor. Thus, in the case where the transistor has the structure illustrated in FIG. 6A and FIG. 6B, for example, a metal oxide is preferably used for the semiconductor layer 113. Note that a material other than a metal oxide, such as silicon, may be used for the semiconductor layer 113.

As described above, the channel formation region, the source region, and the drain region can be formed in the opening 121. Thus, the area occupied by the transistor can be reduced as compared with a planar transistor in which a channel formation region, a source region, and a drain region are provided separately on the XY plane. This allows high integration of the semiconductor device; thus, the memory capacity per unit area can be increased.

As illustrated in FIG. 6B, the semiconductor layer 113, the insulating layer 105, and the conductive layer 115 are provided concentrically on the XY plane including the channel formation region of the semiconductor layer 113. Thus, the side surface of the conductive layer 115 that is provided at the center faces the side surface of the semiconductor layer 113 with the insulating layer 105 therebetween. That is, in a plan view, the entire inner perimeter of the semiconductor layer 113 serves as the channel formation region. In this case, the channel width of the transistor depends on the length of the outer perimeter of the semiconductor layer 113, for example. In other words, the channel width of the transistor depends on the maximum width of the opening 121 (the diameter in the case where the opening 121 is circular in a plan view). In FIG. 6A and FIG. 6B, a maximum width D of the opening 121 is indicated by a dashed double-dotted double-headed arrow. In FIG. 6B, a channel width W of the transistor is indicated by a dashed-dotted double-headed arrow. By increasing the maximum width D of the opening 121, the channel width per unit area can be increased and the on-state current can be increased.

The maximum width D of the opening 121 is preferably, for example, greater than or equal to 5 nm and less than or equal to 100 nm, greater than or equal to 10 nm and less than or equal to 60 nm, greater than or equal to 20 nm and less than or equal to 50 nm, greater than or equal to 20 nm and less than or equal to 40 nm, or greater than or equal to 20 nm and less than or equal to 30 nm. In the case where the opening 121 is circular in a plan view, the maximum width D of the opening 121 corresponds to the diameter of the opening 121, and the channel width W can be calculated to be “D×π”.

In the semiconductor device of one embodiment of the present invention, the channel length L of the transistor is preferably shorter than at least the channel width W of the transistor. The channel length L of the transistor in one embodiment of the present invention is greater than or equal to 0.1 times and less than or equal to 0.99 times, preferably greater than or equal to 0.5 times and less than or equal to 0.8 times the channel width W of the transistor. Such a structure enables the transistor to have favorable electrical characteristics and high reliability.

By providing the semiconductor layer 113, the insulating layer 105, and the conductive layer 115 concentrically, the distance between the conductive layer 115 and the semiconductor layer 113 becomes substantially uniform. Thus, a gate electric field can be substantially uniformly applied to the semiconductor layer 113.

The sidewall of the opening 121 is preferably perpendicular to the top surface of the conductive layer 111, for example. With such a structure, the semiconductor device can be reduced in size or highly integrated. Note that the sidewall of the opening 121 may be tapered.

The components of the transistors included in the memory cell will be described below.

### [Components of Transistor]

As the semiconductor layer 113, a single layer or stacked layers of any of the metal oxides described in the later-described section [Metal oxide] can be used. As the semiconductor layer 113, a single layer or stacked layers of any of the materials, such as silicon, described in the later-described section [Other semiconductor materials] can be used.

In the case of using a metal oxide for the semiconductor layer 113, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be specifically used for the semiconductor layer 113. Note that a composition in the neighborhood includes the range of +30% of an intended atomic ratio. Gallium is preferably used as the element M.

When a film of the metal oxide is formed by a sputtering method, the above atomic ratio is not limited to the atomic ratio of the formed film of the metal oxide and may be the atomic ratio of a sputtering target used for forming the film of the metal oxide.

For analysis of the composition of the metal oxide used for the semiconductor layer 113, it is possible to use, for example, energy dispersive X-ray spectroscopy (EDX), X-ray photoelectron spectroscopy (XPS), inductively coupled plasma-mass spectrometry (ICP-MS), or inductively coupled plasma-atomic emission spectroscopy (ICP-AES). Alternatively, any of these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

For the formation of the metal oxide, an atomic layer deposition (ALD) method can be suitably used.

Alternatively, the metal oxide may be formed by a sputtering method or a chemical vapor deposition (CVD) method.

In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

It is preferable that the metal oxide used for the semiconductor layer 113 have crystallinity. Examples of an oxide semiconductor having crystallinity include a CAAC-OS (C-axis Aligned Crystalline Oxide Semiconductor), an nc-OS (nanocrystalline Oxide Semiconductor), a polycrystalline oxide semiconductor, and a single crystal oxide semiconductor. For the semiconductor layer 113, a CAAC-OS or an nc-OS is preferably used, and a CAAC-OS is particularly preferably used.

A CAAC-OS preferably includes a plurality of layered crystal regions and the c-axis is preferably aligned in a normal direction of a surface where the CAAC-OS is formed. For example, the semiconductor layer 113 preferably includes layered crystals that are substantially parallel to the sidewall of the opening 121, particularly the side surface of the insulating layer 103. With such a structure, the layered crystals of the semiconductor layer 113 are formed substantially in parallel with the channel length direction of the transistor, so that the on-state current of the transistor can be increased.

A CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear grain boundary is difficult to observe in a CAAC-OS; thus, it can be said that a reduction in electron mobility due to the grain boundary is less likely to occur. Thus, a metal oxide including a CAAC-OS is physically stable. Therefore, a metal oxide including a CAAC-OS is resistant to heat and has high reliability.

When a metal oxide having crystallinity, such as a CAAC-OS, is used for the semiconductor layer 113, oxygen extraction from the semiconductor layer 113 by the source electrode or the drain electrode can be inhibited. This can inhibit oxygen extraction from the semiconductor layer 113 even when heat treatment is performed; thus, the transistor is stable with respect to high temperatures in a manufacturing process (what is called thermal budget).

The crystallinity of the semiconductor layer 113 can be analyzed with X-ray diffraction (XRD), a transmission electron microscope (TEM), or electron diffraction (ED), for example. Alternatively, any of these methods may be combined for the analysis.

The thickness of the semiconductor layer 113 is preferably greater than or equal to 1 nm and less than or equal to 20 nm, greater than or equal to 3 nm and less than or equal to 15 nm, greater than or equal to 5 nm and less than or equal to 12 nm, or greater than or equal to 5 nm and less than or equal to 10 nm., for example

Although FIG. 4B, FIG. 4C, and FIG. 6A illustrate the semiconductor layer 113 having a single-layer structure, the present invention is not limited thereto. The semiconductor layer 113 may have a stacked-layer structure of a plurality of oxide layers with different chemical compositions. For example, a structure in which a plurality of kinds of metal oxides selected from the above-described metal oxides are stacked as appropriate may be used.

As the insulating layer 105 functioning as the gate insulating layer, a single layer or stacked layers of any of the insulators described in the later-described section [Insulator] can be used. For the insulating layer 105, silicon oxide or silicon oxynitride can be used, for example. Silicon oxide and silicon oxynitride are preferable because they are thermally stable.

For the insulating layer 105, any of the materials with a high relative permittivity, that is, high-k materials, described in the later-described section [Insulator] may be used. For example, hafnium oxide, aluminum oxide, or the like may be used.

The thickness of the insulating layer 105 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 105 preferably includes a region having the above-described thickness.

The concentration of impurities such as water and hydrogen in the insulating layer 105 is preferably reduced. This can inhibit entry of impurities such as water and hydrogen into the channel formation region of the semiconductor layer 113.

Although FIG. 4B, FIG. 4C, and FIG. 6A illustrate the insulating layer 105 having a single-layer structure, the present invention is not limited thereto. The insulating layer 105 may have a stacked-layer structure.

As the conductive layer 115 functioning as the gate electrode, a single layer or stacked layers of any of the conductors described in the later-described section [Conductor] can be used. For example, a conductive material with high conductivity, such as tungsten, aluminum, or copper, can be used for the conductive layer 115.

A conductive material that is less likely to be oxidized, a conductive material having a function of inhibiting diffusion of oxygen, or the like is preferably used for the conductive layer 115. Examples of such conductive materials include a conductive material containing nitrogen (e.g., titanium nitride and tantalum nitride) and a conductive material containing oxygen (e.g., ruthenium oxide). In that case, a decrease in the conductivity of the conductive layer 115 can be inhibited. A semiconductor with high electrical conductivity, typified by polycrystalline silicon containing an impurity element such as phosphorus, or silicide such as nickel silicide may be used for the conductive layer 115.

Although FIG. 4B, FIG. 4C, and FIG. 6A illustrate the conductive layer 115 having a single-layer structure, the present invention is not limited thereto. The conductive layer 115 may have a stacked-layer structure.

As the conductive layer 111, a single layer or stacked layers of any of the conductors described in the later-described section [Conductor] can be used. A conductive material that is less likely to be oxidized, a conductive material having a function of inhibiting diffusion of oxygen, or the like is preferably used for the conductive layer 111. For example, titanium nitride, tantalum nitride, or the like can be used. For another example, a structure in which tantalum nitride is stacked over titanium nitride may be used. In this case, titanium nitride is in contact with the insulating layer 101, the insulating layer 103c, the insulating layer 131, and the like and tantalum nitride is in contact with the semiconductor layer 113. Such a structure can inhibit excessive oxidation of the conductive layer 111 due to the semiconductor layer 113. In the case of using an oxide insulator for the insulating layer 101, the insulating layer 103c, the insulating layer 131, and the like, the conductive layer 111 can be inhibited from being excessively oxidized by these insulating layers. Alternatively, the conductive layer 111 may employ a structure in which tungsten is stacked over titanium nitride, for example.

The conductive layer 111 includes a region in contact with the semiconductor layer 113 and thus is preferably formed using a conductive material containing oxygen that is described in the later-described section [Conductor]. When a conductive material containing oxygen is used for the conductive layer 111, the conductive layer 111 can maintain its conductivity even when absorbing oxygen. As the conductive layer 111, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

Although FIG. 4B, FIG. 4C, and FIG. 6A illustrate a structure in which the top surface of the conductive layer 111 is flat, the present invention is not limited to the structure. For example, the top surface of the conductive layer 111 may have a concave portion overlapping with the opening 121. When at least parts of the semiconductor layer 113, the insulating layer 105, and the conductive layer 115 are formed to fill the concave portion, a gate electric field of the conductive layer 115 can be easily applied to a portion of the semiconductor layer 113 near the conductive layer 111.

As the conductive layer 112, a single layer or stacked layers of any of the conductors described in the later-described section [Conductor] can be used. For example, a conductive material with high conductivity, such as tungsten, aluminum, or copper, can be used for the conductive layer 112.

A conductive material that is less likely to be oxidized, a conductive material having a function of inhibiting diffusion of oxygen, or the like is preferably used for the conductive layer 112, as in the case of the conductive layer 111 and the conductive layer 115. For example, titanium nitride, tantalum nitride, or the like can be used. Such a structure can inhibit excessive oxidation of the conductive layer 112 due to the semiconductor layer 113. A semiconductor with high electrical conductivity, typified by polycrystalline silicon containing an impurity element such as phosphorus, or silicide such as nickel silicide may be used for the conductive layer 112, as in the case of the conductive layer 115.

For another example, a structure in which tungsten is stacked over titanium nitride may be used. When tungsten is stacked over titanium nitride in this manner, the conductivity of the conductive layer 112 can be improved.

In the case where the conductive layer 112 has a structure where a first conductive layer and a second conductive layer are stacked, the first conductive layer may be formed using a conductive material with high conductivity and the second conductive layer may be formed using a conductive material containing oxygen, for example. By using the conductive material containing oxygen for the second conductive layer whose region in contact with the insulating layer 105 is larger in area than that of the first conductive layer, oxygen contained in the insulating layer 105 can be inhibited from diffusing into the first conductive layer of the conductive layer 112. For example, tungsten is preferably used for the first conductive layer of the conductive layer 112, and indium tin oxide to which silicon is added is preferably used for the second conductive layer of the conductive layer 112.

When the semiconductor layer 113 is in contact with the conductive layer 111, a metal compound or oxygen vacancies are formed in the semiconductor layer 113, and the resistance of the region 113na in the semiconductor layer 113 is reduced. A reduction in the resistance of the semiconductor layer 113 in contact with the conductive layer 111 can reduce the contact resistance between the semiconductor layer 113 and the conductive layer 111. Similarly, when the semiconductor layer 113 is in contact with the conductive layer 112, the resistance of the region 113nb in the semiconductor layer 113 is reduced. Thus, the contact resistance between the semiconductor layer 113 and the conductive layer 112 can be reduced.

The insulating layer 101, the insulating layer 103, and the insulating layer 131 functioning as interlayer insulating layers preferably have a low relative permittivity. When a material with a low relative permittivity is used for the interlayer insulating layers, parasitic capacitance generated between wirings can be reduced. As the insulating layer 101, the insulating layer 103, and the insulating layer 131, a single layer or stacked layers of any of the insulators each including a material with a low relative permittivity described in the later-described section [Insulator] can be used. In particular, silicon oxide and silicon oxynitride are preferable because they are thermally stable.

The concentration of impurities such as water and hydrogen in each of the insulating layer 101, the insulating layer 103, and the insulating layer 131 is preferably reduced. This can inhibit entry of impurities such as water and hydrogen into the channel formation region of the semiconductor layer 113.

The insulating layer 103 positioned in the vicinity of the channel formation region of the semiconductor layer 113 preferably include oxygen that is released by heating (hereinafter sometimes referred to as excess oxygen). When heat treatment is performed on the insulating layer 103 including excess oxygen, oxygen is supplied from the insulating layer 103 to the channel formation region of the semiconductor layer 113, so that oxygen vacancies and defects that are oxygen vacancies into which hydrogen enters (hereinafter sometimes referred to as VoH) can be reduced in the semiconductor layer 113. Accordingly, the transistor can have stable electrical characteristics and higher reliability.

For the insulating layer 103, any of the insulators having a function of capturing or fixing hydrogen described in the later-described [Insulator] may be used. With such a structure, hydrogen in the semiconductor layer 113 can be captured or fixed, so that the hydrogen concentration of the semiconductor layer 113 can be reduced. For the insulating layer 103, magnesium oxide, aluminum oxide, or the like can be used.

Although FIG. 4B, FIG. 4C, and FIG. 6A show that the insulating layer 103 is a single layer, the present invention is not limited thereto. The insulating layer 103 may have a stacked-layer structure.

For the insulating layer 107, any of the insulators with a barrier property against hydrogen described in the later-described section [Insulator] is preferably used. In that case, hydrogen can be inhibited from diffusing from outside the transistor to the semiconductor layer 113 through the insulating layer 105. A silicon nitride film and a silicon nitride oxide film can be suitably used for the insulating layer 107 because they release fewer impurities (e.g., water and hydrogen) and are less likely to transmit oxygen and hydrogen.

For the insulating layer 107, any of the insulators having a function of capturing or fixing hydrogen described in the later-described section [Insulator] is preferably used. With such a structure, diffusion of hydrogen into the semiconductor layer 113 from above the insulating layer 107 can be inhibited, and hydrogen in the semiconductor layer 113 can be captured or fixed, whereby the hydrogen concentration of the semiconductor layer 113 can be reduced. For the insulating layer 107, magnesium oxide, aluminum oxide, hafnium oxide, or the like can be used. Alternatively, for example, a stacked-layer film of aluminum oxide and silicon nitride over the aluminum oxide may be used for the insulating layer 107.

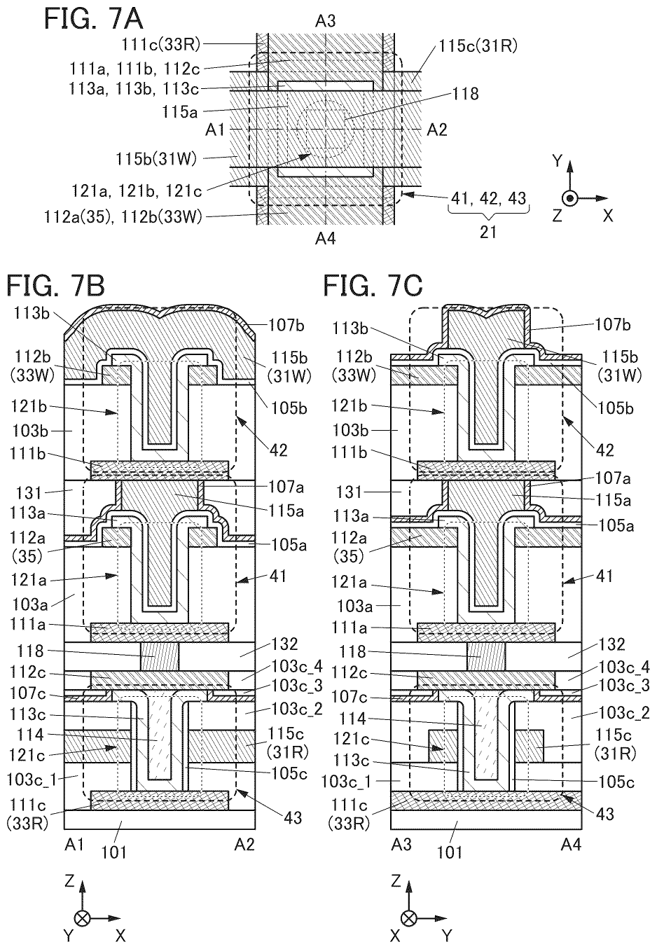

Although the insulating layer 107 is formed over the top surface of the transistor in the structure illustrated in FIG. 4B, FIG. 4C, and FIG. 6A, one embodiment of the present invention is not limited thereto. For example, the insulating layer 107 or an insulating layer having a function or a material similar to that of the insulating layer 107 may be formed on a side surface and the bottom surface of the transistor to surround the transistor. Alternatively, the insulating layer 107 may be formed on the top surfaces, side surfaces, and bottom surfaces of the transistor 43, the transistor 41, and the transistor 42 to surround the transistor 43, the transistor 41, and the transistor 42. Such a structure can inhibit entry of impurities (e.g., water and hydrogen) into the transistor 43, the transistor 41, and the transistor 42.

<Structure example 3 of semiconductor device>FIG. 7A to FIG. 7C illustrate another structure example of the semiconductor device 10 of one embodiment of the present invention, which is different from the above-described structures. FIG. 7A is a plan view illustrating a structure example of part of the semiconductor device 10. FIG. 7B is a cross-sectional view along the dashed-dotted line A1-A2 in FIG. 7A, and FIG. 7C is a cross-sectional view along the dashed-dotted line A3-A4 in FIG. 7A.

The semiconductor device 10 illustrated in FIG. 7A to FIG. 7C is different from the semiconductor device 10 illustrated in FIG. 4A to FIG. 4C in that a conductive layer functioning as the other of the source electrode and the drain electrode of the transistor 43 and a conductive layer functioning as the one of the source electrode and the drain electrode of the transistor 41 are independently provided and the two conductive layers are connected to each other through a conductive layer functioning as a plug.

In the transistor 43 included in the semiconductor device 10 illustrated in FIG. 7A to FIG. 7C, a conductive layer 112c functions as the other of the source electrode and the drain electrode. For the conductive layer 112c, any of the above-described materials that can be used for the conductive layer 111 or the conductive layer 112 can be used.

The conductive layer 112c is provided to be in contact with the top surfaces of the semiconductor layer 113c, the layer 114, the insulating layer 107c, and the insulating layer 103c_3 and to include a region overlapping with the conductive layer 111c. An insulating layer 103c_4 is provided over the insulating layer 103c_3 in a region not overlapping with the conductive layer 112c. The top surface of the conductive layer 112c and the top surface of the insulating layer 103c_4 are substantially level with respect to the substrate.

An insulating layer 132 is provided over the conductive layer 112c and the insulating layer 103c_4. An opening is provided in the insulating layer 132 in a region overlapping with the conductive layer 112c, and a conductive layer 118 is provided to fill the opening. The top surface of the conductive layer 118 and the top surface of the insulating layer 132 are preferably substantially level with respect to the substrate. The top surface of the conductive layer 112c is in contact with the bottom surface of the conductive layer 118. The top surface of the conductive layer 118 is in contact with the bottom surface of the conductive layer 111a. The insulating layer 103c 4 and the insulating layer 132 each function as an interlayer insulating layer. For the insulating layer 103c_4 and the insulating layer 132, any of the above-described materials that can be used for the insulating layer 101, the insulating layer 103, and the insulating layer 131 can be used. The conductive layer 118 has a function of a plug that electrically connects the conductive layer 112c functioning as the other of the source electrode and the drain electrode of the transistor 43 and the conductive layer 111a functioning as the one of the source electrode and the drain electrode of the transistor 41. For the conductive layer 118, any of the above-described conductive materials with high conductivity that can be used for the conductive layer 115 can be used, for example. In order to prevent oxidation of the conductive layer 118 due to oxygen contained in the insulating layer 132 and the like, any of the above-described conductive materials that are less likely to be oxidized or have a function of inhibiting diffusion of oxygen, which can be used for the conductive layer 111, the conductive layer 112, and the conductive layer 115, may be provided in contact with the side surface of the insulating layer 132 and a conductive material with high conductivity may be provided on the inner side of the conductive material.

The description of the semiconductor device 10 illustrated in FIG. 4A to FIG. 4C can be referred to for the semiconductor device 10 illustrated in FIG. 7A to FIG. 7C other than the above-described differences.

### <Structure Example 4 of Semiconductor Device>

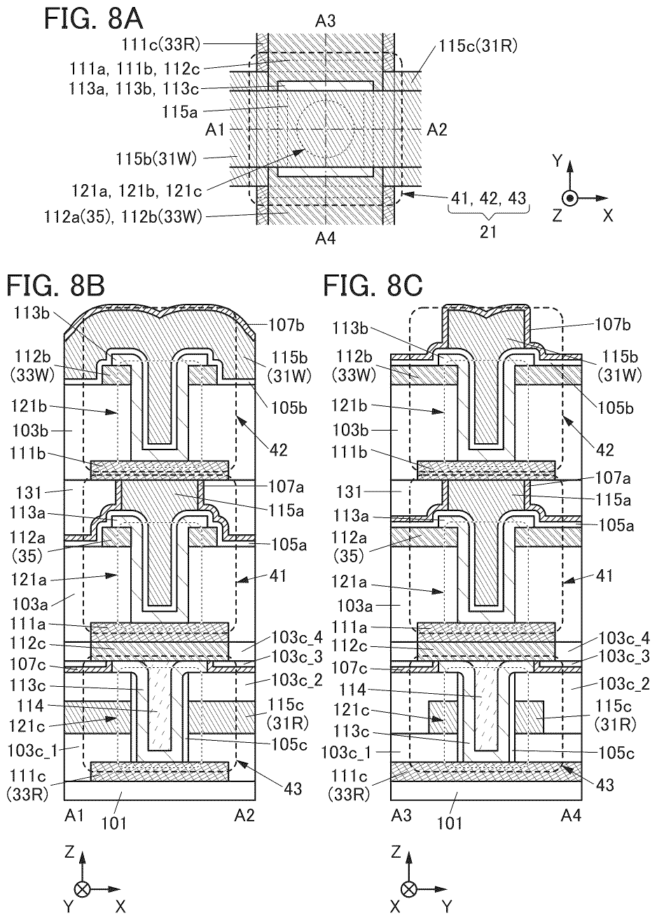

FIG. 8A to FIG. 8C illustrate another structure example of the semiconductor device 10 of one embodiment of the present invention, which is different from the above-described structures.

FIG. 8A is a plan view illustrating a structure example of part of the semiconductor device 10. FIG. 8B is a cross-sectional view along the dashed-dotted line A1-A2 in FIG. 8A, and FIG. 8C is a cross-sectional view along the dashed-dotted line A3-A4 in FIG. 8A.

The semiconductor device 10 illustrated in FIG. 8A to FIG. 8C is different from the semiconductor device 10 illustrated in FIG. 7A to FIG. 7C in that the conductive layer functioning as the other of the source electrode and the drain electrode of the transistor 43 (the conductive layer 112c) and the conductive layer functioning as the one of the source electrode and the drain electrode of the transistor 41 (the conductive layer 111a) are directly connected to each other without a plug (i.e., the top surface of the conductive layer 112c is in contact with the bottom surface of the conductive layer 111a).

The manufacturing process of the semiconductor device 10 illustrated in FIG. 8A to FIG. 8C, which has the above-described structure, can be simplified as compared with the manufacturing process of the semiconductor device 10 illustrated in FIG. 7A to FIG. 7C.

The description of the semiconductor device 10 illustrated in FIG. 4A to FIG. 4C can be referred to for the semiconductor device 10 illustrated in FIG. 8A to FIG. 8C other than the above-described difference.

### <Structure Example 5 of Semiconductor Device>

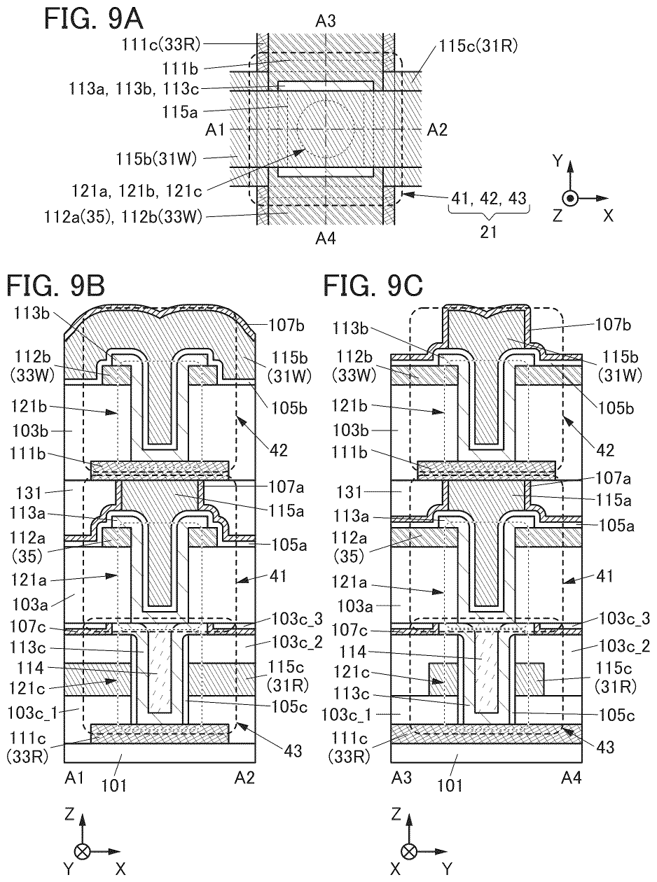

FIG. 9A to FIG. 9C illustrate another structure example of the semiconductor device 10 of one embodiment of the present invention, which is different from the above-described structures.

FIG. 9A is a plan view illustrating a structure example of part of the semiconductor device 10. FIG. 9B is a cross-sectional view along the dashed-dotted line A1-A2 in FIG. 9A, and FIG. 9C is a cross-sectional view along the dashed-dotted line A3-A4 in FIG. 9A.

The semiconductor device 10 illustrated in FIG. 9A to FIG. 9C is different from the semiconductor device 10 illustrated in FIG. 4A to FIG. 4C in not including the conductive layer 111a functioning as the other of the source electrode and the drain electrode of the transistor 43 and the one of the source electrode and the drain electrode of the transistor 41.

In the semiconductor device 10 illustrated in FIG. 9A to FIG. 9C, the bottom surface of the semiconductor layer 113a (the surface on the transistor 43 side) in the transistor 41 is directly in contact with part of the top surface of the semiconductor layer 113c in the transistor 43 and the top surface of the layer 114.

The manufacturing process of the semiconductor device 10 illustrated in FIG. 9A to FIG. 9C, which has the above-described structure, can be simplified as compared with the manufacturing process of the semiconductor device 10 illustrated in FIG. 4A to FIG. 4C.

The description of the semiconductor device 10 illustrated in FIG. 4A to FIG. 4C can be referred to for the semiconductor device 10 illustrated in FIG. 9A to FIG. 9C other than the above-described differences.

### <Structure Example 6 of Semiconductor Device>

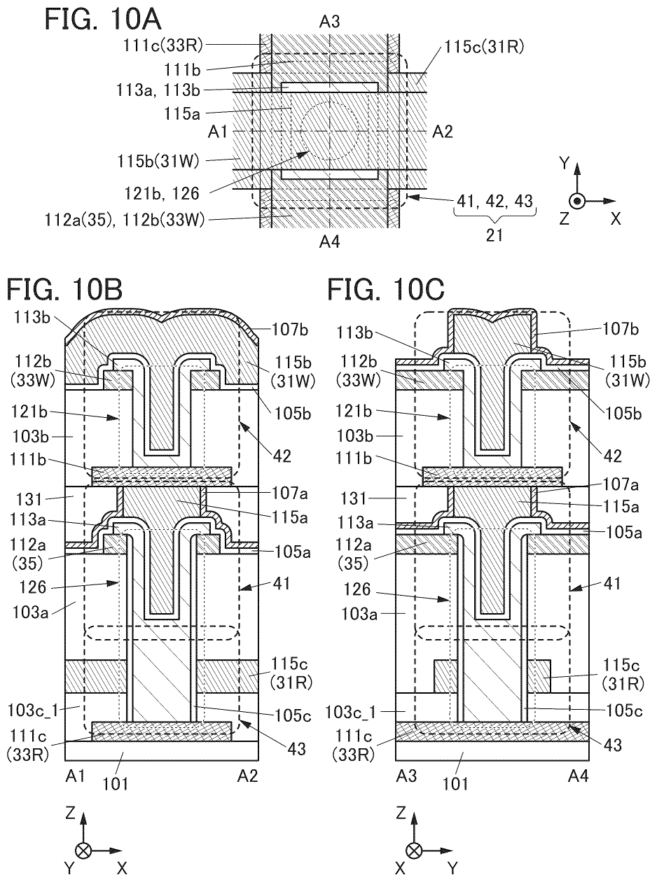

FIG. 10A to FIG. 10C illustrate another structure example of the semiconductor device 10 of one embodiment of the present invention, which is different from the above-described structures. FIG. 10A is a plan view illustrating a structure example of part of the semiconductor device 10. FIG. 10B is a cross-sectional view along the dashed-dotted line A1-A2 in FIG. 10A, and FIG. 10C is a cross-sectional view along the dashed-dotted line A3-A4 in FIG. 10A.

The semiconductor device 10 illustrated in FIG. 10A to FIG. 10C is different from the semiconductor device 10 illustrated in FIG. 9A to FIG. 9C in that one opening 126 is formed collectively in the transistor 43 and the transistor 41 without separately providing the opening 121c included in the transistor 43 and the opening 121a included in the transistor 41.

In the semiconductor device 10 illustrated in FIG. 10A to FIG. 10C, the opening 126 reaching the conductive layer 111c is provided in the insulating layer 103c_1, the conductive layer 115c, the insulating layer 103a, and the conductive layer 112a. The insulating layer 105c is provided in contact with the side surface of the insulating layer 103c_1, the side surface of the conductive layer 115c, the side surface of the insulating layer 103a, and the side surface of the conductive layer 112a on the opening 126 side. The semiconductor layer 113a is provided to fill at least part of the opening 126 with the insulating layer 105c therebetween. The conductive layer 115a is provided over the insulating layer 105a to fill a concave portion over the semiconductor layer 113a in the opening 126.

The manufacturing process of the semiconductor device 10 illustrated in FIG. 10A to FIG. 10C, which has the above-described structure, can be simplified as compared with the manufacturing process of the semiconductor device 10 illustrated in FIG. 9A to FIG. 9C.

The description of the semiconductor device 10 illustrated in FIG. 4A to FIG. 4C can be referred to for the semiconductor device 10 illustrated in FIG. 10A to FIG. 10C other than the above-described differences.

### <Structure Example 7 of Semiconductor Device>

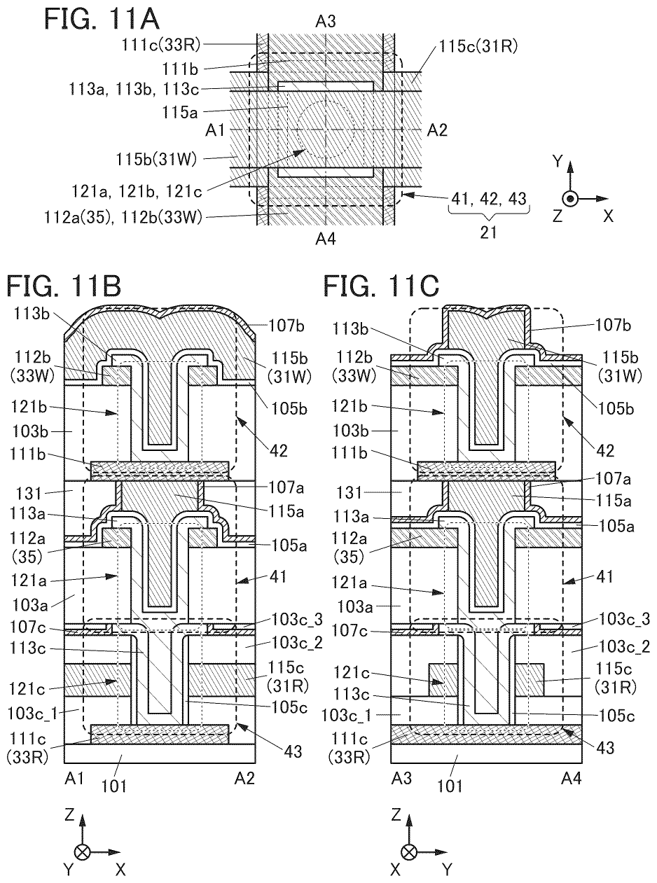

FIG. 11A to FIG. 11C illustrate another structure example of the semiconductor device 10 of one embodiment of the present invention, which is different from the above-described structures. FIG. 11A is a plan view illustrating a structure example of part of the semiconductor device 10. FIG. 11B is a cross-sectional view along the dashed-dotted line A1-A2 in FIG. 11A, and FIG. 11C is a cross-sectional view along the dashed-dotted line A3-A4 in FIG. 11A.

The semiconductor device 10 illustrated in FIG. 11A to FIG. 11C is different from the semiconductor device 10 illustrated in FIG. 9A to FIG. 9C in that the semiconductor layer 113a included in the transistor 41 is formed to fill a concave portion over the semiconductor layer 113c included in the transistor 43.

In the semiconductor device 10 illustrated in FIG. 11A to FIG. 11C, the semiconductor layer 113a included in the transistor 41 is provided at the place where the layer 114 included in the transistor 43 of the semiconductor device 10 illustrated in FIG. 9A to FIG. 9C is provided.

The manufacturing process of the semiconductor device 10 illustrated in FIG. 11A to FIG. 11C, which has the above-described structure, can be simplified as compared with the manufacturing process of the semiconductor device 10 illustrated in FIG. 9A to FIG. 9C.

The description of the semiconductor device 10 illustrated in FIG. 4A to FIG. 4C can be referred to for the semiconductor device 10 illustrated in FIG. 11A to FIG. 11C other than the above-described difference.

### <Structure Example 8 of Semiconductor Device>

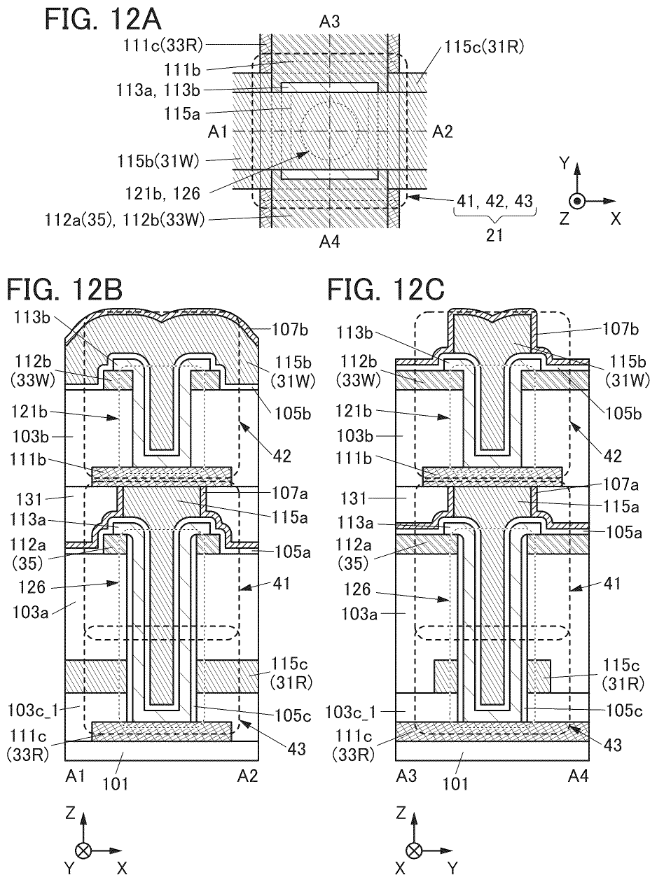

FIG. 12A to FIG. 12C illustrate another structure example of the semiconductor device 10 of one embodiment of the present invention, which is different from the above-described structures. FIG. 12A is a plan view illustrating a structure example of part of the semiconductor device 10. FIG. 12B is a cross-sectional view along the dashed-dotted line A1-A2 in FIG. 12A, and FIG. 12C is a cross-sectional view along the dashed-dotted line A3-A4 in FIG. 12A.

The semiconductor device 10 illustrated in FIG. 12A to FIG. 12C is the same as the semiconductor device 10 illustrated in FIG. 10A to FIG. 10C in that the opening 126 reaching the conductive layer 111c is provided in the insulating layer 103c_1, the conductive layer 115c, the insulating layer 103a, and the conductive layer 112a. Meanwhile, the semiconductor device 10 illustrated in FIG. 12A to FIG. 12C is different from the semiconductor device 10 illustrated in FIG. 10A to FIG. 10C in that the bottom surface of the conductive layer 115a included in the transistor 41 is positioned below the conductive layer 115c included in the transistor 43 (on the conductive layer 111c side).

In the semiconductor device 10 illustrated in FIG. 12A to FIG. 12C, the insulating layer 105c is provided in contact with the side surface of the insulating layer 103c_1, the side surface of the conductive layer 115c, the side surface of the insulating layer 103a, and the side surface of the conductive layer 112a on the opening 126 side. The semiconductor layer 113a is provided in contact with the top surface of the conductive layer 112a, the side surface of the insulating layer 105c, and the top surface of the conductive layer 111c. The insulating layer 105a is provided to cover the semiconductor layer 113a. Here, a concave portion reflecting the shape of the opening 126 is formed over the semiconductor layer 113a and the insulating layer 105a. The conductive layer 115a is provided to fill the concave portion.

In the semiconductor device 10 illustrated in FIG. 12A to FIG. 12C, which has the above-described structure, a region sandwiched between the conductive layer 115a and the conductive layer 115c is formed in the semiconductor layer 113a. The region is a region to which both the electric field from the conductive layer 115a and the electric field from the conductive layer 115c are applied. Thus, the semiconductor device 10 illustrated in FIG. 12A to FIG. 12C can have higher carrier controllability in the semiconductor layer 113a than the semiconductor device 10 illustrated in FIG. 10A to FIG. 10C.

The description of the semiconductor device 10 illustrated in FIG. 4A to FIG. 4C can be referred to for the semiconductor device 10 illustrated in FIG. 12A to FIG. 12C other than the above-described differences.

The semiconductor device of one embodiment of the present invention may include a memory cell including a capacitor, as illustrated in FIG. 2B, FIG. 3B, and FIG. 3C. Structure examples of a semiconductor device including a capacitor that is one embodiment of the present invention will be described below.

### <Structure Example 9 of Semiconductor Device>

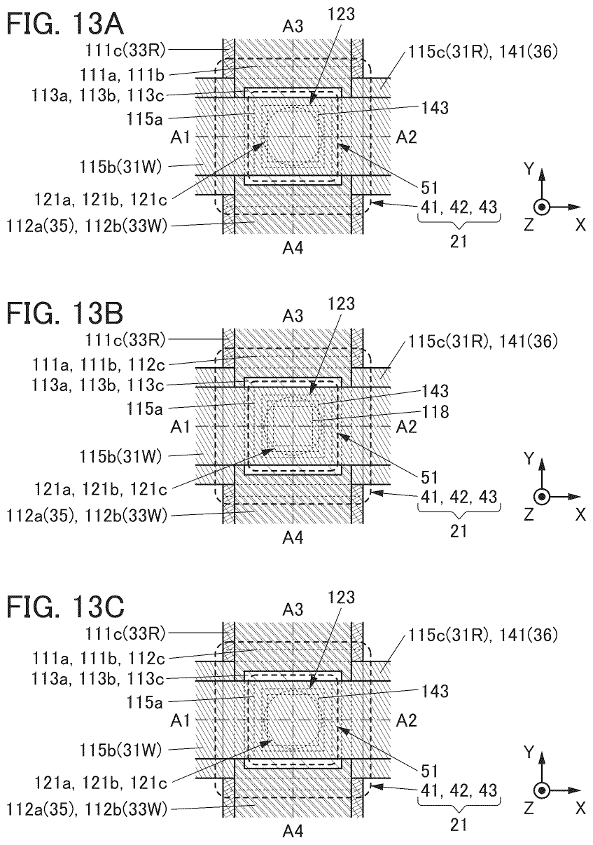

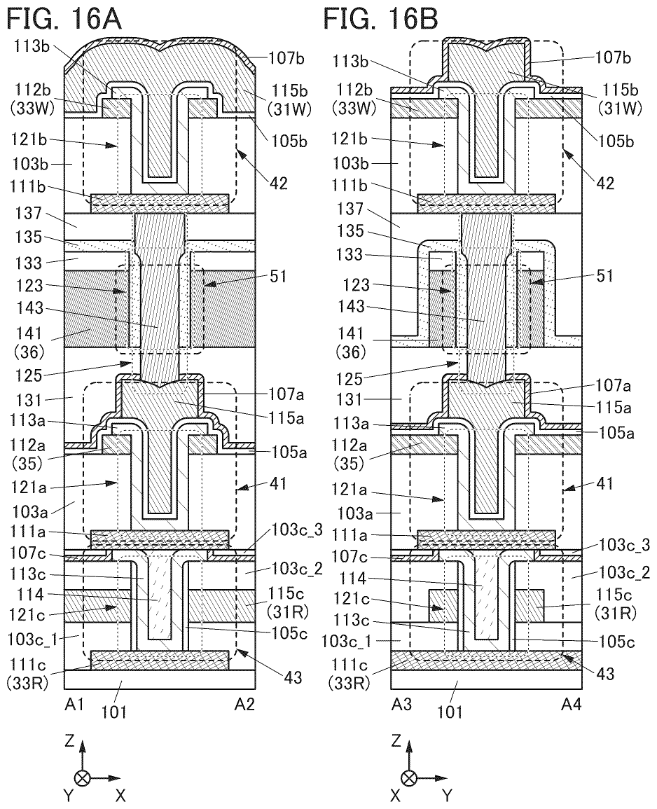

FIG. 13A, FIG. 16A, and FIG. 16B illustrate a structure example of the semiconductor device 10 of one embodiment of the present invention. FIG. 13A is a plan view illustrating a structure example of part of the semiconductor device 10. FIG. 16A is a cross-sectional view along the dashed-dotted line A1-A2 in FIG. 13A, and FIG. 16B is a cross-sectional view along the dashed-dotted line A3-A4 in FIG. 13A.

The semiconductor device 10 illustrated in FIG. 13A, FIG. 16A, and FIG. 16B includes the capacitor 51 in addition to the components of the semiconductor device 10 illustrated in FIG. 4A to FIG. 4C. The capacitor 51 is provided over the transistor 41 to overlap with the transistor 41, and the transistor 42 is provided over the capacitor 51 to overlap with the capacitor 51.

The capacitor 51 includes a conductive layer 141, a conductive layer 143, and an insulating layer 135.

The conductive layer 143 functions as one electrode of the capacitor 51. The conductive layer 141 functions as the other electrode of the capacitor 51 and functions as the wiring 36. The insulating layer 135 functions as a dielectric layer of the capacitor 51. The conductive layer 141 functioning as the wiring 36 includes a region extending in the X direction.

The conductive layer 141 includes an opening 123, and the insulating layer 135 and the conductive layer 143 are provided in the opening 123. Specifically, in the opening 123, the insulating layer 135 is provided to cover a side surface of the conductive layer 141, and the conductive layer 143 is provided on the inner side of the insulating layer 135. Thus, the conductive layer 141 is provided to cover at least part of a side surface of the conductive layer 143 with the insulating layer 135 therebetween. The insulating layer 135 includes, inside the opening 123, a region in contact with the side surface of the conductive layer 141 and a region in contact with the side surface of the conductive layer 143, for example.

An insulating layer 133 is provided over the conductive layer 141. The conductive layer 141 and the insulating layer 133 can have the same shape in a plan view and both include the opening 123. For example, a conductive film to be the conductive layer 141 and an insulating film to be the insulating layer 133 are sequentially formed, and then a pattern is formed by a photolithography method, and the insulating film and the conductive film are processed by an etching method using the pattern, whereby the insulating layer 133 and the conductive layer 141 each including the opening 123 can be formed.

FIG. 13A shows an example in which the shape of the opening 123 is quadrangular in a plan view. Although the shape of the opening 123 is a square in the plan view of FIG. 13A, the shape of the opening 123 is not limited thereto and may be, for example, a rectangle, a rhombus, or a parallelogram in a plan view. Furthermore, the shape of the opening 123 may be, for example, a triangle or a polygon with five or more corners in a plan view. Furthermore, in the example illustrated in FIG. 13A, the conductive layer 143 has a quadrangular top surface like the opening 123; the conductive layer 143 can have a shape similar to any of the above-described top-surface shapes that the opening 123 can have. Note that the top-surface shape of the opening 123 and the top-surface shape of the conductive layer 143 may be different from each other.

The insulating layer 135 is provided over the insulating layer 133. Specifically, the insulating layer 135 is provided to cover the top surface and a side surface of the insulating layer 133. An insulating layer 137 is provided over the insulating layer 135.

An opening 125 is provided in the insulating layer 107a, the insulating layer 131, the insulating layer 135, and the insulating layer 137. The opening 125 is provided to include a region overlapping with the opening 123. The conductive layer 143 is provided in the opening 125. By providing the conductive layer 143 in the opening 125 that reaches the conductive layer 115a, the top surface of the conductive layer 115a can be in contact with the bottom surface of the conductive layer 143, for example. Thus, the conductive layer 115a functioning as the gate electrode of the transistor 41 and the conductive layer 143 functioning as the one electrode of the capacitor 51 can be electrically connected to each other.

Here, in the case where the insulating layer 133 is not provided over the conductive layer 141, in the step of forming the opening 125, a region where the thickness of the insulating layer 135 is small might be formed between the conductive layer 141 and the conductive layer 143. In other words, a region where the distance between the conductive layer 141 and the conductive layer 143 is short might be formed. In that case, for example, a short circuit might occur between the conductive layer 141 and the conductive layer 143. In view of this, providing the insulating layer 133 over the conductive layer 141 can inhibit formation of the region where the distance between the conductive layer 141 and the conductive layer 143 is short. Accordingly, the reliability of the memory cell 21 can be increased, and a highly reliable semiconductor device can be provided. Furthermore, the manufacturing yield of the semiconductor device can be increased, and an inexpensive semiconductor device can be provided. Note that the insulating layer 133 is not necessarily provided as long as a short circuit between the conductive layer 141 and the conductive layer 143 does not occur, for example. In this case, the manufacturing process of the semiconductor device can be simplified.

The top surface of the conductive layer 143 and the top surface of the insulating layer 137 are substantially equal in height from the substrate surface. Over the conductive layer 143, the conductive layer 111b functioning as the one of the source electrode and the drain electrode of the transistor 42 is provided to include a region overlapping with the conductive layer 143.

The conductive layer 111b has a region in contact with the conductive layer 143. For example, the bottom surface of the conductive layer 111b includes a region in contact with the top surface of the conductive layer 143. Thus, the conductive layer 111b functioning as the one of the source electrode and the drain electrode of the transistor 42 and the conductive layer 143 functioning as the one electrode of the capacitor 51 can be electrically connected to each other. As described above, the conductive layer 143 is electrically connected to the conductive layer 115a functioning as the gate electrode of the transistor 41. In this way, the gate electrode of the transistor 41, the one of the source electrode and the drain electrode of the transistor 42, and the one electrode of the capacitor 51 are electrically connected to each other.

The components of the capacitor included in the memory cell will be described below.

### [Components of Capacitor]

As each of the conductive layer 141 and the conductive layer 143, a single layer or stacked layers of any of the conductors described in the later-described section [Conductor] can be used. For example, a conductive material with high conductivity, such as tungsten, aluminum, or copper, can be used for the conductive layer 141 and the conductive layer 143. With the use of a conductive material with high conductivity, the conductivity of the conductive layer 141 and the conductive layer 143 can be improved.

As each of the conductive layer 141 and the conductive layer 143, a single layer or stacked layers of a conductive material that is less likely to be oxidized, a conductive material having a function of inhibiting diffusion of oxygen, or the like are preferably used. For example, titanium nitride, indium tin oxide to which silicon is added, or the like may be used. For another example, a structure in which titanium nitride is stacked over tungsten may be used. For another example, a structure in which tungsten is stacked over first titanium nitride and second titanium nitride is stacked over the tungsten may be used. With such a structure, the conductive layer 141 and the conductive layer 143 can be inhibited from being oxidized by the insulating layer 135 in the case of using an oxide insulator for the insulating layer 135. Furthermore, the conductive layer 141 can be inhibited from being oxidized by the insulating layer 133 in the case of using an oxide insulator for the insulating layer 133. A semiconductor having high electrical conductivity, typified by polycrystalline silicon containing an impurity element such as phosphorus, or silicide such as nickel silicide may be used for the conductive layer 141 and the conductive layer 143.

For the insulating layer 135, any of the materials with a high relative permittivity, that is, high-k materials, described in the later-described section [Insulator] is preferably used. Using a high-k material for the insulating layer 135 allows the insulating layer 135 to be thick enough to inhibit a leakage current and the capacitor 51 to have a sufficiently high electrostatic capacitance. It is preferable to use, as the insulating layer 135, stacked insulators formed of any of the high-k materials; it is preferable to use a stacked-layer structure of a material having a high relative permittivity (high-k material) and a material having higher dielectric strength than the high-k material. As the insulating layer 135, an insulating film in which zirconium oxide, aluminum oxide, and zirconium oxide are stacked in this order can be used, for example. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 51.

Alternatively, a material that can have ferroelectricity may be used for the insulating layer 135. Examples of the material that can have ferroelectricity include metal oxides such as hafnium oxide, zirconium oxide, and HfZrO_{X} (X is a real number greater than 0). Another example of the material that can have ferroelectricity is a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Other examples of the material that can have ferroelectricity include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Another example of the material that can have ferroelectricity is a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element MI to the element M2 can be set as appropriate. A metal oxide containing the element MI and nitrogen has ferroelectricity in some cases even though the metal oxide does not contain the element M2. Another example of the material that can have ferroelectricity is a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Other examples of the material that can have ferroelectricity include a perovskite-type oxynitride such as SrTaO₂N and BaTaO₂N, and GaFeO₃ with a κ-alumina-type structure.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulating layer 135 can have a stacked-layer structure of a plurality of materials selected from the above-listed materials. The above-listed materials, for example, may change their crystal structures (characteristics) according to a variety of processes as well as deposition conditions. Thus, a material that exhibits ferroelectricity is referred to not only as a ferroelectric but also as a material that can have ferroelectricity or a material that has ferroelectricity in this specification and the like.

A metal oxide containing one or both of hafnium and zirconium is preferable because the metal oxide can have ferroelectricity even when being processed into a thin film of several nanometers. Here, the thickness of the insulating layer 135 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. With the use of the ferroelectric layer that can have a small thickness, the capacitor 51 can be combined with a semiconductor element such as a scaled-down transistor to fabricate a semiconductor device. Note that in this specification and the like, the material that can have ferroelectricity processed into a layered shape may be referred to as a ferroelectric layer, a metal oxide film, or a metal nitride film. Furthermore, a device including such a ferroelectric layer, metal oxide film, or metal nitride film may be referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupied area) in a plan view of less than or equal to 100 μm², less than or equal to 10 μm², less than or equal to 1 μm², or less than or equal to 0.1 μm². Furthermore, even a ferroelectric layer with an area less than or equal to 10000 nm² or less than or equal to 1000 nm² has ferroelectricity in some cases. With a small-area ferroelectric layer, the area occupied by the capacitor 51 can be reduced.

The ferroelectric is an insulator and has properties of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 51, the semiconductor device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer 135 can exhibit ferroelectricity, the insulating layer 135 needs to include a crystal. It is particularly preferable that the insulating layer 135 include a crystal having an orthorhombic crystal structure to exhibit ferroelectricity. Note that a crystal included in the insulating layer 135 may have one or more selected from cubic, tetragonal, orthorhombic, monoclinic, and hexagonal crystal structures. Alternatively, the insulating layer 135 may have an amorphous structure. In that case, the insulating layer 135 may have a composite structure including an amorphous structure and a crystal structure.

The insulating layer 133 preferably has a low relative permittivity. In that case, parasitic capacitance generated between wirings can be reduced. As the insulating layer 133, a single layer or stacked layers of any of the insulators each including a material with a low relative permittivity described in the later-described section [Insulator] can be used. In particular, silicon oxide and silicon oxynitride are preferable because they are thermally stable.

Although FIG. 16A and FIG. 16B show that the insulating layer 133 is a single layer, the present invention is not limited thereto. The insulating layer 133 may have a stacked-layer structure.

### <Structure Example 10 of Semiconductor Device>

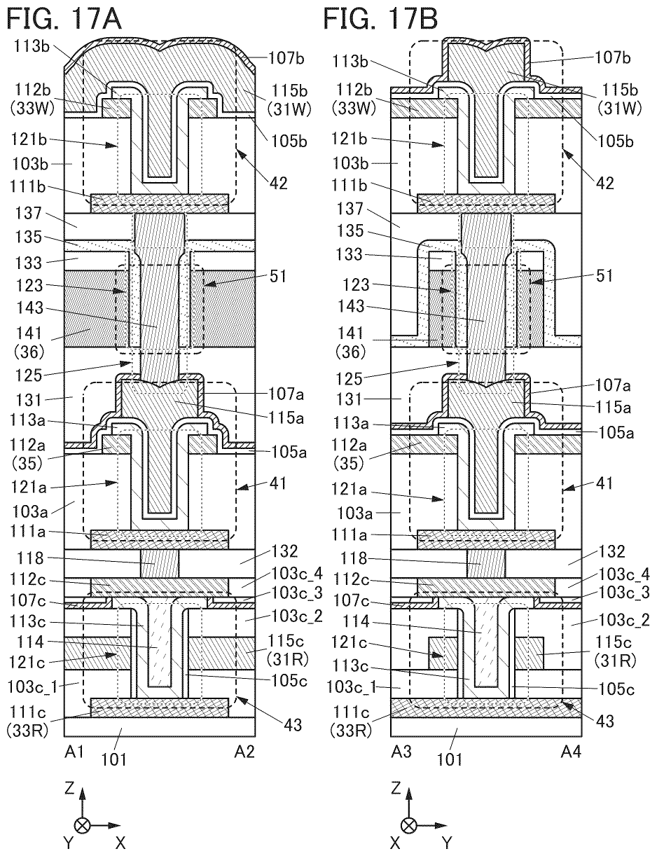

FIG. 13B, FIG. 17A, and FIG. 17B illustrate another structure example of the semiconductor device 10 of one embodiment of the present invention, which is different from the above-described structures. FIG. 13B is a plan view illustrating a structure example of part of the semiconductor device 10. FIG. 17A is a cross-sectional view along the dashed-dotted line A1-A2 in FIG. 13B, and FIG. 17B is a cross-sectional view along the dashed-dotted line A3-A4 in FIG. 13B.

The semiconductor device 10 illustrated in FIG. 13B, FIG. 17A, and FIG. 17B has a structure in which the semiconductor device 10 illustrated in FIG. 7A to FIG. 7C and the semiconductor device 10 illustrated in FIG. 13A, FIG. 16A, and FIG. 16B are combined.

Specifically, the semiconductor device 10 illustrated in FIG. 13B, FIG. 17A, and FIG. 17B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 7A to FIG. 7C.

The description of the semiconductor device 10 illustrated in FIG. 7A to FIG. 7C and the description of the semiconductor device 10 illustrated in FIG. 13A, FIG. 16A, and FIG. 16B can be referred to for the semiconductor device 10 illustrated in FIG. 13B, FIG. 17A, and FIG. 17B other than the above.

### <Structure Example 11 of Semiconductor Device>

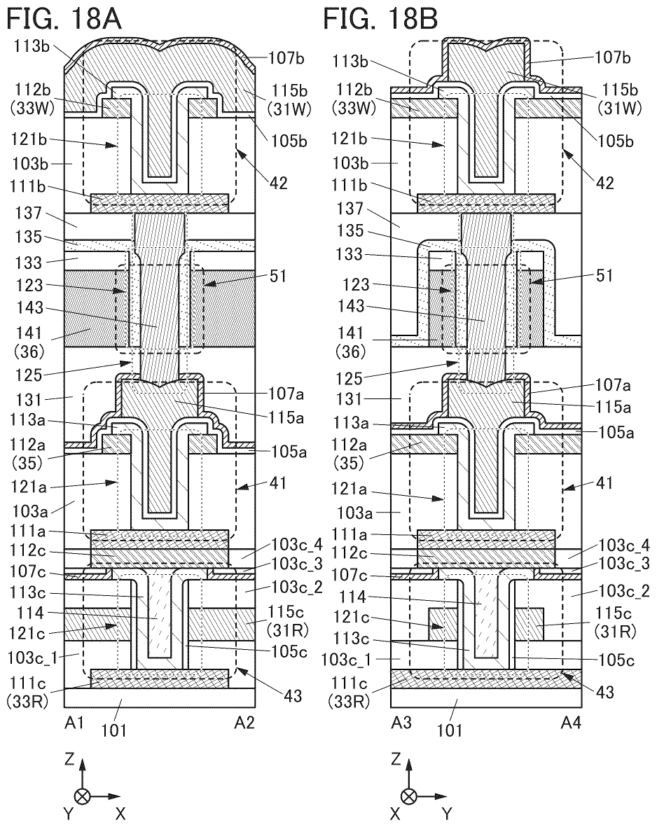

FIG. 13C, FIG. 18A, and FIG. 18B illustrate another structure example of the semiconductor device 10 of one embodiment of the present invention, which is different from the above-described structures. FIG. 13C is a plan view illustrating a structure example of part of the semiconductor device 10. FIG. 18A is a cross-sectional view along the dashed-dotted line A1-A2 in FIG. 13C, and FIG. 18B is a cross-sectional view along the dashed-dotted line A3-A4 in FIG. 13C.

The semiconductor device 10 illustrated in FIG. 13C, FIG. 18A, and FIG. 18B has a structure in which the semiconductor device 10 illustrated in FIG. 8A to FIG. 8C and the semiconductor device 10 illustrated in FIG. 13A, FIG. 16A, and FIG. 16B are combined.

Specifically, the semiconductor device 10 illustrated in FIG. 13C, FIG. 18A, and FIG. 18B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 8A to FIG. 8C.

The description of the semiconductor device 10 illustrated in FIG. 8A to FIG. 8C and the description of the semiconductor device 10 illustrated in FIG. 13A, FIG. 16A, and FIG. 16B can be referred to for the semiconductor device 10 illustrated in FIG. 13C, FIG. 18A, and FIG. 18B other than the above.

### <Structure Example 12 of Semiconductor Device>

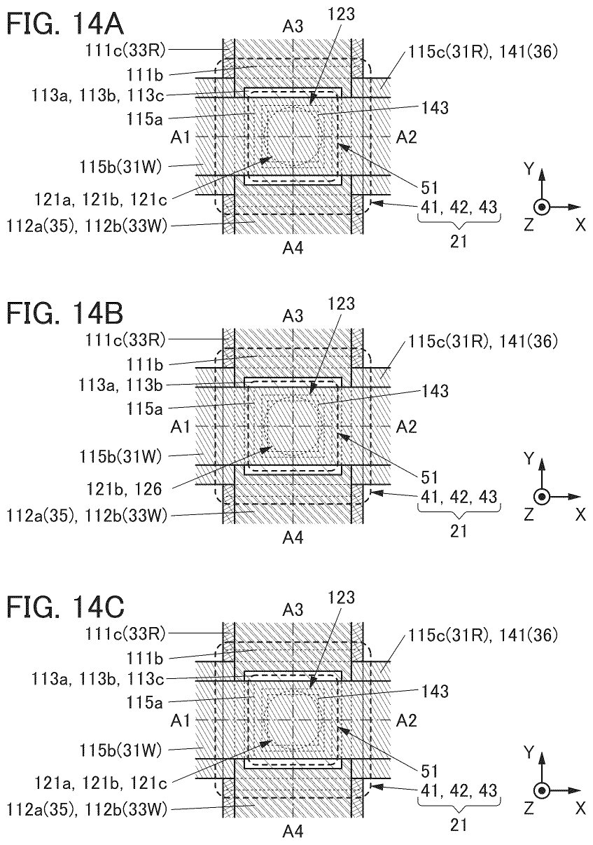

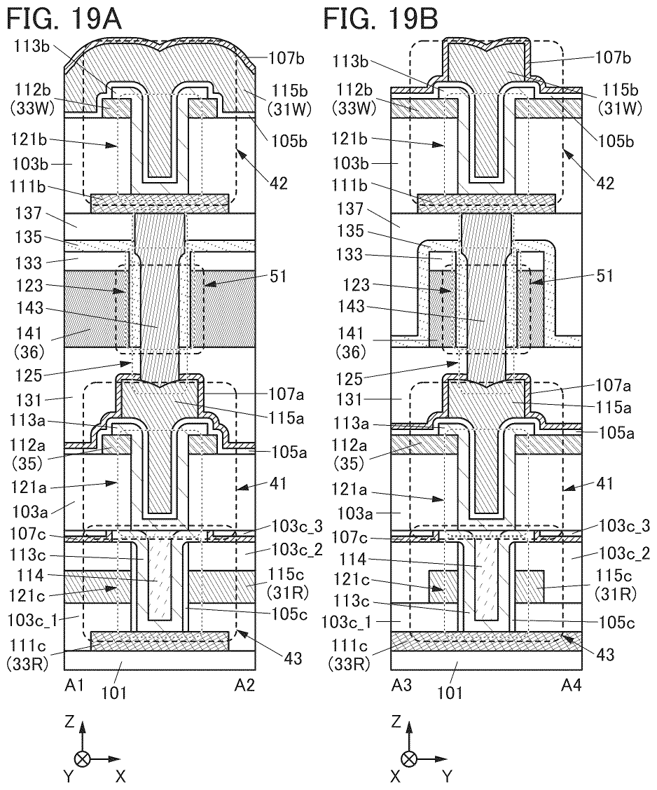

FIG. 14A, FIG. 19A, and FIG. 19B illustrate another structure example of the semiconductor device 10 of one embodiment of the present invention, which is different from the above-described structures. FIG. 14A is a plan view illustrating a structure example of part of the semiconductor device 10. FIG. 19A is a cross-sectional view along the dashed-dotted line A1-A2 in FIG. 14A, and FIG. 19B is a cross-sectional view along the dashed-dotted line A3-A4 in FIG. 14A.

The semiconductor device 10 illustrated in FIG. 14A, FIG. 19A, and FIG. 19B has a structure in which the semiconductor device 10 illustrated in FIG. 9A to FIG. 9C and the semiconductor device 10 illustrated in FIG. 13A, FIG. 16A, and FIG. 16B are combined.

Specifically, the semiconductor device 10 illustrated in FIG. 14A, FIG. 19A, and FIG. 19B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 9A to FIG. 9C.

The description of the semiconductor device 10 illustrated in FIG. 9A to FIG. 9C and the description of the semiconductor device 10 illustrated in FIG. 13A, FIG. 16A, and FIG. 16B can be referred to for the semiconductor device 10 illustrated in FIG. 14A, FIG. 19A, and FIG. 19B other than the above.

### <Structure Example 13 of Semiconductor Device>

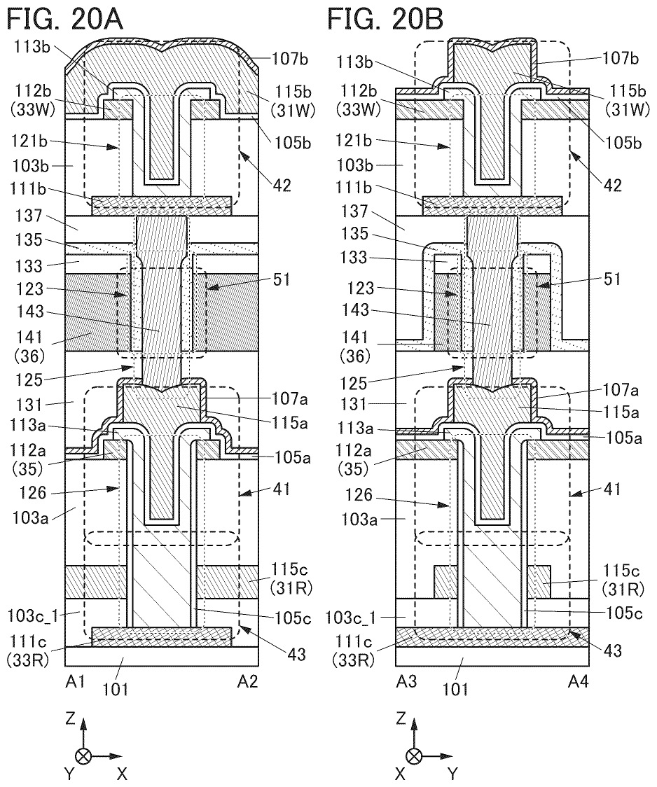

FIG. 14B, FIG. 20A, and FIG. 20B illustrate another structure example of the semiconductor device 10 of one embodiment of the present invention, which is different from the above-described structures. FIG. 14B is a plan view illustrating a structure example of part of the semiconductor device 10. FIG. 20A is a cross-sectional view along the dashed-dotted line A1-A2 in FIG. 14B, and FIG. 20B is a cross-sectional view along the dashed-dotted line A3-A4 in FIG. 14B.

The semiconductor device 10 illustrated in FIG. 14B, FIG. 20A, and FIG. 20B has a structure in which the semiconductor device 10 illustrated in FIG. 10A to FIG. 10C and the semiconductor device 10 illustrated in FIG. 13A, FIG. 16A, and FIG. 16B are combined.

Specifically, the semiconductor device 10 illustrated in FIG. 14B, FIG. 20A, and FIG. 20B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 10A to FIG. 10C.

The description of the semiconductor device 10 illustrated in FIG. 10A to FIG. 10C and the description of the semiconductor device 10 illustrated in FIG. 13A, FIG. 16A, and FIG. 16B can be referred to for the semiconductor device 10 illustrated in FIG. 14B, FIG. 20A, and FIG. 20B other than the above.

### <Structure Example 14 of Semiconductor Device>

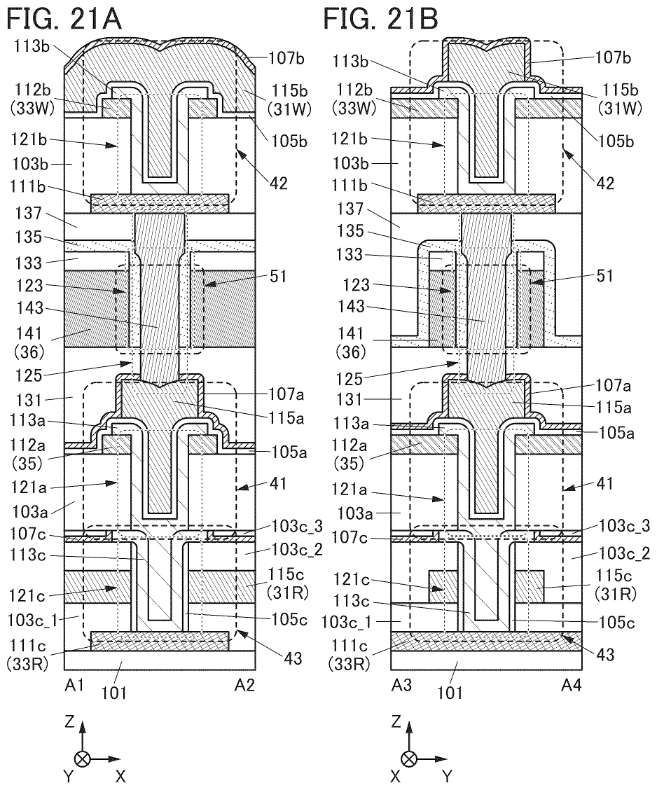

FIG. 14C, FIG. 21A, and FIG. 21B illustrate another structure example of the semiconductor device 10 of one embodiment of the present invention, which is different from the above-described structures. FIG. 14C is a plan view illustrating a structure example of part of the semiconductor device 10. FIG. 21A is a cross-sectional view along the dashed-dotted line A1-A2 in FIG. 14C, and FIG. 21B is a cross-sectional view along the dashed-dotted line A3-A4 in FIG. 14C.

The semiconductor device 10 illustrated in FIG. 14C, FIG. 21A, and FIG. 21B has a structure in which the semiconductor device 10 illustrated in FIG. 11A to FIG. 11C and the semiconductor device 10 illustrated in FIG. 13A, FIG. 16A, and FIG. 16B are combined.

Specifically, the semiconductor device 10 illustrated in FIG. 14C, FIG. 21A, and FIG. 21B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 11A to FIG. 11C.

The description of the semiconductor device 10 illustrated in FIG. 11A to FIG. 11C and the description of the semiconductor device 10 illustrated in FIG. 13A, FIG. 16A, and FIG. 16B can be referred to for the semiconductor device 10 illustrated in FIG. 14C, FIG. 21A, and FIG. 21B other than the above.

### <Structure Example 15 of Semiconductor Device>

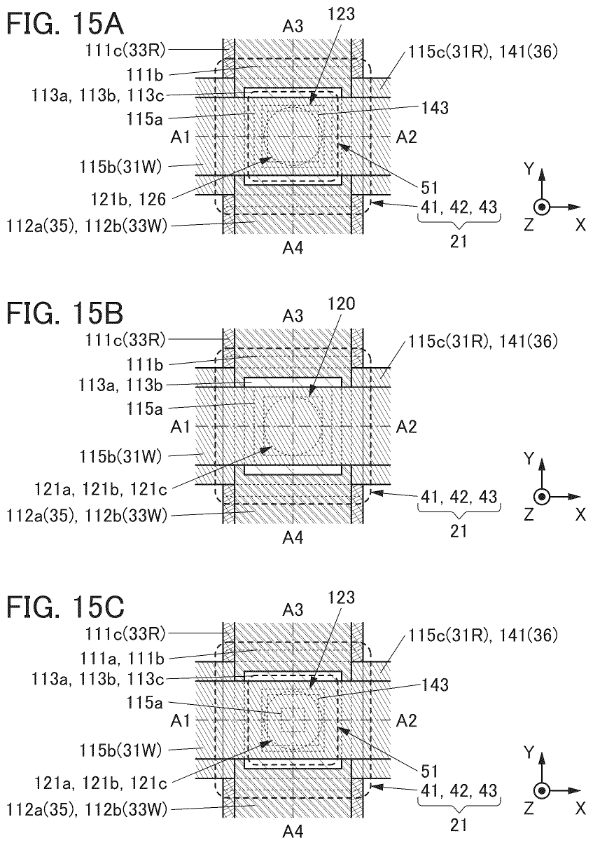

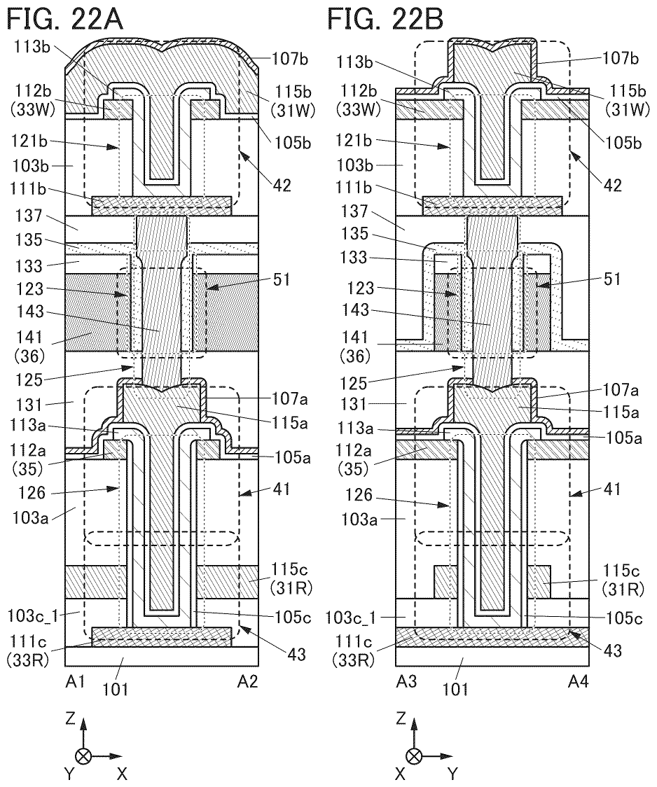

FIG. 15A, FIG. 22A, and FIG. 22B illustrate another structure example of the semiconductor device 10 of one embodiment of the present invention, which is different from the above-described structures. FIG. 15A is a plan view illustrating a structure example of part of the semiconductor device 10. FIG. 22A is a cross-sectional view along the dashed-dotted line A1-A2 in FIG. 15A, and FIG. 22B is a cross-sectional view along the dashed-dotted line A3-A4 in FIG. 15A.

The semiconductor device 10 illustrated in FIG. 15A, FIG. 22A, and FIG. 22B has a structure in which the semiconductor device 10 illustrated in FIG. 12A to FIG. 12C and the semiconductor device 10 illustrated in FIG. 13A, FIG. 16A, and FIG. 16B are combined.

Specifically, the semiconductor device 10 illustrated in FIG. 15A, FIG. 22A, and FIG. 22B has a structure in which the capacitor 51 included in the semiconductor device 10 illustrated in FIG. 13A, FIG. 16A, and FIG. 16B is provided between the transistor 41 and the transistor 42 in the arrangement of the transistor 43, the transistor 41, and the transistor 42 included in the semiconductor device 10 illustrated in FIG. 12A to FIG. 12C.

The description of the semiconductor device 10 illustrated in FIG. 12A to FIG. 12C and the description of the semiconductor device 10 illustrated in FIG. 13A, FIG. 16A, and FIG. 16B can be referred to for the semiconductor device 10 illustrated in FIG. 15A, FIG. 22A, and FIG. 22B other than the above.

### <Structure Example 16 of Semiconductor Device>

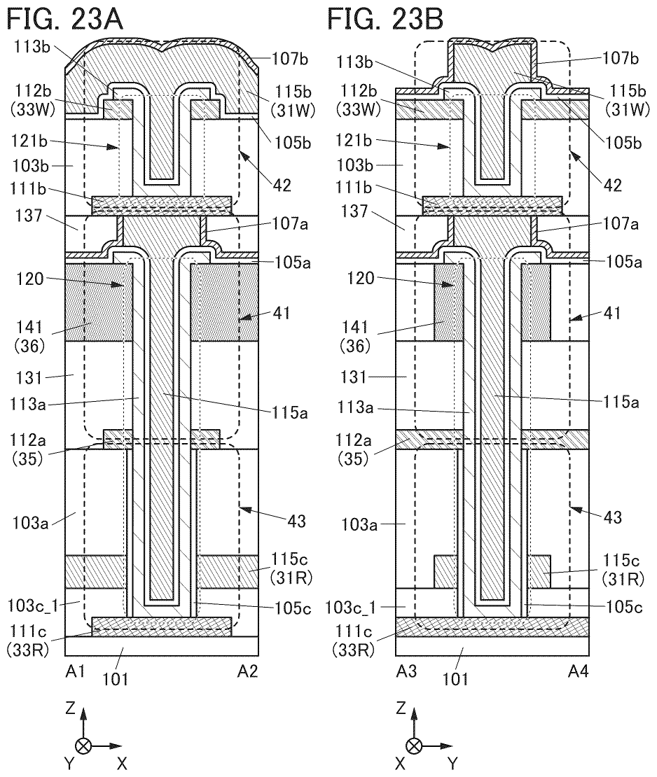

FIG. 15B, FIG. 23A, and FIG. 23B illustrate another structure example of the semiconductor device 10 of one embodiment of the present invention, which is different from the above-described structures. FIG. 15B is a plan view illustrating a structure example of part of the semiconductor device 10. FIG. 23A is a cross-sectional view along the dashed-dotted line A1-A2 in FIG. 15B, and FIG. 23B is a cross-sectional view along the dashed-dotted line A3-A4 in FIG. 15B.

The semiconductor device 10 illustrated in FIG. 15B, FIG. 23A, and FIG. 23B includes the transistor 43, the transistor 41, and the transistor 42 (a 3Tr0C memory cell structure).

In the semiconductor device 10 illustrated in FIG. 15B, FIG. 23A, and FIG. 23B, the insulating layer 103c_1, the conductive layer 115c, the insulating layer 103a, the conductive layer 112a, the insulating layer 131, and the conductive layer 141 are provided in this order over the insulating layer 101 and the conductive layer 111c, and the opening 120 reaching the conductive layer 111c is provided in these layers. The insulating layer 105c is provided in contact with the side surface of the insulating layer 103c_1, the side surface of the conductive layer 115c, and the side surface of the insulating layer 103a on the opening 120 side. The semiconductor layer 113a is provided in contact with the top surface of the conductive layer 141 and the side surface of the conductive layer 141, the side surface of the insulating layer 131, the side surface of the conductive layer 112a, the side surface of the insulating layer 105c, and the top surface of the conductive layer 111c in the opening 120. The insulating layer 105a is provided to cover the semiconductor layer 113a. Here, a concave portion reflecting the shape of the opening 120 is formed over the semiconductor layer 113a and the insulating layer 105a. The conductive layer 115a is provided to fill the concave portion.

In the semiconductor device 10 illustrated in FIG. 15B, FIG. 23A, and FIG. 23B, the semiconductor layer 113a functions as both the semiconductor layer of the transistor 43 and the semiconductor layer of the transistor 41. The insulating layer 105a functions as both the gate insulating layer of the transistor 43 and the gate insulating layer of the transistor 41. The conductive layer 115a functions as both the gate electrode of the transistor 43 and the gate electrode of the transistor 41. The conductive layer 112a functions as both the other of the source electrode and the drain electrode of the transistor 43 and the one of the source electrode and the drain electrode of the transistor 41. The conductive layer 141 functions as the other of the source electrode and the drain electrode of the transistor 41.

Here, in the semiconductor device 10 illustrated in FIG. 16A, FIG. 16B, and the like, the conductive layer 141 has a function of the other electrode of the capacitor 51. Meanwhile, the semiconductor device 10 illustrated in FIG. 15B, FIG. 23A, and FIG. 23B does not include the capacitor 51. In such a memory cell structure without a capacitor, a conductive layer that can be used as the other electrode of a capacitor may be used as part of a conductive layer of a transistor.

Note that in the transistor 43, in addition to the insulating layer 105a, the insulating layer 105c also functions as a gate insulating layer. In addition to the conductive layer 115a, the conductive layer 115c also functions as a gate electrode. That is, the transistor 43 has a structure including two gate electrodes. Thus, the carrier controllability in the semiconductor layer 113a can be increased as compared with a structure including only one gate electrode.

As described above, many layers including the semiconductor layer 113a, the insulating layer 105a, and the conductive layer 115a can be shared by the transistor 43 and the transistor 41; hence, the manufacturing process of the semiconductor device can be simplified.

### <Structure Example 17 of Semiconductor Device>

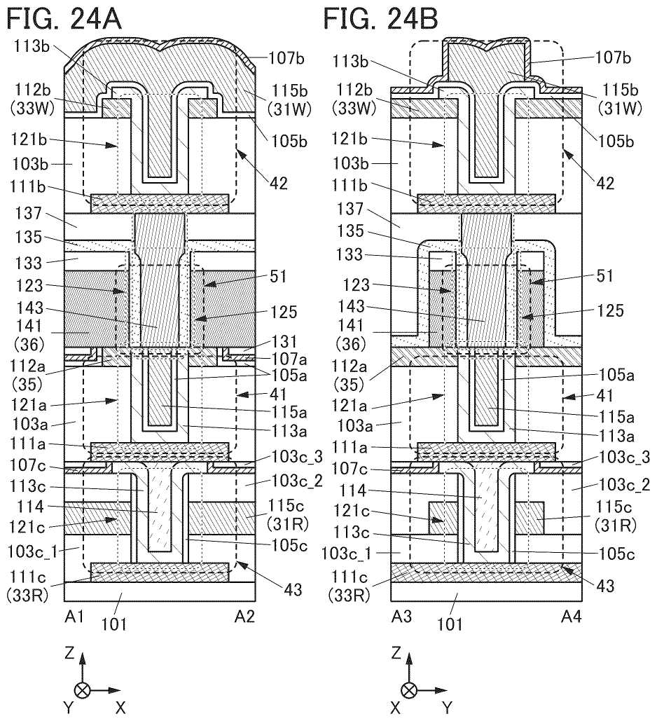

FIG. 15C, FIG. 24A, and FIG. 24B illustrate another structure example of the semiconductor device 10 of one embodiment of the present invention, which is different from the above-described structures. FIG. 15C is a plan view illustrating a structure example of part of the semiconductor device 10. FIG. 24A is a cross-sectional view along the dashed-dotted line A1-A2 in FIG. 15C, and FIG. 24B is a cross-sectional view along the dashed-dotted line A3-A4 in FIG. 15C.

The semiconductor device 10 illustrated in FIG. 15C, FIG. 24A, and FIG. 24B is different from the semiconductor device 10 illustrated in FIG. 16A and FIG. 16B in that the conductive layer 112a functioning as the other of the source electrode and the drain electrode of the transistor 41 is electrically connected to the conductive layer 141 having a function of the other electrode of the capacitor 51.

In the semiconductor device 10 illustrated in FIG. 15C, FIG. 24A, and FIG. 24B, the top surface of the conductive layer 115a, the uppermost surface of the insulating layer 105a, the uppermost surface of the semiconductor layer 113a, the top surface of the conductive layer 112a, and the uppermost surface of the insulating layer 107a that are included in the transistor 41, and the top surface of the insulating layer 131 are substantially equal in height from the substrate surface. Meanwhile, the bottom surface of the conductive layer 143, the lowermost surface of the insulating layer 135, and the bottom surface of the conductive layer 141 included in the capacitor 51 are substantially equal in height from the substrate surface. The top surface of the conductive layer 112a and the bottom surface of the conductive layer 141 are provided to include a region where they are in contact with each other.

In the semiconductor device 10 illustrated in FIG. 15C, FIG. 24A, and FIG. 24B, which has the above-described structure, potentials having the same level can be supplied to the conductive layer 112a and the conductive layer 141. As described above, the conductive layer 112a functions as the wiring 35, and the conductive layer 141 functions as the wiring 36. Thus, when the semiconductor device 10 has the above-described structure, the number of wirings can be reduced and the manufacturing process can be simplified.

The description of the semiconductor device 10 illustrated in FIG. 16A and FIG. 16B can be referred to for the semiconductor device 10 illustrated in FIG. 15C, FIG. 24A, and FIG. 24B other than the above-described differences.

### <Structure Example of Display Apparatus>

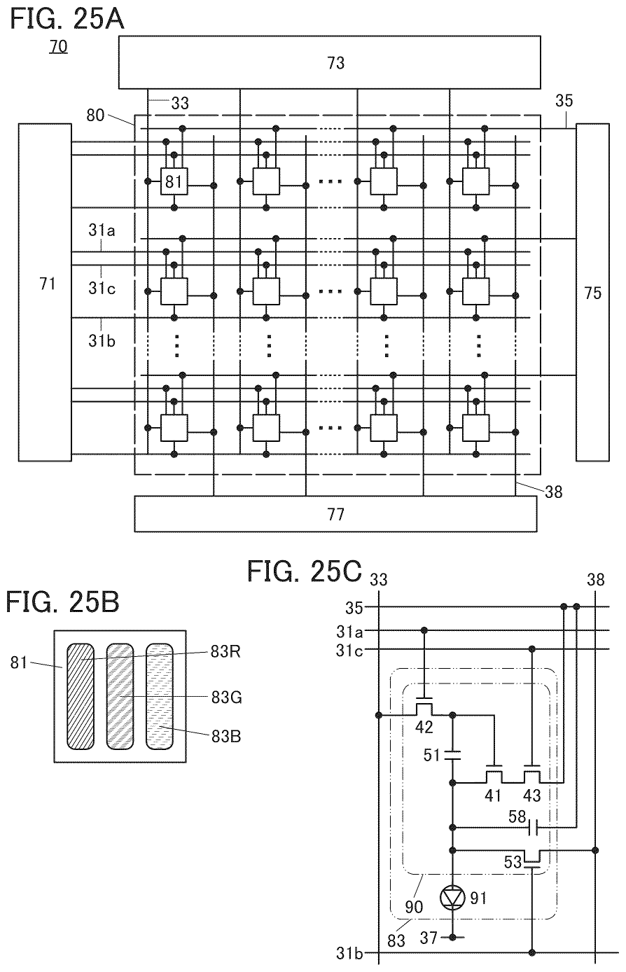

One embodiment of the present invention can also be applied to a display apparatus. FIG. 25A is a block diagram illustrating a structure example of a display apparatus 70 that is a display apparatus of one embodiment of the present invention. The display apparatus 70 includes a display portion 80, a scan line driver circuit 71, a signal line driver circuit 73, a power supply circuit 75, and a reference potential generator circuit 77. The display portion 80 includes a plurality of pixels 81 arranged in a matrix. Note that the power supply circuit 75 may be provided outside the display apparatus 70.

The scan line driver circuit 71 is electrically connected to the pixels 81 through the wirings 31 (a wiring 31a, a wiring 31b, and a wiring 31c). The wirings 31 extend in the row direction of the matrix, for example.

The signal line driver circuit 73 is electrically connected to the pixels 81 through the wirings 33. The wirings 33 extend in the column direction of the matrix, for example.

The power supply circuit 75 is electrically connected to the pixels 81 through the wirings 35. The wirings 35 extend in the row direction of the matrix, for example.

The reference potential generator circuit 77 is electrically connected to the pixels 81 through wirings 38. The wirings 38 extend in the column direction of the matrix, for example.

Each of the pixels 81 includes a display element (also referred to as a display device), and an image can be displayed on the display portion 80 with the display elements. As the display element, for example, a light-emitting element (also referred to as a light-emitting device) can be used; specifically, an organic EL element can be used. As the display element, a liquid crystal element (also referred to as a liquid crystal device) can also be used.

The scan line driver circuit 71 has a function of selecting the pixel 81 to which image data is to be written on a row-by-row basis, for example. Specifically, the scan line driver circuit 71 can select the pixel 81 to which image data is to be written by outputting a signal to the wiring 31. Here, the scan line driver circuit 71 can select all the pixels 81 by, for example, outputting the signal to the wiring 31 in the first row, outputting the signal to the wiring 31 in the second row, and then outputting the signals to the wirings 31 from the third row to the last row sequentially. Thus, the signal output from the scan line driver circuit 71 to the wiring 31 is a scan signal, and the wiring 31 provided in the display apparatus 70 can be referred to as a scan line.

The signal line driver circuit 73 has a function of generating image data. The image data is supplied to the pixel 81 through the wiring 33. For example, image data can be written to all the pixels 81 included in a row selected by the scan line driver circuit 71. Here, the image data can be represented as a signal (image signal). Thus, the wiring 33 provided in the display apparatus 70 can be referred to as a signal line.

The power supply circuit 75 has a function of generating a power supply potential and supplying it to the wiring 35. The power supply circuit 75 has a function of generating a high power supply potential (hereinafter, also simply referred to as “high potential” or “VDD”) and supplying it to the wiring 35, for example. The power supply circuit 75 may have a function of generating a low power supply potential (hereinafter, also simply referred to as “low potential” or “VSS”). As described above, the wiring 35 functions as a power supply line.

The reference potential generator circuit 77 has a function of generating a reference potential and supplying it to the wiring 38. Since the potential of the wiring 38 is a reference potential, the wiring 38 can be referred to as a reference potential line. Note that the electrical characteristics of the pixels may be read out to the reference potential generator circuit 77, which is outside the pixels, through the wirings 38. That is, the reference potential generator circuit 77 may have a function of sensing the electrical characteristics of the pixels. The reference potential generator circuit 77 may sense deterioration, variations, and the like of elements (transistors, light-emitting elements, or the like) in the pixels by reading the electrical characteristics of the pixels. Then, the read characteristics may be fed back to a video signal to correct deterioration and variations of image quality.

FIG. 25B is a plan view illustrating a structure example of the pixel 81. The pixel 81 can include a plurality of subpixels 83. FIG. 25B illustrates an example in which the pixel 81 includes a subpixel 83R, a subpixel 83G, and a subpixel 83B as the subpixels 83. Here, in the case where the pixel 81 includes a light-emitting element as the display element, for example, the top surface shape of each of the subpixels illustrated in FIG. 25B corresponds to the top surface shape of a light-emitting region of the light-emitting element. Although FIG. 25B illustrates the subpixel 83R, the subpixel 83G, and the subpixel 83B that have the same or substantially the same aperture ratio (also referred to as size or size of a light-emitting region), one embodiment of the present invention is not limited thereto. The aperture ratio of each of the subpixel 83R, the subpixel 83G, and the subpixel 83B can be determined as appropriate. The subpixel 83R, the subpixel 83G, and the subpixel 83B may have different aperture ratios, or two or more of the subpixels may have the same or substantially the same aperture ratio.

The pixel 81 illustrated in FIG. 25B employs stripe arrangement as the arrangement method of the subpixels 83. Note that S-stripe arrangement, matrix arrangement, delta arrangement, Bayer arrangement, PenTile arrangement, or the like may be employed as the arrangement method of the subpixels 83.

The subpixel 83R, the subpixel 83G, and the subpixel 83B emit light of different colors. The subpixel 83R, the subpixel 83G, and the subpixel 83B can be subpixels of three colors of red (R), green (G), and blue (B) or subpixels of three colors of yellow (Y), cyan (C), and magenta (M), for example. The pixel 81 may include four or more subpixels 83. For example, the pixel 81 may include subpixels of four colors of R, G, B, and white (W). In the above manner, in the display apparatus 70, the pixel 81 includes a plurality of subpixels 83 that emit light of different colors, whereby the display portion 80 can display a full-color image. Note that the pixel 81 may include subpixels of R, G, B, and infrared light (IR), for example.

Note that a sensor may be provided in the display portion 80; for example, a sensor may be provided in the pixel 81. For example, the display portion 80 may have a function of a fingerprint sensor. For example, the display portion 80 may have a function of an optical or ultrasonic fingerprint sensor.

FIG. 25C is a circuit diagram illustrating a structure example of the subpixel 83 included in the pixel 81 illustrated in FIG. 25A. The subpixel 83 illustrated in FIG. 25C includes a pixel circuit 90 and a light-emitting element 91.

The pixel circuit 90 includes the transistor 41, the transistor 42, the transistor 43, a transistor 53, the capacitor 51, and a capacitor 58. That is, the pixel circuit 90 is a 4Tr2C pixel circuit.

In the pixel circuit 90, one of the source and the drain of the transistor 42 is electrically connected to the wiring 33. The other of the source and the drain of the transistor 42 is electrically connected to one electrode of the capacitor 51 and the gate of the transistor 41. The gate of the transistor 42 is electrically connected to the wiring 31a. One of the source and the drain of the transistor 41 is electrically connected to one of the source and the drain of the transistor 43. The other of the source and the drain of the transistor 43 is electrically connected to the wiring 35. The gate of the transistor 43 is electrically connected to the wiring 31c. One electrode of the capacitor 58 is electrically connected to the other of the source and the drain of the transistor 41, one of a source and a drain of the transistor 53, the other electrode of the capacitor 51, and one electrode of the light-emitting element 91. The other electrode of the capacitor 58 is electrically connected to the wiring 35. The other of the source and the drain of the transistor 53 is electrically connected to the wiring 38. A gate of the transistor 53 is electrically connected to the wiring 31b. The other electrode of the light-emitting element 91 is electrically connected to a wiring 37.

The transistor 43 has a function of a switch and has a function of controlling electrical continuity or discontinuity between the wiring 35 and the one of the source and the drain of the transistor 41 on the basis of the potential of the wiring 31c.

When the transistor 43 is turned on, current having a level corresponding to the gate potential of the transistor 41 flows from the wiring 35 to the wiring 37, for example. Thus, the light-emitting element 91 emits light with luminance corresponding to the gate potential of the transistor 41. Meanwhile, when the transistor 43 is turned off, current can be prevented from flowing through the light-emitting element 91; thus, the light-emitting element 91 can be prevented from emitting light.

OS transistors are preferably used as the transistor 41, the transistor 42, and the transistor 43. An OS transistor has higher field-effect mobility than a transistor including amorphous silicon, for example. Thus, by using OS transistors as the transistor 41 and the transistor 42, the display apparatus 70 can be driven at high speed.

The off-state current of an OS transistor is extremely low as described above. Thus, by using an OS transistor as the transistor 42, charge accumulated in the capacitor 51 can be retained for a long period. Accordingly, image data written to the subpixel 83 can be retained for a long period and thus the frequency of the refresh operation (image data rewriting to the subpixel 83) can be reduced. Consequently, power consumption of the display apparatus 70 can be reduced.

To increase the emission luminance of the light-emitting element 91, the amount of current fed through the light-emitting element 91 needs to be increased. To increase the current amount, it is necessary to increase the source-drain voltage of the transistor 41, which is a driving transistor. Since an OS transistor has a higher withstand voltage between a source and a drain than a Si transistor, high voltage can be applied between the source and the drain of the OS transistor. Accordingly, when an OS transistor is used as the transistor 41, the amount of current flowing through the light-emitting element 91 can be increased, so that the emission luminance of the light-emitting element 91 can be increased.

As the light-emitting element 91, an OLED (Organic Light Emitting Diode) or a QLED (Quantum-dot Light Emitting Diode) is preferably used, for example. Examples of a light-emitting substance contained in the light-emitting element 91 include a substance that exhibits fluorescence (a fluorescent material), a substance that exhibits phosphorescence (a phosphorescent material), a substance that exhibits thermally activated delayed fluorescence (a thermally activated delayed fluorescence (TADF) material), and an inorganic compound (e.g., a quantum dot material). An LED such as a micro-LED (Light Emitting Diode) can also be used as the light-emitting element 91.

### <Structure Example 18 of Semiconductor Device>

A structure example of a plurality of memory cells 21 is described below. Specifically, a structure example of the memory cells 21 in four rows and four columns is described with reference to plan views. Note that some reference numerals are omitted in the plan views in some cases.

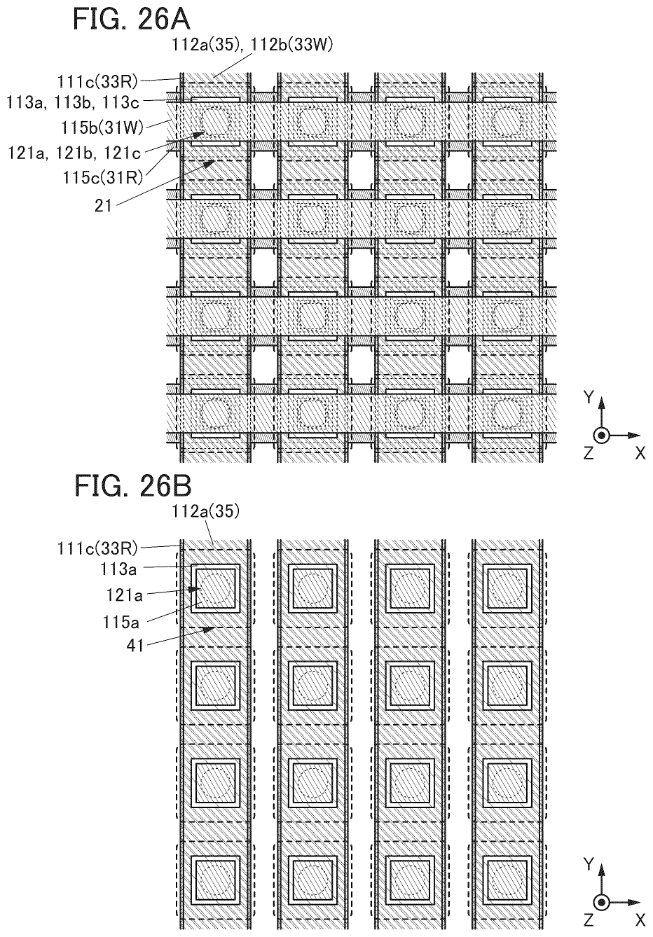

FIG. 26A is a plan view illustrating a structure example in which the memory cells 21 illustrated in FIG. 4A are arranged in a matrix. FIG. 26B is a plan view in which the transistor 42 and the transistor 43 are omitted from the structure illustrated in FIG. 26A.

As illustrated in FIG. 26A and FIG. 26B, the conductive layer 111c functioning as the wiring 33R and the conductive layer 112a functioning as the wiring 35 each include a region extending in the Y direction and are shared by the memory cells 21 arranged in the Y direction. In other words, the memory cells 21 in one column share the same conductive layer 111c and the same conductive layer 112a. Thus, at the time of reading data retained in the memory cell 21, current can be prevented from flowing from a plurality of wirings 33R functioning as read bit lines to one wiring 35 functioning as a power supply line. Accordingly, the amount of current flowing through the wiring 35 can be reduced. According to Ohm's law, the voltage drop AV of a wiring is a product of the wiring resistance R and the current I (ΔV=R×I). Thus, reducing the amount of current flowing through the wiring 35 can inhibit a decrease in the potential supplied as a power supply potential particularly in the memory cell 21 at a long wiring distance from the power source circuit 15 illustrated in FIG. 1A, for example. This can inhibit the data retained in the memory cell 21 from being incorrectly read, for example. Therefore, a memory cell and a semiconductor device that have high reading accuracy can be provided.

In the example illustrated in FIG. 26A, the conductive layer 115b functioning as the wiring 31W includes a region extending in the X direction and is shared by the memory cells 21 arranged in the X direction. That is, the memory cells 21 in the same row share the same conductive layer 115b. Moreover, the conductive layer 112b functioning as the wiring 33W includes a region extending in the Y direction and is shared by the memory cells 21 arranged in the Y direction. That is, the memory cells 21 in the same column share the same conductive layer 112b.

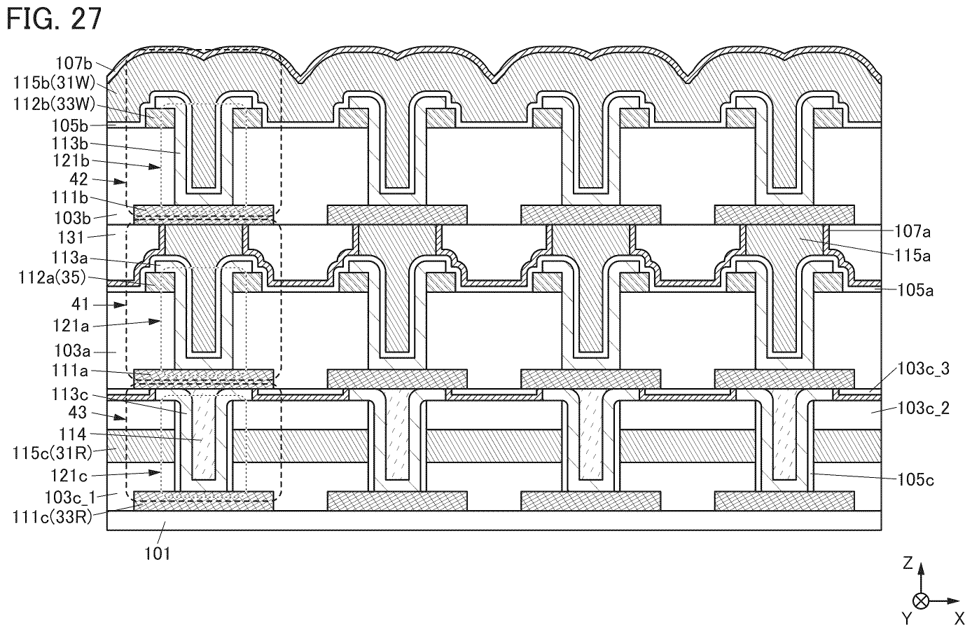

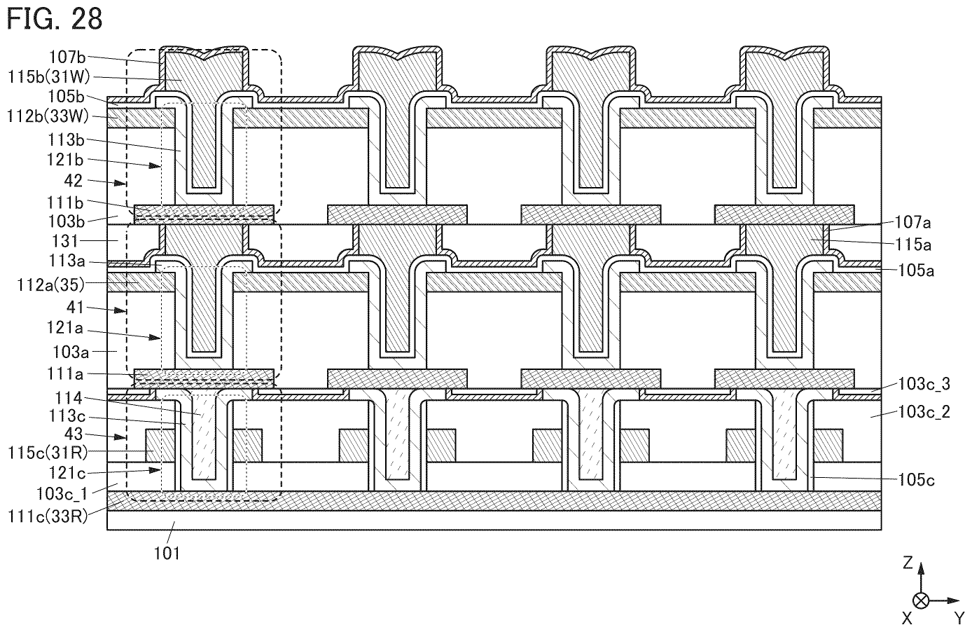

FIG. 27 and FIG. 28 are cross-sectional views of the memory cells 21 that are illustrated in the plan view of FIG. 26A and arranged in four rows and four columns. FIG. 27 is a cross-sectional view along the XZ plane, and FIG. 28 is a cross-sectional view along the YZ plane. As illustrated in the plan view of FIG. 26A and the cross-sectional views of FIG. 27 and FIG. 28, in the semiconductor device of one embodiment of the present invention, the memory cells 21 each including the stacked three transistors each having the source electrode and the drain electrode provided at different heights from the substrate surface can be arranged at high density in the XY plane. Thus, the area occupied by each memory cell in a plan view can be reduced, and additionally, a semiconductor device in which a plurality of memory cells are highly integrated can be achieved.

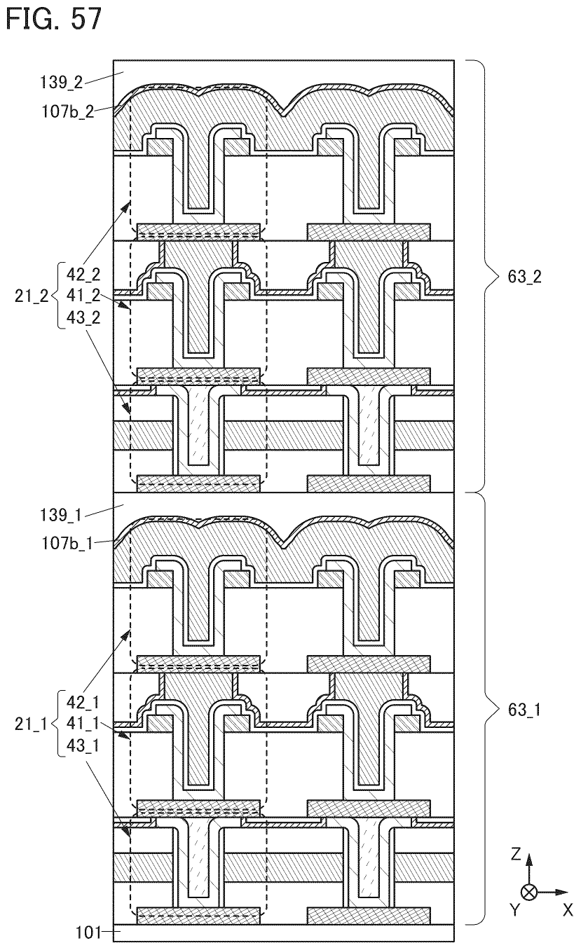

Note that as described later in FIG. 57 and the like, the semiconductor device of one embodiment of the present invention may have a structure in which the memory cells 21 are stacked not only in the XY plane but also in the Z direction. With this structure, higher integration of the semiconductor layer device can be achieved.

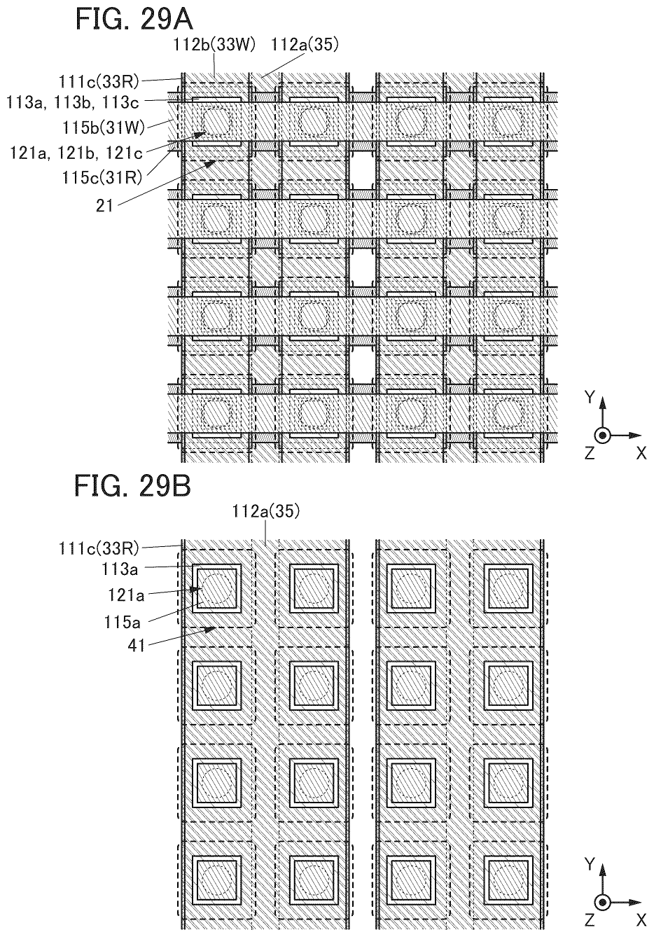

FIG. 29A and FIG. 29B illustrate a variation example of the structure illustrated in FIG. 26A and FIG. 26B, respectively, and illustrate an example in which the conductive layer 112a functioning as the wiring 35 is shared by the memory cells 21 in two adjacent columns. When the memory cells 21 in a plurality of columns share the conductive layer 112a, the memory cells 21 can be arranged at high density.

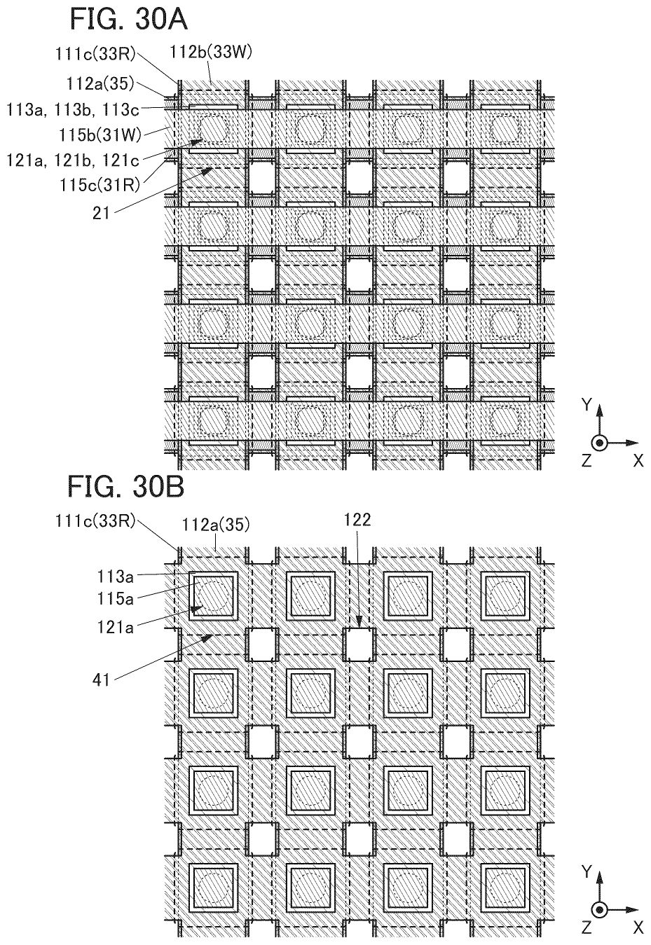

FIG. 30A and FIG. 30B illustrate a variation example of the structure illustrated in FIG. 26A and FIG. 26B, respectively, and the conductive layer 112a functioning as the wiring 35 serving as the power supply line includes a region extending in the X direction and a region extending in the Y direction. The conductive layer 112a includes the opening 121a in a region where the region extending in the X direction and the region extending in the Y direction intersect with each other. With such a shape of the conductive layer 112a, the wiring resistance of the conductive layer 112a can be lower than that in the structure illustrated in FIG. 26A and FIG. 26B, for example. In contrast, in the example illustrated in FIG. 30A and FIG. 30B, the conductive layers 112a included in all the memory cells 21 are electrically connected to each other, for example. Thus, at the time of reading data retained in the memory cell 21, current flows from all the wirings 33R to one conductive layer 112a, for example. Note that in the example illustrated in FIG. 30B, the conductive layer 112a includes an opening 122 surrounded by four memory cells 21.

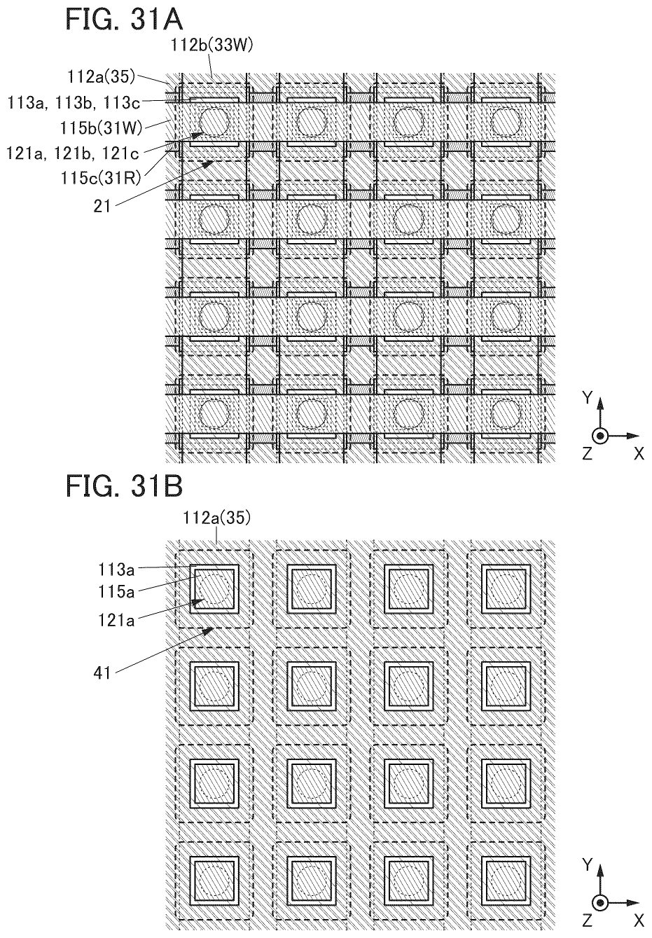

FIG. 31A and FIG. 31B illustrate a variation example of the structure illustrated in FIG. 30A and FIG. 30B, respectively, and illustrate an example in which the conductive layer 112a does not include the opening 122. In the example illustrated in FIG. 31A and FIG. 31B, in the memory portion where the memory cells 21 are arranged in a matrix, the shape of the conductive layer 112a can be quadrangular and the opening 121a can be provided in the quadrangular conductive layer 112a.

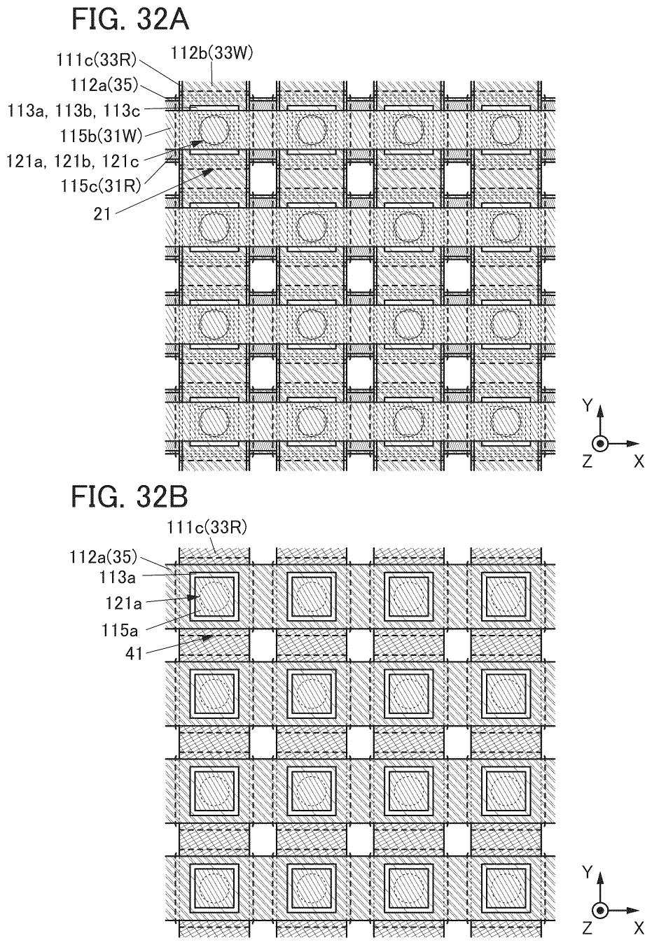

FIG. 32A and FIG. 32B illustrate a variation example of the structure illustrated in FIG. 26A and FIG. 26B, respectively, and illustrate an example in which the conductive layer 112a functioning as the wiring 35 includes a region extending in the X direction and is shared by the memory cells 21 arranged in the X direction. That is, in the example illustrated in FIG. 32A and FIG. 32B, the memory cells 21 in the same row share the same conductive layer 112a.

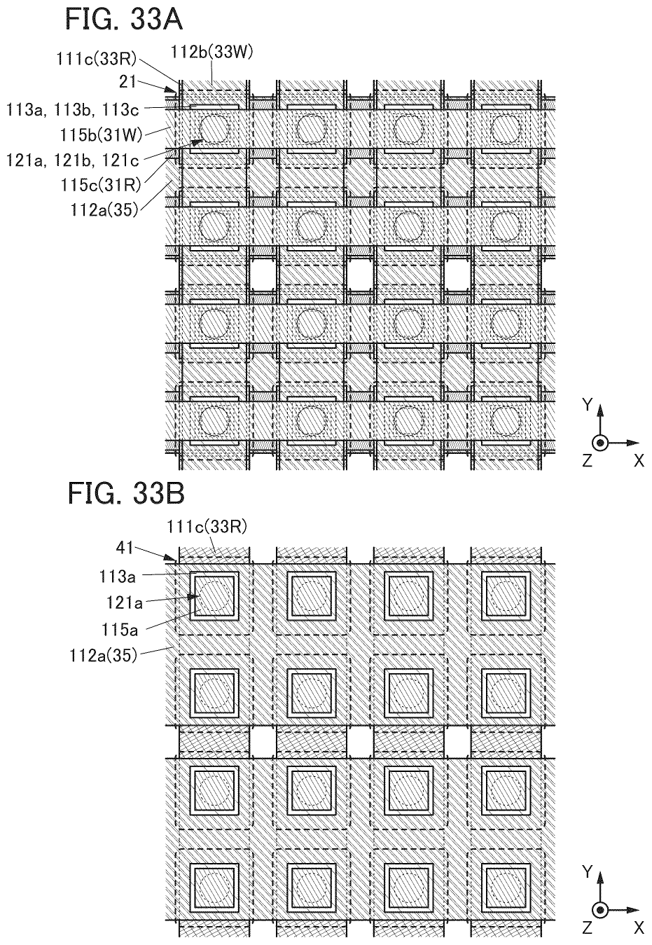

FIG. 33A and FIG. 33B illustrate a variation example of the structure illustrated in FIG. 32A and FIG. 32B, respectively, and illustrate an example in which the conductive layer 112a is shared by the memory cells 21 in two adjacent rows. When the memory cells 21 in a plurality of rows share the conductive layer 112a, the memory cells 21 can be arranged at high density.

<Constituent materials for semiconductor device>Constituent materials that can be used for the semiconductor device will be described below.

### [Substrate]

As a substrate where the transistor 41, the transistor 42, the transistor 43, and the capacitor 51 are formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material, and a compound semiconductor substrate including silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, any of these substrates provided with an element may be used.

### [Insulator]

Examples of an insulator include an oxide, a nitride, an oxynitride, a nitride oxide, a metal oxide, a metal oxynitride, and a metal nitride oxide, each of which has an insulating property.

With further miniaturization and higher integration of a transistor, for example, a problem such as generation of leakage current may arise because of a thinned gate insulating layer. When a high-k material is used for an insulator functioning as a gate insulating layer, the voltage at the time of the operation of the transistor can be reduced while the physical thickness is maintained. In addition, the equivalent oxide thickness (EOT) of the insulator functioning as the gate insulating layer can be reduced. In contrast, when a material with a low relative permittivity is used as an insulator functioning as an interlayer insulating layer, parasitic capacitance generated between wirings can be reduced. Thus, a material is preferably selected in accordance with the function of the insulator. Note that the material with a low relative permittivity is a material with high dielectric strength.

Examples of a material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. These silicon oxides may contain nitrogen. Silicon oxide may be formed using, for example, organosilane such as tetraethoxysilane (TEOS).

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor layer or provided in the vicinity of the semiconductor layer, such as a gate insulating layer, preferably includes a region including excess oxygen. For example, when an insulator including a region including excess oxygen is in contact with a semiconductor layer or provided in the vicinity of the semiconductor layer, the number of oxygen vacancies in the semiconductor layer can be reduced. Examples of an insulator in which a region including excess oxygen is easily formed include silicon oxide, silicon oxynitride, and porous silicon oxide.

Examples of an insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In an oxide having an amorphous structure, an oxygen atom has a dangling bond, and the oxide has a property of capturing or fixing hydrogen with the dangling bond in some cases. Although these metal oxides preferably have an amorphous structure, a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance obtained by bonding with hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom, an oxygen molecule, and the like. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive material containing oxygen may be referred to as an oxide conductor.

In addition, a conductive material containing tungsten, copper, or aluminum as its main component is preferable because it has high conductivity.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for a channel formation region of a transistor, the conductor functioning as a gate electrode preferably employs a stacked-layer structure combining a material containing the above metal element and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from a surrounding insulator or the like can be captured in some cases.

### [Metal Oxide]

A metal oxide has a lattice defect in some cases. Examples of a lattice defect include point defects such as an atomic vacancy and an exotic atom, linear defects such as transition, plane defects such as a grain boundary, and volume defects such as a cavity. Examples of a factor in generating a lattice defect include a deviation of the proportion of the number of constituent element atoms (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

Electrical characteristics of a transistor using a metal oxide in a semiconductor layer are likely to vary especially in the case where oxygen vacancies (Vo) and impurities are present in the metal oxide in a channel formation region, and the reliability thereof might be degraded. In some cases, hydrogen in the vicinity of the oxygen vacancy forms VoH and generates an electron serving as a carrier. Thus, when the metal oxide in the channel formation region includes oxygen vacancies, the transistor tends to have normally on characteristics (characteristics with which, even when no voltage is applied to the gate electrode, the channel exists and current flows through the transistor). Therefore, oxygen vacancies and impurities are preferably reduced as much as possible in the metal oxide in the channel formation region. In other words, it is preferable that the metal oxide in the channel formation region have a reduced carrier concentration and be of i-type (intrinsic) or be substantially of i-type.

The kind of a lattice defect that is likely to be present in a metal oxide and the amount of lattice defects that are present there depend on the structure of the metal oxide, a method for forming a film of the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure.

A metal oxide having an a-like structure and a metal oxide having an amorphous structure each include a void or a low-density region. That is, a metal oxide having an a-like structure and a metal oxide having an amorphous structure each have low crystallinity compared with a metal oxide having an nc structure and a metal oxide having a CAAC structure. Moreover, a metal oxide having an a-like structure has higher hydrogen concentration in the metal oxide than a metal oxide having an nc structure and a metal oxide having a CAAC structure. Thus, a lattice defect is likely to be generated in a metal oxide having an a-like structure and a metal oxide having an amorphous structure.

Accordingly, a metal oxide with high crystallinity is preferably used in a semiconductor layer of a transistor. For example, it is preferable to use a metal oxide having a CAAC structure or a metal oxide having a single crystal structure. The use of the metal oxide for a semiconductor layer of a transistor enables the transistor to have favorable electrical characteristics. In addition, a transistor with high reliability can be obtained.

For the channel formation region of a transistor, a metal oxide that increases the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (e.g., a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the surface where the metal oxide is formed or the film surface of the metal oxide. This enables the plurality of layers to be placed parallel or substantially parallel to the surface where the metal oxide is formed or the film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and their deformed structures.

Preferably, each of the first layer to the third layer is composed of one metal element or a plurality of metal elements with the same valence and oxygen. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the mobility of the metal oxide. Thus, the use of the metal oxide for the channel formation region of a transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, the element M, and zinc. Note that the element Mis a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

As the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used, for example. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which can make the off-state current of the transistor low. Furthermore, a change in electrical characteristics of the transistor can be inhibited, and the reliability of the transistor can be increased.

By increasing the proportion of the number of In atoms in the total number of atoms of all the metal elements contained in the metal oxide, a high on-state current and excellent frequency characteristics of the transistor can be achieved.

In the description of this embodiment, In—Ga—Zn oxide is sometimes given as an example of the metal oxide.

For the formation of a metal oxide having the layered crystal structure, atomic layers are preferably deposited one by one. By an ALD method, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. The use of plasma in a PEALD method is sometimes preferable because it enables film formation at a lower temperature. Note that a precursor used in an ALD method sometimes contains an element such as carbon or chlorine. Thus, in some cases, a film provided by an ALD method includes a larger amount of an element such as carbon or chlorine than a film provided by another film formation method. Note that these elements can be quantified by XPS or SIMS.

When an ALD method is used as the deposition method of a metal oxide, one or both of a deposition condition with a high substrate temperature and impurity removal treatment can form a film with smaller amounts of carbon and chlorine than the case of using an ALD method without the condition and the treatment.

For example, impurity removal treatment is preferably intermittently performed in an atmosphere containing oxygen during the deposition of the metal oxide. Furthermore, impurity removal treatment is preferably performed in an atmosphere containing oxygen after the deposition of the metal oxide. Impurities in the film can be removed by performing impurity removal treatment during and/or after the deposition of the metal oxide. This can inhibit impurities (e.g., hydrogen, carbon, and nitrogen) contained in a raw material such as a precursor from remaining in the metal oxide. Accordingly, the impurity concentration in the metal oxide can be reduced. Moreover, the crystallinity of the metal oxide can be increased.

Examples of the impurity removal treatment include plasma treatment, microwave treatment, and heat treatment.

When plasma treatment or microwave treatment is performed, the substrate temperature is preferably higher than or equal to room temperature (e.g., 25° C.) and lower than or equal to 500° C., higher than or equal to 100° C. and lower than or equal to 500° C., higher than or equal to 200° C. and lower than or equal to 500° C., higher than or equal to 300° C. and lower than or equal to 500° C., higher than or equal to 400° C. and lower than or equal to 500° C., or higher than or equal to 400° C. and lower than or equal to 450° C. The temperature of heat treatment is preferably higher than or equal to 100° C. and lower than or equal to 450° C., higher than or equal to 200° C. and lower than or equal to 450° C., higher than or equal to 300° C. and lower than or equal to 450°C., or higher than or equal to 400° C. and lower than or equal to 450° C.

The temperature at the time of the impurity removal treatment is particularly preferably set lower than or equal to the maximum temperature in the manufacturing process of the transistor or the semiconductor device, in which case the impurity content in the metal oxide can be reduced without a decrease in productivity. For example, when the maximum temperature in manufacturing the semiconductor device of one embodiment of the present invention is lower than or equal to 500° C., preferably lower than or equal to 450° C., the productivity of the semiconductor device can be increased.

Here, the microwave treatment refers to, for example, treatment using an apparatus including a power source that generates high-density plasma with the use of a microwave. In this specification and the like, the microwave refers to an electromagnetic wave having a frequency greater than or equal to 300 MHz and less than or equal to 300 GHZ.

The microwave treatment is preferably performed with a microwave treatment apparatus including a power source for generating high-density plasma using microwaves, for example. Here, the frequency of the microwave treatment apparatus is preferably set higher than or equal to 300 MHz and lower than or equal to 300 GHz, further preferably higher than or equal to 2.4 GHZ and lower than or equal to 2.5 GHZ, and can be set to 2.45 GHZ, for example. Oxygen radicals at a high density can be generated with high-density plasma. The electric power of the power source that applies microwaves of the microwave treatment apparatus is preferably set higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the film efficiently.

The microwave treatment is preferably performed under reduced pressure, and the pressure is preferably set higher than or equal to 10 Pa and lower than or equal to 1000 Pa, further preferably higher than or equal to 300 Pa and lower than or equal to 700 Pa. The treatment temperature is preferably higher than or equal to room temperature (25° C.) and lower than or equal to 750° C., further preferably higher than or equal to 300° C. and lower than or equal to 500° C., still further preferably higher than or equal to 400° C. and lower than or equal to 450° C.

After the microwave treatment or plasma treatment is performed, heat treatment may be successively performed without exposure to the air. The temperature of the heat treatment is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%.

The heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is preferably approximately 20%. Alternatively, the heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. The heat treatment may be performed under an atmosphere of ultra-dry air (air with a water content lower than or equal to 20 ppm, preferably lower than or equal to 1 ppm, further preferably lower than or equal to 10 ppb).

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity, specifically, a metal oxide having the above-described CAAC structure can be formed.

Unlike a film formation method in which particles ejected from a target or the like are deposited, an ALD method is a film formation method in which a film is formed by reaction at a surface of an object. Thus, an ALD method is a film formation method that enables favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a sputtering method or a CVD method, in some cases. A method in which a sputtering method is used to deposit a first metal oxide and an ALD method is used to deposit a second metal oxide over the first metal oxide is given as an example. For example, in the case where the first metal oxide has a crystal part, crystal growth occurs in the second metal oxide with the use of the crystal part as a nucleus.

In an ALD method, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is not required. Thus, the productivity of the semiconductor device can be increased in some cases.

### [Transistor Including Metal Oxide]

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be obtained. Furthermore, a scaled-down or highly integrated transistor can be achieved. For example, a transistor with a channel length greater than or equal to 2 nm and less than or equal to 30 nm can be manufactured.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, an OS transistor includes an oxide semiconductor that is a semiconductor material having a large band gap, and thus can suppress the short-channel effect. In other words, a short-channel effect does not appear or hardly appears in an OS transistor.

Note that the short-channel effect refers to degradation of electrical characteristics that becomes apparent along with miniaturization of a transistor (a decrease in channel length). Specific examples of the short-channel effect include a decrease in threshold voltage, an increase in a subthreshold swing value (sometimes referred to as an S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

An OS transistor is an accumulation-type transistor and a Si transistor is an inversion-type transistor. Accordingly, the OS transistor has a shorter characteristic length between a source region and a channel formation region and a shorter characteristic length between a drain region and a channel formation region than the Si transistor. Therefore, the OS transistor has higher resistance to the short-channel effect than the Si transistor. That is, in the case where a transistor with a short channel length is to be manufactured, the OS transistor is preferable to the Si transistor.

Even in the case where the carrier concentration of the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor with the above structure can have favorable electrical characteristics even when a semiconductor device is reduced in size or highly integrated. For example, favorable electrical characteristics can be obtained even when the OS transistor has a channel length or a gate length greater than or equal to 1 nm and less than or equal to 20 nm, greater than or equal to 3 nm and less than or equal to 15 nm, greater than or equal to 5 nm and less than or equal to 10 nm, greater than or equal to 5 nm and less than or equal to 7 nm, or greater than or equal to 5 nm and less than or equal to 6 nm. In contrast, it is sometimes difficult for the Si transistor to have a gate length less than or equal to 20 nm or less than or equal to 15 nm because of appearance of the short-channel effect. Thus, the OS transistor can be more suitably used as a short-channel transistor than the Si transistor. Note that the gate length refers to the length of a gate electrode in a direction in which carriers move inside a channel formation region during the operation of the transistor.

Miniaturization of the OS transistor can improve the high frequency characteristics of the transistor. Specifically, the cutoff frequency of the transistor can be improved. When the gate length of the OS transistor is within any of the above ranges, the cutoff frequency of the transistor can be higher than or equal to 50 GHz, preferably higher than or equal to 100 GHZ, further preferably higher than or equal to 150 GHz in a room temperature environment, for example.

As described above, the OS transistor has effects superior to those of the Si transistor, such as a low off-state current and capability of having a short channel length.

### [Impurity in Metal Oxide]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor that is obtained by SIMS is set lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸atoms/cm³. The silicon concentration in the channel formation region of the oxide semiconductor that is obtained by SIMS is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor using an oxide semiconductor that contains nitrogen for a semiconductor layer is likely to have normally-on characteristics. When the oxide semiconductor contains nitrogen, trap states are sometimes formed. This might make the electrical characteristics of the transistor unstable. Therefore, the nitrogen concentration in the channel formation region of the oxide semiconductor that is obtained by SIMS is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The semiconductor layer 113 can be rephrased as a semiconductor layer including the channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single-element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride as the layered material contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer can provide a semiconductor device with a high on-state current.

This embodiment can be combined with the other embodiments as appropriate. In this specification, in the case where a plurality of structure examples are shown in one embodiment, the structure examples can be combined as appropriate.

### EMBODIMENT 2

In this embodiment, a method for manufacturing the semiconductor device of one embodiment of the present invention will be described with reference to drawings.

### <Example of Method for Manufacturing Semiconductor Device>

As a method for manufacturing the semiconductor device of one embodiment of the present invention, an example of a method for manufacturing the semiconductor device illustrated in FIG. 4A to FIG. 4C will be described below.

Note that A of each drawing is a top view. Moreover, B of each drawing is a cross-sectional view corresponding to a portion indicated by the dashed-dotted line A1-A2 in A of each drawing. Furthermore, C of each drawing is a cross-sectional view corresponding to a portion indicated by the dashed-dotted line A3-A4 in A of each drawing. Note that for the sake of clarity of the drawing, some components are omitted in the plan view of A of each drawing.

Hereinafter, an insulating material for forming an insulator, a conductive material for forming a conductor, or a semiconductor material for forming a semiconductor can be deposited by a deposition method such as a sputtering method, a CVD method, an MBE method, a PLD method, or an ALD method as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

A CVD method can be classified into a plasma CVD (PECVD) method using plasma, a thermal CVD (TCVD) method using heat, a photo CVD method using light, and the like. Moreover, a CVD method can be classified into a metal CVD (MCVD) method and a metal organic CVD (MOCVD) method depending on a source gas to be used.

A high-quality film can be obtained at a relatively low temperature by a plasma CVD method. A thermal CVD method is a deposition method that does not use plasma and thus enables film formation without plasma damage to an object on which the film is to be formed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of a thermal CVD method, which does not use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, an ALD method is a film formation method that enables favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be deposited depending on the flow rate ratio of the source gases. For example, by a CVD method, a film whose composition is continuously changed can be deposited by changing the flow rate ratio of the source gases during deposition. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be deposited by concurrently introducing different kinds of precursors. In the case where different kinds of precursors are introduced, a film with a certain composition can be formed by controlling the number of cycles for each of the precursors.

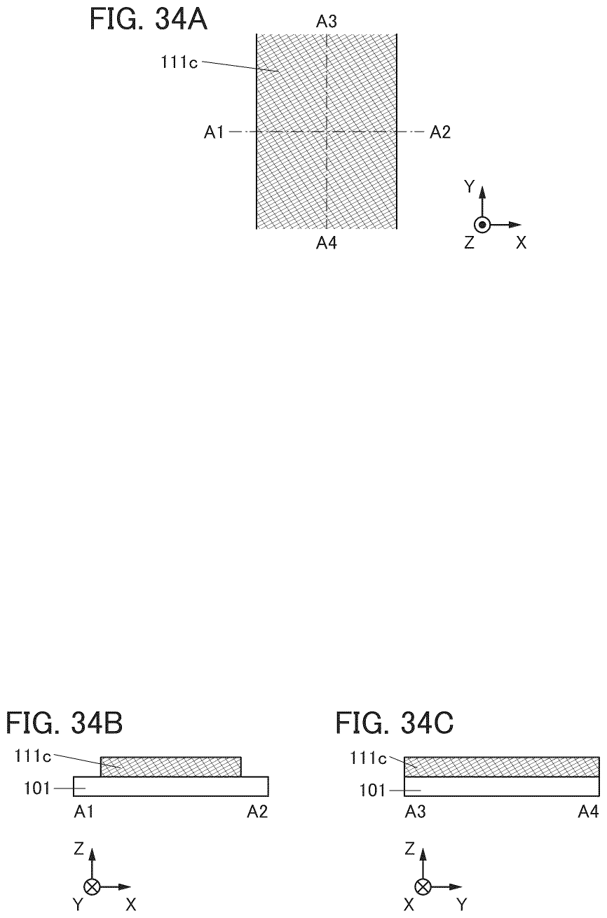

First, a substrate (not illustrated) is prepared, and the insulating layer 101 is formed over the substrate (FIG. 34A to FIG. 34C). Any of the above-described insulating materials can be appropriately used for the insulating layer 101. The insulating layer 101 can be formed by using a film formation method such as a sputtering method, a CVD method, an MBE method, a PLD method, or an ALD method as appropriate.

Next, the conductive layer 111c is formed over the insulating layer 101 (FIG. 34A to FIG. 34C). For example, a conductive film to be the conductive layer 111c is formed and processed, whereby the conductive layer 111c can be formed. For the conductive film to be the conductive layer 111c, any of the above-described conductive materials that can be used for the conductive layer 111 can be used as appropriate.

The conductive film to be the conductive layer 111c can be formed by using a film formation method such as a sputtering method, a CVD method, an MBE method, a PLD method, or an ALD method as appropriate. For example, as the conductive film to be the conductive layer 111c, a stacked-layer film in which tungsten and titanium nitride are deposited in this order by a CVD method can be formed. After the conductive film to be the conductive layer 111c is formed, a pattern is formed by a lithography method, for example, and the conductive film is processed by a dry etching method, a wet etching method, or the like using the pattern, whereby the conductive layer 111c can be formed. Here, for fine processing, the conductive film is preferably processed by a dry etching method.

Note that in a lithography method, first, a resist is exposed to light through a mask. Next, a region exposed to light is removed or left using a developing solution, so that a resist mask is formed. Thus, a pattern is formed.

The resist mask is formed through, for example, exposure of the resist to KrF excimer laser light, ArF excimer laser light, EUV light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

Next, etching treatment is performed using the resist mask. Thus, the conductive layer, a semiconductor layer, the insulating layer, and the like can be processed into desired shapes.

In the case of performing dry etching treatment as the above etching treatment, an etching gas including a halogen can be used as an etching gas; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, a NF₃ gas, a CHF₃ gas, a Cl₂ gas, a BCl₃ gas, a SiCl₄ gas, a CCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus can be used, for example.

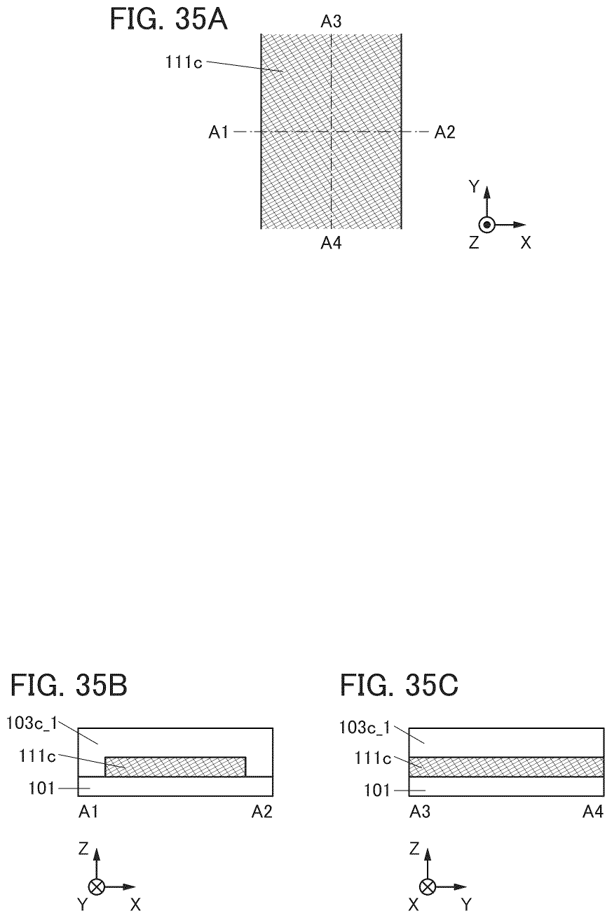

Then, the insulating layer 103c_1 functioning as an interlayer insulating layer is formed over the insulating layer 101 and the conductive layer 111c (FIG. 35A to FIG. 35C). For the insulating layer 103c_1, any of the above-described insulating materials can be appropriately used. The insulating layer 103c_1 can be formed by using a film formation method such as a sputtering method, a CVD method, an MBE method, a PLD method, or an ALD method as appropriate. For example, a silicon oxide film is formed by a sputtering method as the insulating layer 103c_1. The top surface of the formed insulating layer 103c_1 is preferably planarized by chemical mechanical polishing (CMP) treatment. The planarization treatment performed on the insulating layer 103c_1 enables the conductive layer 115c functioning as a wiring to be favorably formed in a later step. Furthermore, aluminum oxide may be deposited over the insulating layer 103c_1 by a sputtering method, and then subjected to CMP treatment until the insulating layer 103c_1 is reached. The CMP treatment can planarize and smooth the surface of the insulating layer 103c_1. When the CMP treatment is performed on the aluminum oxide provided over the insulating layer 103c_1, it is easy to detect the endpoint of the CMP treatment.

Note that the CMP treatment may be skipped in some cases. In that case, the top surface of the insulating layer 103c_1 has a convex curved shape. By not performing planarization treatment, manufacturing cost can be reduced and production yield can be increased.

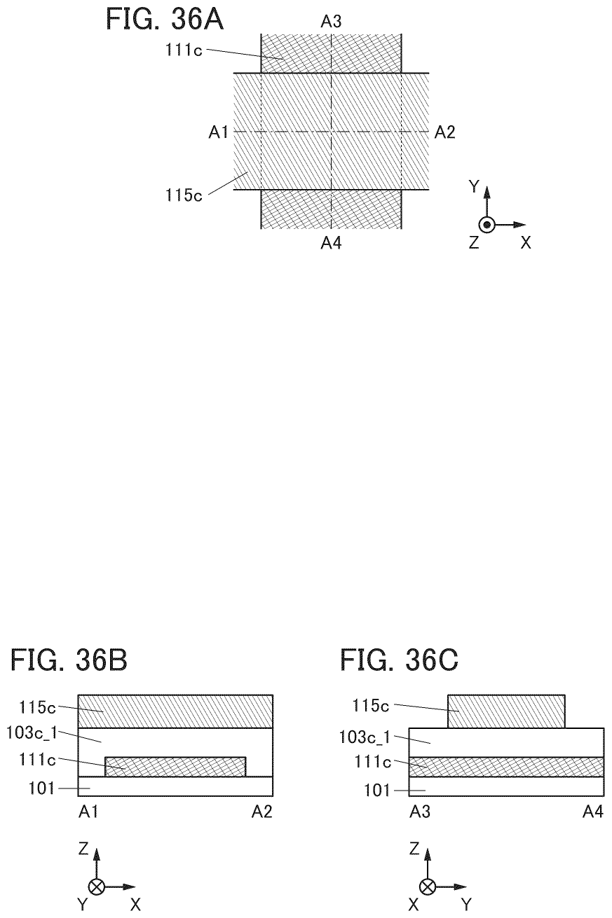

Subsequently, the conductive layer 115c is formed over the insulating layer 103c_1 (FIG. 36A to FIG. 36C). For example, a conductive film to be the conductive layer 115c is formed and processed, whereby the conductive layer 115c can be formed. For the conductive film to be the conductive layer 115c, any of the above-described conductive materials that can be used for the conductive layer 115 can be appropriately used. The conductive film to be the conductive layer 115c can be formed by using a film formation method such as a sputtering method, a CVD method, an MBE method, a PLD method, or an ALD method as appropriate.

After the conductive film to be the conductive layer 115c is formed, a pattern is formed by a lithography method, for example, and the conductive film is processed by a dry etching method, a wet etching method, or the like using the pattern, whereby the conductive layer 115c can be formed. Here, for fine processing, the conductive film is preferably processed by a dry etching method.

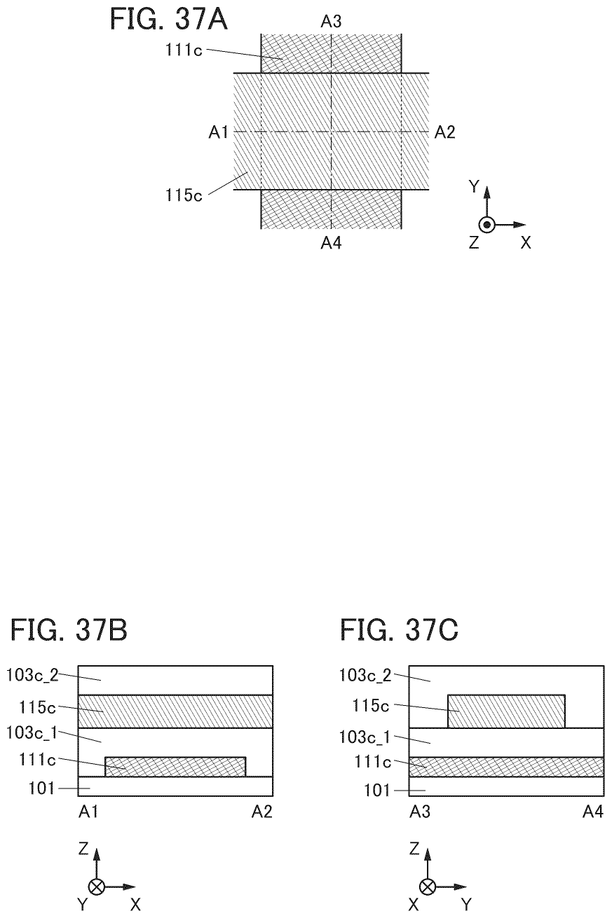

Next, the insulating layer 103c_2 functioning as an interlayer insulating layer is formed over the insulating layer 103c_1 and the conductive layer 115c (FIG. 37A to FIG. 37C). The insulating layer 103c_2 can be formed using the same material and the same formation method as those for the insulating layer 103c_1. After the formation of the insulating layer 103c_2, the top surface of the insulating layer 103c_2 is preferably planarized by CMP treatment.

Here, since the total thickness of the insulating layer 103c_1, the conductive layer 115c, and the insulating layer 103c_2 corresponds to the channel length of the transistor 43, the thicknesses of the insulating layer 103c_1, the conductive layer 115c, and the insulating layer 103c_2 can be set as appropriate in accordance with the design value of the channel length of the transistor 43.

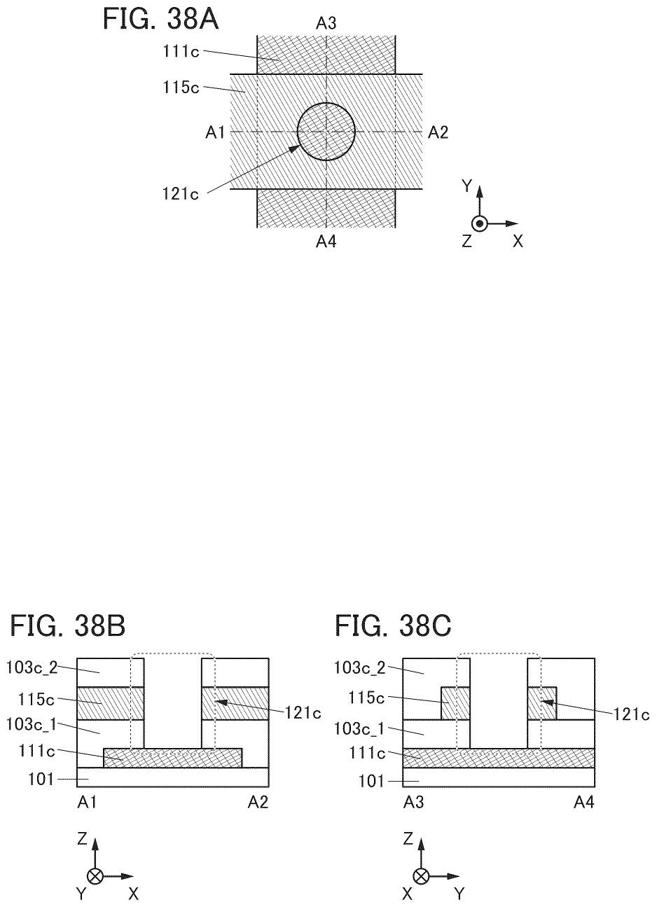

Then, part of the insulating layer 103c_2, part of the conductive layer 115c, and part of the insulating layer 103c_1 are processed, thereby forming the opening 121c that reaches the conductive layer 111c (FIG. 38A to FIG. 38C). The opening 121c can be formed by a lithography method and an etching method, for example.

Here, the sidewall of the opening 121c is preferably perpendicular to the top surface of the conductive layer 111c. With such a structure, the semiconductor device can be reduced in size or highly integrated. Alternatively, the sidewall of the opening 121c may be tapered. When the sidewall of the opening 121c is tapered, the coverage with a later-described metal oxide film to be the semiconductor layer 113c, for example, can be improved, so that defects such as voids can be reduced.

The maximum width of the opening 121c (the diameter in the case where the opening 121c is circular in a plan view) is preferably small. For example, the maximum width of the opening 121c is preferably greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, or greater than or equal to 5 nm and less than or equal to 20 nm.

Since the opening 121c has a high aspect ratio, part of the conductive layer 103c_2, the part of the conductive layer 115c, and part of the insulating layer 103c_1 are preferably processed by anisotropic etching. Processing by a dry etching method is particularly preferable because it is suitable for fine processing. The part of the conductive layer 103c_2, the part of the conductive layer 115c, and the part of the insulating layer 103c_1 may be processed under different conditions. Note that the inclination of the side surface of the insulating layer 103c_2 in the opening 121c, the inclination of the side surface of the conductive layer 115c in the opening 121c, and the inclination of the side surface of the insulating layer 103c_1 in the opening 121c may be different from each other depending on the conditions for processing part of the insulating layer 103c_2, part of the conductive layer 115c, and part of the insulating layer 103c_1.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in an atmosphere of a nitrogen gas or an inert gas, for example. Alternatively, the heat treatment may be performed under reduced pressure. By the above-described heat treatment, impurities such as water contained in the insulating layer 103c_1 and the insulating layer 103c_2, for example, can be reduced before the later-described metal oxide film to be the semiconductor layer 113c is formed.

The gas used in the above heat treatment is preferably highly purified. For example, the amount of moisture contained in the gas used in the above heat treatment is lower than or equal to 1 ppb, preferably lower than or equal to 0.1 ppb, further preferably lower than or equal to 0.05 ppb. The heat treatment using a highly purified gas can prevent, for example, entry of moisture into the insulating layer 103c_1 and the insulating layer 103c_2 as much as possible.

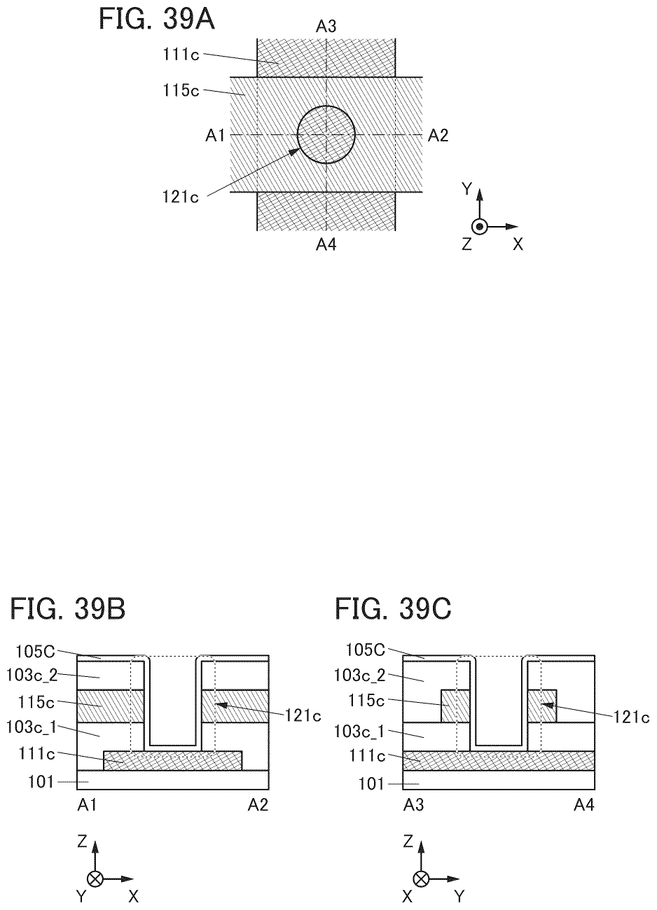

Then, an insulating film 105C to be the insulating layer 105c later is formed in contact with the top surface of the insulating layer 103c_2, the side surface of the insulating layer 103c_2, the side surface of the conductive layer 115c, the side surface of the insulating layer 103c_1, and the top surface of the conductive layer 111c (FIG. 39A to FIG. 39C). For the insulating film 105C, any of the above-described insulating materials can be appropriately used. The insulating film 105C can be formed by using a film formation method such as a sputtering method, a CVD method, an MBE method, a PLD method, or an ALD method as appropriate. Here, the insulating film 105C is preferably formed in contact with the bottom portion and the sidewall of the opening 121c with a high aspect ratio. Thus, the insulating film 105C is preferably formed by a film formation method enabling favorable coverage, and is further preferably formed by a CVD method, an ALD method, or the like. For example, a film of silicon oxide is formed as the insulating film 105C by an ALD method.

In the case where the sidewall of the opening 121c is tapered, the method for forming the insulating film 105C is not limited to a CVD method or an ALD method. For example, a sputtering method may be employed.

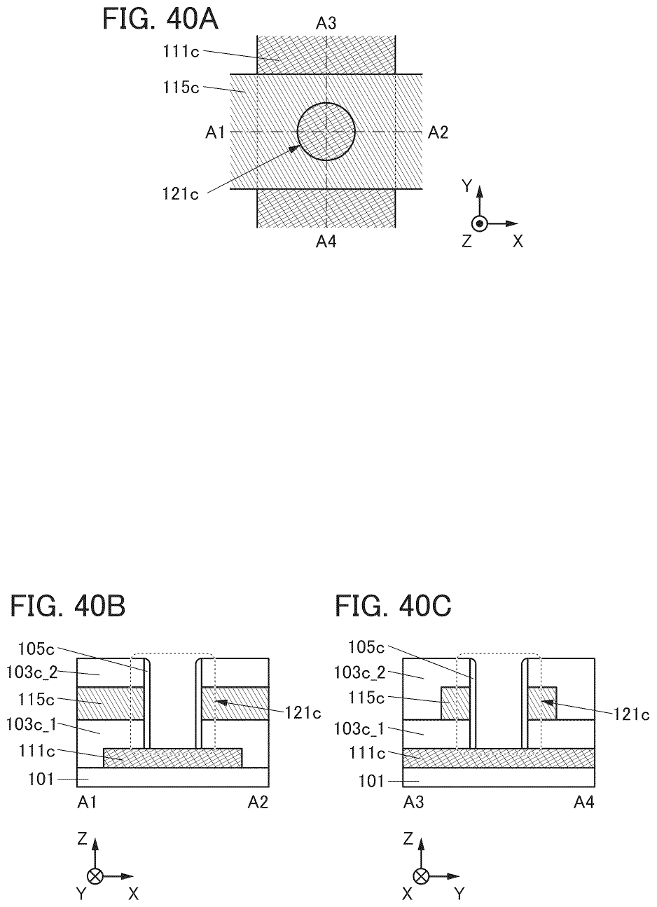

Next, the insulating film 105C is processed to expose the top surface of the insulating layer 103c_2 and the top surface of the conductive layer 111c, thereby forming the insulating layer 105c in contact with the side surface of the insulating layer 103c_1, the side surface of the conductive layer 115c, and the side surface of the insulating layer 103c_2 (FIG. 40A to FIG. 40C). An upper end portion of the insulating layer 105c has a curved shape.

Anisotropic etching is preferably used to process the insulating film 105C. When anisotropic etching is used to process the insulating film 105C, only a region in contact with the bottom portion of the opening 121c can be selectively removed in the insulating film 105C positioned in the opening 121c with a high aspect ratio. Accordingly, the insulating layer 105c in contact with the sidewall of the opening 121c can be formed with high accuracy.

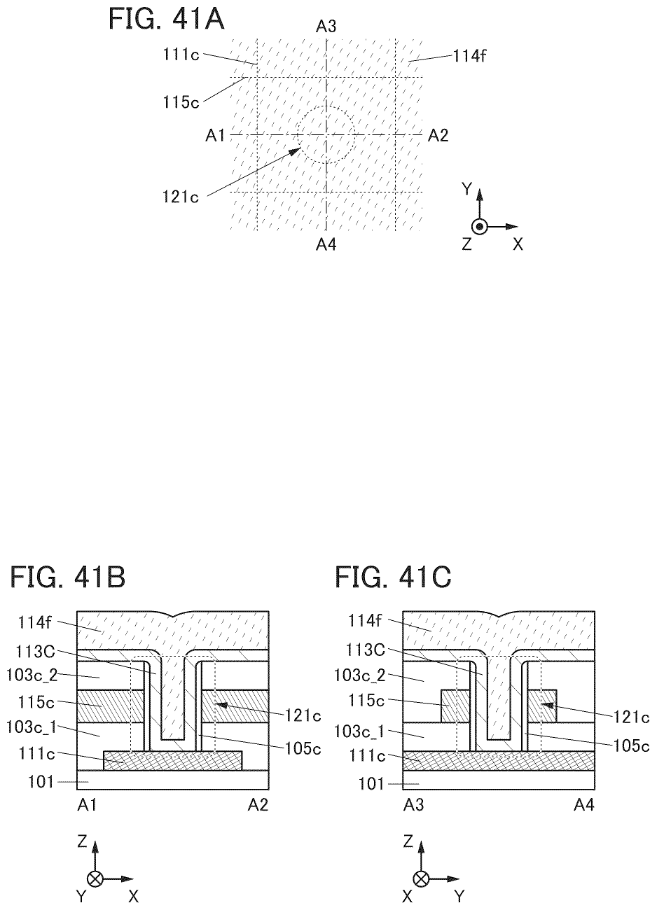

Subsequently, a metal oxide film 113C to be the semiconductor layer 113c later is formed in contact with the top surface of the conductive layer 111c, the side surface of the insulating layer 105c, the curved portion of the insulating layer 105c, and the top surface of the insulating layer 103c_2 (FIG. 41A to FIG. 41C). For the metal oxide film 113C, any of the above-described metal oxides that can be used for the semiconductor layer 113 can be appropriately used. The metal oxide film 113C can be formed by using a film formation method such as a sputtering method, a CVD method, an MBE method, a PLD method, or an ALD method as appropriate. Here, the metal oxide film 113C is preferably formed in contact with the side surface of the insulating layer 105c and the top surface of the conductive layer 111c in the opening 121c with a high aspect ratio. Thus, the metal oxide film 113C is preferably formed by a film formation method enabling favorable coverage, and is further preferably formed by a CVD method, an ALD method, or the like. For example, a film of In—Ga—Zn oxide is formed as the metal oxide film 113C by an ALD method. Alternatively, a film of In—Al—Zn oxide may be formed as the metal oxide film 113C.

In the case where the sidewall of the opening 121c is tapered, the method for forming the metal oxide film 113C is not limited to a CVD method or an ALD method. For example, a sputtering method may be employed.

In the case where the semiconductor layer 113c has a stacked-layer structure, the layers included in the semiconductor layer 113c may be formed by the same film formation method or different film formation methods. For example, in the case where the semiconductor layer 113c has a stacked-layer structure of two layers, the lower layer of the metal oxide film 113C may be formed by a sputtering method and the upper layer of the metal oxide film 113C may be formed by an ALD method. A metal oxide film formed by a sputtering method is likely to have crystallinity. Thus, when a metal oxide film having crystallinity is provided as the lower layer of the metal oxide film 113C, the crystallinity of the upper layer of the metal oxide film 113C can be increased. Even when a pinhole, disconnection, or the like is caused in the lower layer of the metal oxide film 113C formed by a sputtering method, a portion overlapping with the pinhole, disconnection, or the like can be filled with the upper layer of the metal oxide film 113C formed by an ALD method achieving excellent coverage.

Here, the metal oxide film 113C is preferably formed in contact with the top surface of the conductive layer 111a in the opening 121c, the side surface of the insulating layer 105c in the opening 121c, the curved portion of the insulating layer 105c, and the top surface of the insulating layer 103c_2. When the metal oxide film is formed in contact with the conductive layer 111c, the conductive layer 111c functions as one of the source electrode and the drain electrode of the transistor 43.

Next, heat treatment is preferably performed. The heat treatment can be performed in a temperature range where the metal oxide film 113C does not become polycrystals, i.e., at higher than or equal to 250° C. and lower than or equal to 650° C., preferably higher than or equal to 400° C. and lower than or equal to 600° C. For the details of the heat treatment, the above description can be referred to.

Here, the above-described heat treatment is preferably performed in a state where the insulating layer 103c_2 including excess oxygen is provided in contact with the metal oxide film 113C. By performing the heat treatment in such a manner, oxygen is supplied from the insulating layer 103c_2 to the metal oxide film 113C, so that oxygen vacancies and VoH in the semiconductor layer 113c to be formed later can be reduced.

Although the heat treatment is performed after the metal oxide film 113C is formed in the above description, the present invention is not limited thereto. The heat treatment may be performed in a later step.

Then, a film 114f to be the layer 114 later is formed over the metal oxide film 113C (FIG. 41A to FIG. 41C). The film 114f is formed to fill at least a concave portion formed over the metal oxide film 113C in the opening 121c. As the film 114f, an organic insulating film functioning as a planarization film is preferably formed by a coating method or the like.

Examples of a material that can be used for the film 114f include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. For the film 114f, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used as a photosensitive resin. As a photosensitive organic resin, either a positive material or a negative material may be used.

Note that the film 114f does not need to be formed in the case where a concave portion is not formed over the metal oxide film 113C in the opening 121c.

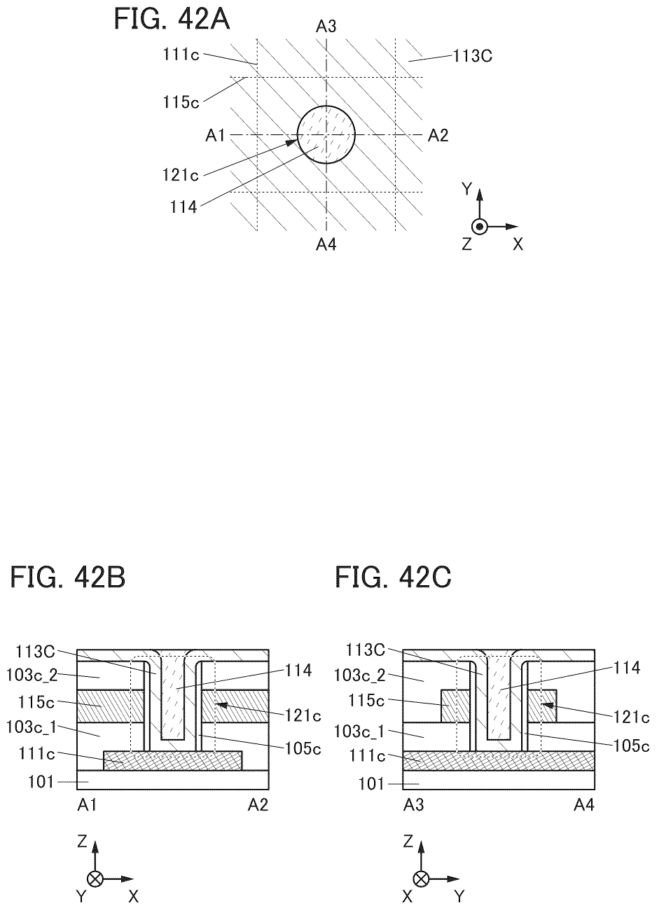

Subsequently, the top surface of the film 114f is polished by CMP treatment, so that the top surface of the metal oxide film 113C is exposed. By the treatment, the layer 114 whose height with respect to the substrate surface is substantially equal to the uppermost surface of the metal oxide film 113C is formed (FIG. 42A to FIG. 42C).

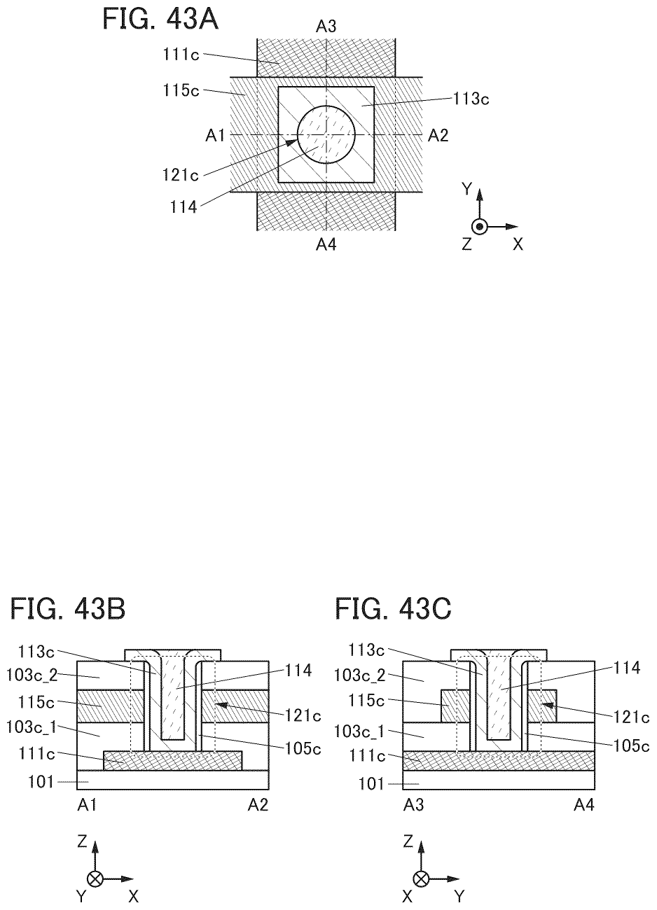

Next, a pattern for the metal oxide film 113C is formed by a lithography method, for example, and then, the metal oxide film 113C is processed by an etching method using the pattern. Thus, the semiconductor layer 113c is formed to include a region overlapping with the opening 121c (FIG. 43A to FIG. 43C). Consequently, part of the semiconductor layer 113c is formed in the opening 121c. The semiconductor layer 113c is in contact with part of the top surface of the insulating layer 103c_2. Accordingly, the semiconductor layer 113c including a region in contact with the top surface of the conductive layer 111c in the opening 121c, a region in contact with the side surface of the insulating layer 105c in the opening 121c, a region in contact with the curved portion of the insulating layer 105c, and a region in contact with the top surface of the insulating layer 103c_2 is formed.

Here, the conductive layer 115c and the semiconductor layer 113c include a region where they face each other with the insulating layer 105c therebetween. In the transistor 43, the conductive layer 115c functions as the gate electrode. Thus, the region of the semiconductor layer 113c that faces the conductive layer 115c functions as the channel formation region of the transistor 43. The region of the insulating layer 105c that is sandwiched between the conductive layer 115c and the semiconductor layer 113c functions as the gate insulating layer of the transistor 43.

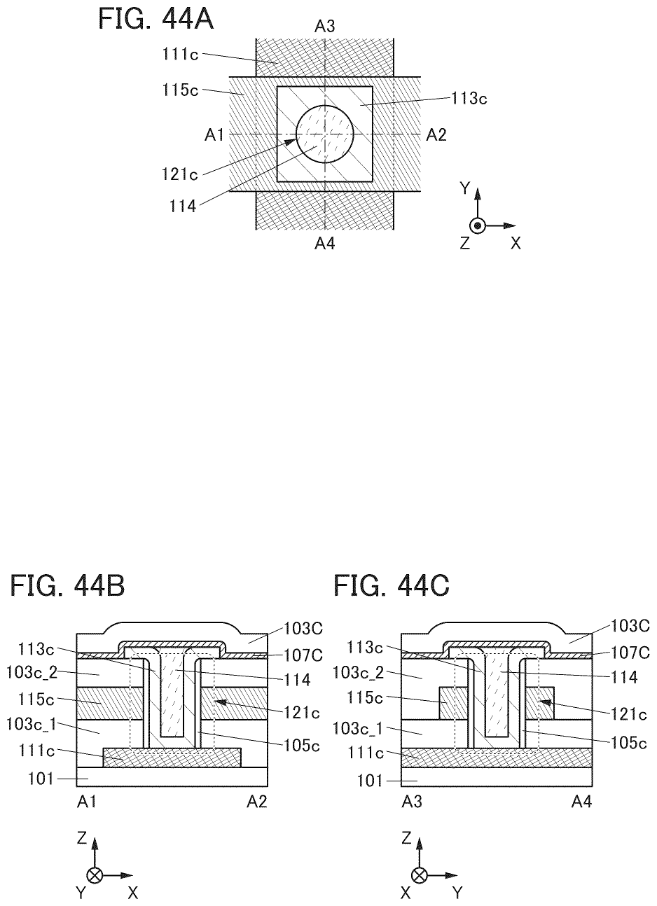

Next, an insulating film 107C to be the insulating layer 107c later and an insulating film 103C to be the insulating layer 103c_3 later are formed in this order over the semiconductor layer 113c, the layer 114, and the insulating layer 103c_2 (FIG. 44A to FIG. 44C). The insulating film 107C and the insulating film 103C can each be formed by using a film formation method such as a sputtering method, a CVD method, an MBE method, a PLD method, or an ALD method as appropriate.

The insulating film 107C is provided in contact with the top surface of the insulating layer 103c_2, the side surface of the semiconductor layer 113c, the top surface of the semiconductor layer 113c, and the top surface of the layer 114. The insulating film 103C is provided in contact with the top surface of the insulating film 107C. For the insulating film 107C and the insulating film 103C, any of the above-described insulating materials that can be used for the insulating layer 107 and the insulating layer 103, respectively, can be used as appropriate.

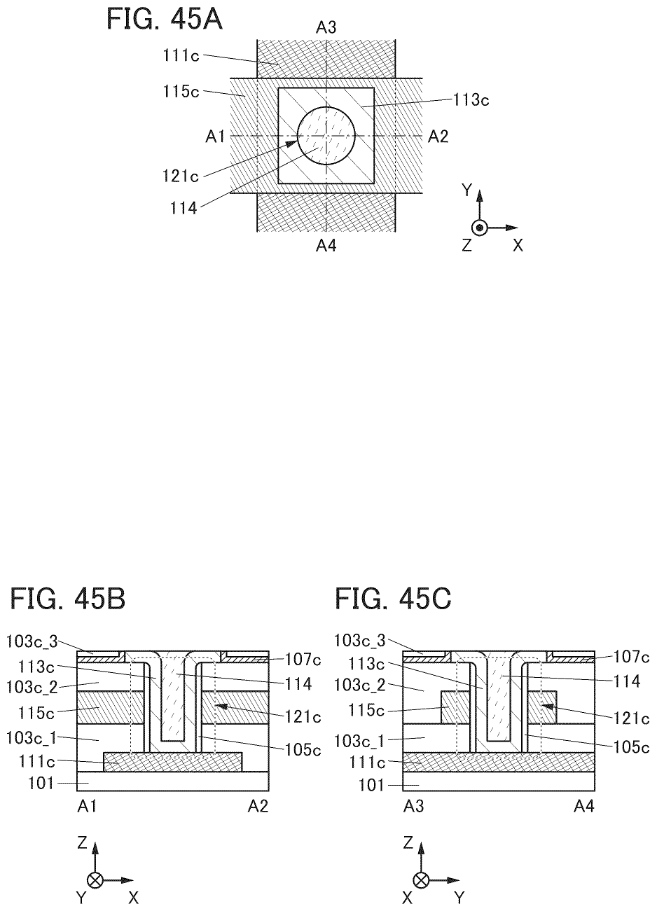

Then, the top surfaces of the insulating film 103C and the insulating film 107C are polished by CMP treatment, so that the top surface of the semiconductor layer 113c is exposed. By the treatment, the insulating layer 103c_3 and the insulating layer 107c whose heights with respect to the substrate surface are substantially equal to the uppermost surface of the semiconductor layer 113c and the top surface of the layer 114 are formed (FIG. 45A to FIG. 45C).

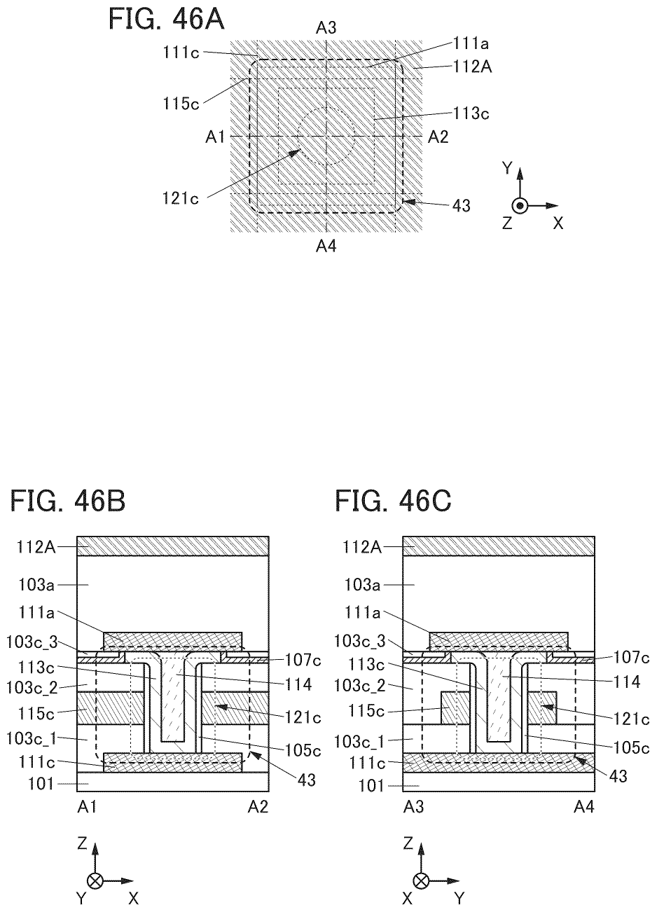

Next, the conductive layer 111a is formed over and in contact with the semiconductor layer 113c, the layer 114, the insulating layer 107c, and the insulating layer 103c_3 (FIG. 46A to FIG. 46C). For example, a conductive film to be the conductive layer 111a is formed and processed, whereby the conductive layer 111a can be formed. The conductive film to be the conductive layer 111a can be formed by the same method as the conductive layer 111c by appropriately using any of the above-described conductive materials that can be used for the conductive layer 111.

Here, the top surface of the semiconductor layer 113c and the bottom surface of the conductive layer 111a are in contact with each other. Thus, the conductive layer 111a functions as the other of the source electrode and the drain electrode of the transistor 43.

In the above manner, the transistor 43 including the conductive layer 111c, the conductive layer 111a, the semiconductor layer 113c, the insulating layer 105c, and the conductive layer 115c can be formed. As described above, the conductive layer 111c functions as the one of the source electrode and the drain electrode of the transistor 43, the conductive layer 111a functions as the other of the source electrode and the drain electrode of the transistor 43, the insulating layer 105c functions as the gate insulating layer of the transistor 43, and the conductive layer 115c functions as the gate electrode of the transistor 43.

Subsequently, the insulating layer 103a functioning as an interlayer insulating layer is formed over the conductive layer 111a and the insulating layer 103c_3 (FIG. 46A to FIG. 46C). The insulating layer 103a can be formed by the same method as the insulating layer 103c_1 and the insulating layer 103c_2 by using any of the above insulating materials as appropriate. After the formation of the insulating layer 103a, the top surface of the insulating layer 103a is preferably planarized by CMP treatment. The planarization treatment performed on the insulating layer 103a enables the conductive layer 112a functioning as a wiring to be favorably formed in a later step.

Note that the CMP treatment may be skipped in some cases. In that case, the top surface of the insulating layer 103a has a convex curved shape. By not performing planarization treatment, manufacturing cost can be reduced and production yield can be increased.

Since the thickness of the insulating layer 103a over the conductive layer 111a corresponds to the channel length of the transistor 41, the thickness of the insulating layer 103a can be set as appropriate depending on the design value of the channel length of the transistor 41.

When the insulating layer 103a is formed by a sputtering method in an oxygen-containing atmosphere, the insulating layer 103a including excess oxygen can be formed. Since a molecule containing hydrogen is not used as a deposition gas in a sputtering method, the hydrogen concentration of the insulating layer 103a can be reduced. When the insulating layer 103a is formed in this manner, oxygen can be supplied from the insulating layer 103a to the channel formation region of the semiconductor layer 113a, which is to be formed in a later step; hence, oxygen vacancies and VoH therein can be reduced.

Then, a conductive film 112A to be the conductive layer 112a later is formed over the insulating layer 103a (FIG. 46A to FIG. 46C). For the conductive film 112A, any of the above-described conductive materials that can be used for the conductive layer 112 can be appropriately used. The conductive film 112A can be formed by using a film formation method such as a sputtering method, a CVD method, an MBE method, a PLD method, or an ALD method as appropriate.

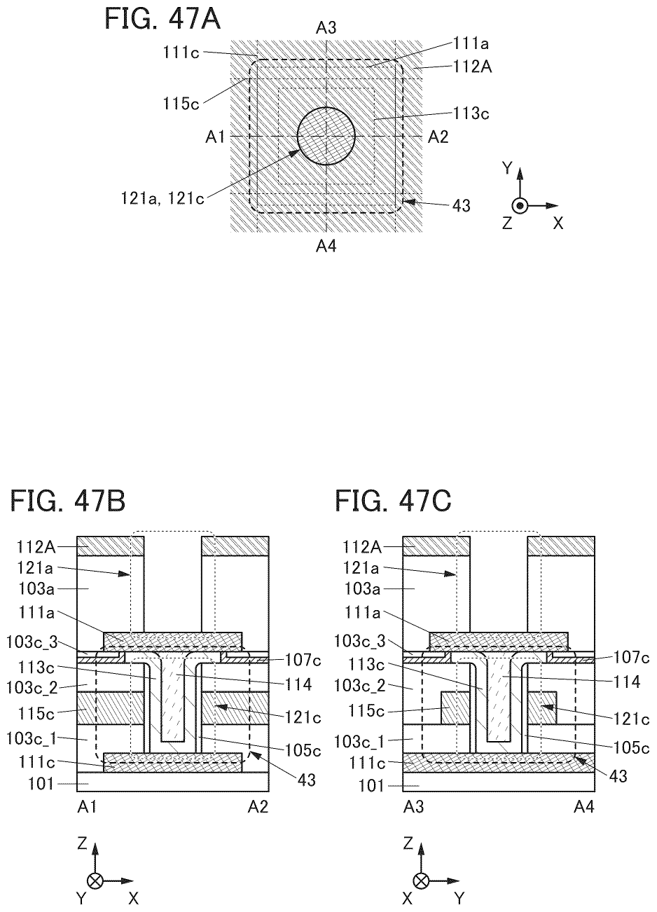

Next, part of the conductive film 112A and part of the insulating layer 103a are processed, thereby forming the opening 121a that reaches the conductive layer 111a (FIG. 47A to FIG. 47C). The opening 121a can be formed by a lithography method and an etching method, for example.

As described above, the sidewall of the opening 121a is preferably perpendicular to the top surface of the conductive layer 111a. With such a structure, the semiconductor device can be reduced in size or highly integrated. Alternatively, the sidewall of the opening 121a may be tapered. When the sidewall of the opening 121a is tapered, the coverage with a later-described metal oxide film to be the semiconductor layer 113a, for example, can be improved, so that defects such as voids can be reduced.

The maximum width of the opening 121a (the diameter in the case where the opening 121a is circular in a plan view) is preferably small. For example, the maximum width of the opening 121a is preferably greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, or greater than or equal to 5 nm and less than or equal to 20 nm.

Since the opening 121a has a high aspect ratio, part of the conductive film 112A and part of the insulating layer 103a are preferably processed by anisotropic etching. Processing by a dry etching method is particularly preferable because it is suitable for fine processing. Part of the conductive film 112A and part of the insulating layer 103a may be processed under different conditions. Depending on the conditions for processing part of the conductive film 112A and part of the insulating layer 103a, the inclination of the side surface of the conductive layer 112a in the opening 121a may be different from the inclination of the side surface of the insulating layer 103a in the opening 121a as described above.

Next, heat treatment may be performed. For the details of the heat treatment, the above description can be referred to. By the heat treatment, impurities such as water contained in the insulating layer 103a and the like can be reduced before the later-described metal oxide film to be the semiconductor layer 113a is formed.

Then, a metal oxide film to be the semiconductor layer 113a is formed in contact with the bottom portion and the sidewall of the opening 121a and at least part of the top surface of the conductive film 112A. For the metal oxide film, any of the above-described metal oxides that can be used for the semiconductor layer 113 can be appropriately used. The metal oxide film can be formed by the same formation method as the metal oxide film 113C. For example, a film of In—Ga—Zn oxide is formed as the metal oxide film by an ALD method.

Note that in the case where the sidewall of the opening 121a is tapered, the method for forming the metal oxide film to be the semiconductor layer 113a is not limited to a CVD method or an ALD method. For example, a sputtering method may be employed.

In the case where the semiconductor layer 113a has a stacked-layer structure, the layers included in the semiconductor layer 113a may be formed by the same film formation method or different film formation methods. For example, in the case where the semiconductor layer 113a has a stacked-layer structure of two layers, the lower metal oxide film may be formed by a sputtering method and the upper metal oxide film may be formed by an ALD method. A metal oxide film formed by a sputtering method is likely to have crystallinity. Thus, when a metal oxide film having crystallinity is provided as the lower metal oxide film, the crystallinity of the upper metal oxide film can be increased. Even when a pinhole, disconnection, or the like is caused in the lower metal oxide film formed by a sputtering method, a portion overlapping with the pinhole, disconnection, or the like can be filled with the upper metal oxide film formed by an ALD method achieving excellent coverage.

Here, the metal oxide film to be the semiconductor layer 113a is preferably formed in contact with the top surface of the conductive layer 111a in the opening 121a, the side surface of the insulating layer 103a in the opening 121a, the side surface of the conductive layer 112a in the opening 121a, and the top surface of the conductive layer 112a. When the metal oxide film is formed in contact with the conductive layer 111a, the conductive layer 111a functions as one of the source electrode and the drain electrode of the transistor 41. When the metal oxide film is formed in contact with the conductive layer 112a, the conductive layer 112a functions as the other of the source electrode and the drain electrode of the transistor 41.

Next, heat treatment is preferably performed. For the details of the heat treatment, the above description can be referred to.

Here, the heat treatment is preferably performed in a state where the insulating layer 103a including excess oxygen is in contact with the metal oxide film. When the heat treatment is performed in that manner, oxygen can be supplied from the insulating layer 103a to the channel formation region of the semiconductor layer 113a, so that oxygen vacancies and VoH can be reduced.

Although the heat treatment is performed after the metal oxide film is formed in the above description, the present invention is not limited thereto. The heat treatment may be performed in a later step.

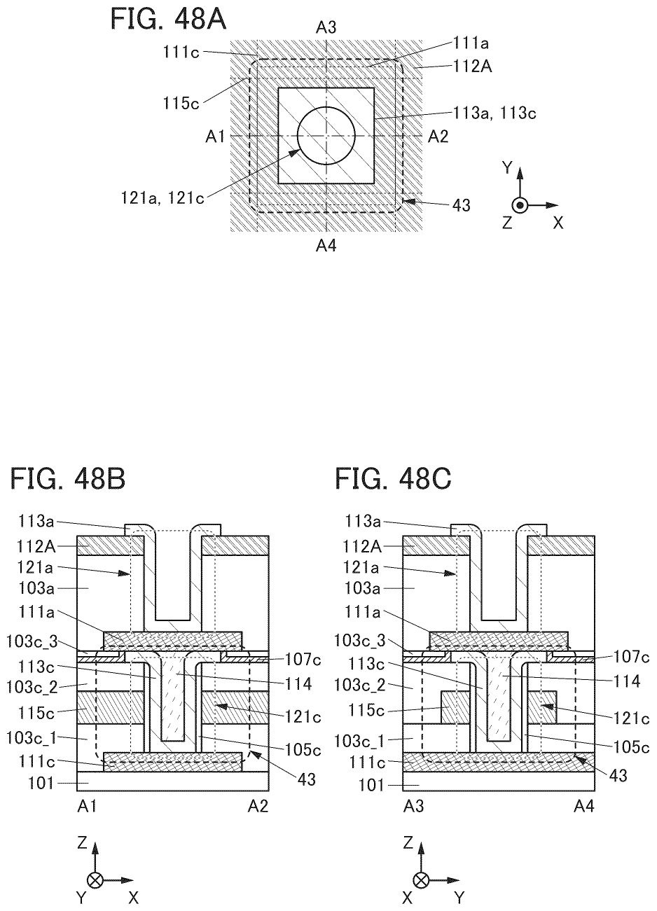

Subsequently, a pattern for the metal oxide film to be the semiconductor layer 113a is formed by a lithography method, for example, and then, the metal oxide film is processed by an etching method using the pattern. Thus, the semiconductor layer 113a is formed to include a region overlapping with the opening 121a (FIG. 48A to FIG. 48C). Accordingly, part of the semiconductor layer 113a is formed in the opening 121a. The semiconductor layer 113a is in contact with the side surface and part of the top surface of the conductive film 112A. In the above manner, the semiconductor layer 113a is formed to include a region in contact with the top surface of the conductive layer 111a, a region in contact with the side surface of the conductive film 112A, and a region in contact with the top surface of the conductive film 112A and to include a region positioned in the opening 121a.

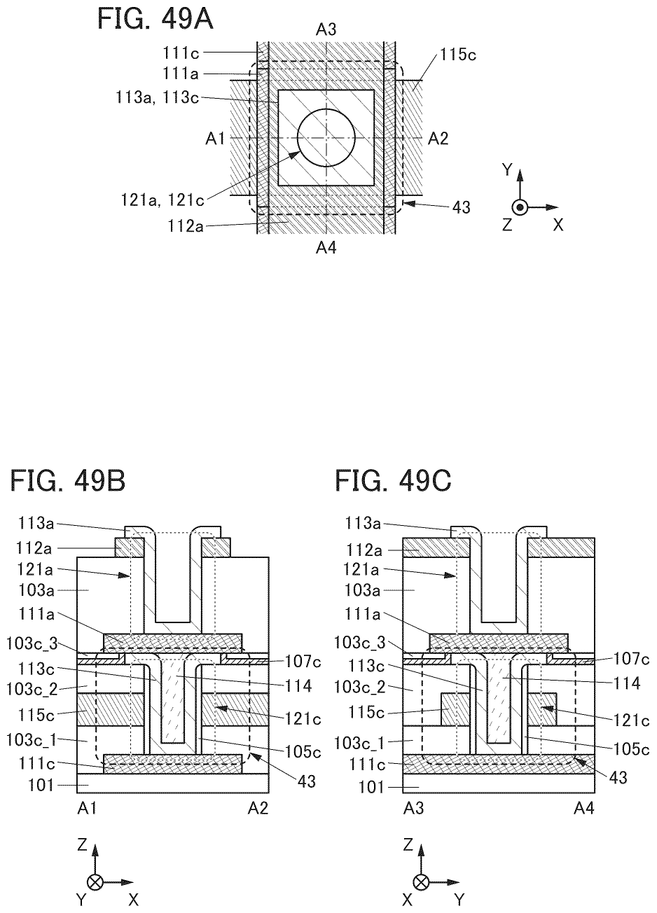

Then, part of the conductive film 112A is processed, whereby the conductive layer 112a is formed to include a region overlapping with the conductive layer 111a (FIG. 49A to FIG. 49C). The conductive layer 112a can be formed by, for example, forming a pattern by a lithography method and then processing the conductive film 112A by an etching method using the pattern. Although the processing can be performed, for example, by a dry etching method or a wet etching method, processing by a dry etching method is preferable because it is suitable for microfabrication.

Here, a method that is different from the above-described method in the formation of the conductive layer 112a and the semiconductor layer 113a is described.

The steps up to and including the formation of the conductive film 112A illustrated in FIG. 46A to FIG. 46C are performed in a manner similar to the above-described method.

Next, part of the conductive film 112A is processed, thereby forming the conductive layer 112a. For example, the above description can be referred to for the method for forming the conductive layer 112a.

Then, part of the conductive layer 112a and part of the insulating layer 103a are processed, thereby forming the opening 121a reaching the conductive layer 111a. For example, the above description can be referred to for the method for forming the opening 121a.

Next, heat treatment may be performed. For example, the above description can be referred to for the conditions of the heat treatment.

Subsequently, a metal oxide film to be the semiconductor layer 113a is formed in contact with the bottom portion and the sidewall of the opening 121a and at least part of the top surface of the conductive layer 112a. Here, the metal oxide film includes a region in contact with the top surface of the insulating layer 103a. For example, the above description can be referred to for the method for forming the metal oxide film.

Next, heat treatment is preferably performed. For example, the above description can be referred to for the conditions of the heat treatment.

Then, the metal oxide film to be the semiconductor layer 113a is processed by a lithography method, thereby forming the semiconductor layer 113a (FIG. 49A to FIG. 49C).

The following steps for manufacturing the semiconductor device are common to both of the methods.

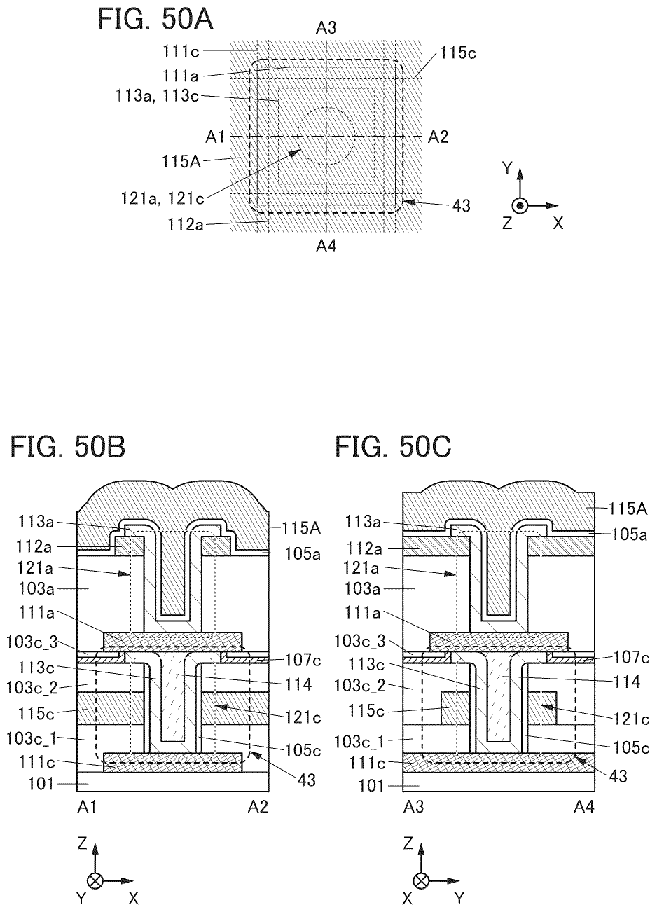

Next, the insulating layer 105a is formed over the semiconductor layer 113a, the conductive layer 112a, and the insulating layer 103a (FIG. 50A to FIG. 50C). For the insulating layer 105a, any of the above-described insulating materials can be appropriately used. The insulating layer 105a can be formed by using a film formation method such as a sputtering method, a CVD method, an MBE method, a PLD method, or an ALD method as appropriate. Here, the insulating layer 105a is preferably formed in contact with the semiconductor layer 113a that is provided in the opening 121a having a high aspect ratio. Thus, the insulating layer 105a is preferably formed by a film formation method enabling favorable coverage, and is further preferably formed by a CVD method, an ALD method, or the like. For example, a film of silicon oxide is formed as the insulating layer 105a by an ALD method.

In the case where the sidewall of the opening 121a is tapered, the method for forming the insulating layer 105a is not limited to a CVD method or an ALD method. For example, a sputtering method may be employed.

When the insulating layer 105a is formed after the semiconductor layer 113a is formed, the side end portion of the semiconductor layer 113a is covered with the insulating layer 105a. Thus, a short circuit between the semiconductor layer 113a and the conductive layer 115a formed in a later step can be prevented. Furthermore, in the above-described structure, the side end portion of the conductive layer 112a is covered with the insulating layer 105a. Thus, a short circuit between the conductive layer 112a and the conductive layer 115a can be prevented.

Subsequently, a conductive film 115A is formed over the insulating layer 105a to fill a concave portion defined by the insulating layer 105a (FIG. 50A to FIG. 50C). For the conductive film 115A, any of the above-described conductive materials that can be used for the conductive layer 115a can be appropriately used. The conductive film 115A can be formed by using a film formation method such as a sputtering method, a CVD method, an MBE method, a PLD method, or an ALD method as appropriate. Here, the conductive film 115A is preferably formed in contact with the insulating layer 105a provided in the opening 121a with a high aspect ratio. Thus, the conductive film 115A is preferably formed by a film formation method enabling favorable coverage or a good filling property, and is further preferably formed by a CVD method, an ALD method, or the like.

In the case where the conductive film 115A is formed by a CVD method, the average surface roughness of the top surface of the conductive film 115A is sometimes increased. In this case, the top surface of the conductive film 115A is preferably planarized by a CMP method. At this time, before the CMP treatment, a silicon oxide film or a silicon oxynitride film may be formed over the conductive film 115A and the CMP treatment may be performed until the silicon oxide film or the silicon oxynitride film is removed.

Although the conductive film 115A is provided to fill the opening 121a in the above description, the present invention is not limited thereto. For example, a concave portion reflecting the shape of the opening 121a is formed in a center portion of the conductive film 115A in some cases. The concave portion may be filled with an inorganic insulating material, for example.

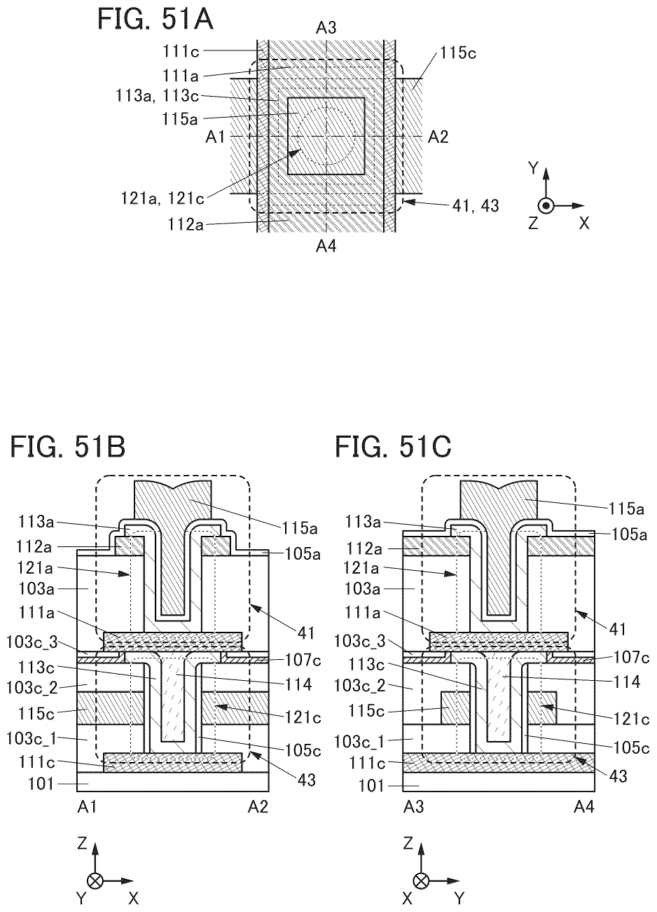

Next, part of the conductive film 115A is processed, thereby forming the conductive layer 115a (FIG. 51A to FIG. 51C). The conductive layer 115a can be formed by, for example, forming a pattern by a lithography method and then processing the conductive film 115A by an etching method using the pattern. Although the processing can be performed, for example, by a dry etching method or a wet etching method, processing by a dry etching method is preferable because it is suitable for microfabrication. The conductive layer 115a is formed over the insulating layer 105a to include a region overlapping with the semiconductor layer 113a.

In the above manner, the transistor 41 including the conductive layer 111a, the conductive layer 112a, the semiconductor layer 113a, the insulating layer 105a, and the conductive layer 115a can be formed. As described above, the conductive layer 111a functions as the one of the source electrode and the drain electrode of the transistor 41 (and the other of the source electrode and the drain electrode of the transistor 43), the conductive layer 112a functions as the other of the source electrode and the drain electrode of the transistor 41, the insulating layer 105a functions as the gate insulating layer of the transistor 41, and the conductive layer 115a functions as the gate electrode of the transistor 41.

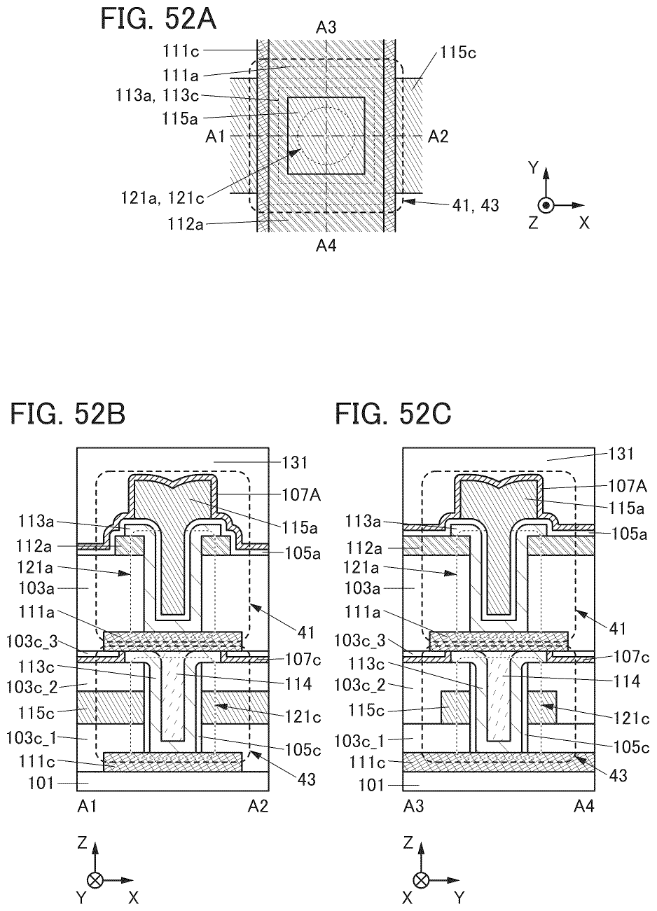

Then, an insulating film 107A to be the insulating layer 107a later is formed to cover the conductive layer 115a and the insulating layer 105a. After that, the insulating layer 131 is formed over the insulating film 107A (FIG. 52A to FIG. 52C). For the insulating film 107A and the insulating layer 131, any of the above-described insulating materials that can be used for the insulating layer 107 and the insulating layer 131, respectively, can be used as appropriate. The insulating film 107A and the insulating layer 131 can each be formed by using a film formation method such as a sputtering method, a CVD method, an MBE method, a PLD method, or an ALD method as appropriate.

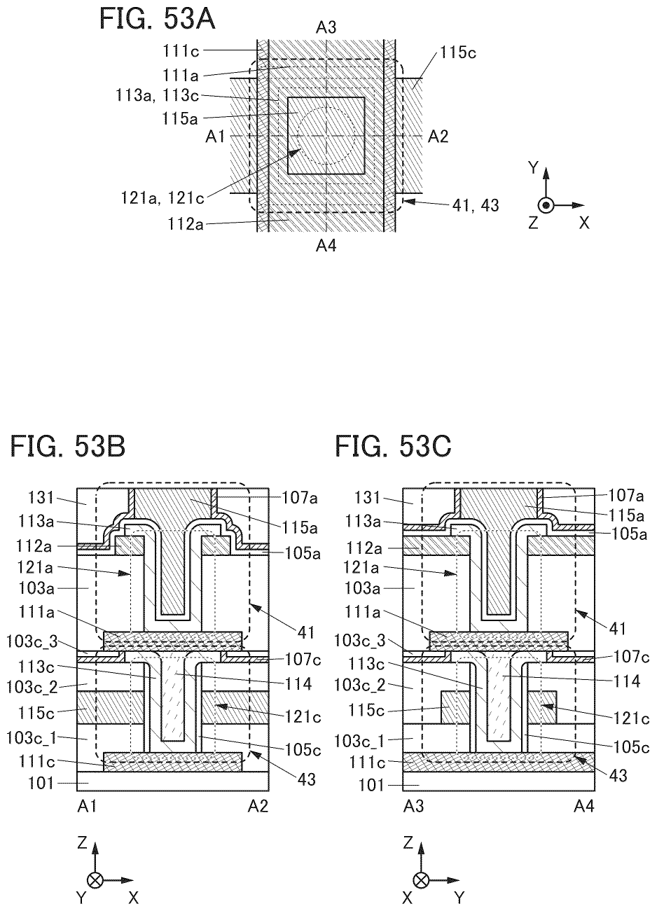

Next, the top surfaces of the insulating layer 131, the insulating film 107A, and the conductive layer 115a are polished by CMP treatment. By the treatment, the insulating layer 131, the insulating layer 107a, and the conductive layer 115a that are substantially equal in height from the substrate surface are formed (FIG. 53A to FIG. 53C).

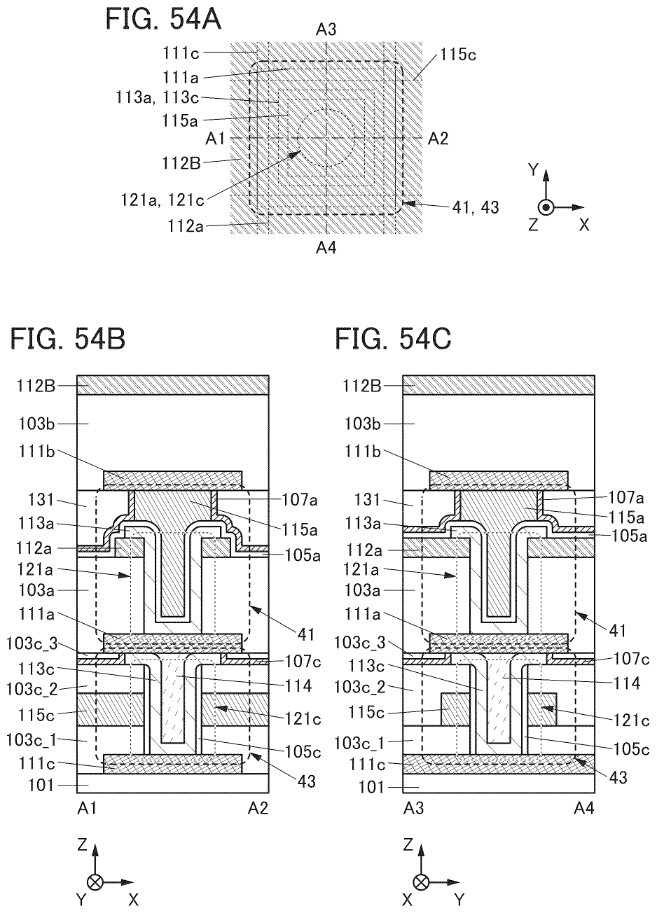

Subsequently, the conductive layer 111b is formed over the conductive layer 115a, the insulating layer 107a, and the insulating layer 131 (FIG. 54A to FIG. 54C). For example, the conductive layer 111b is formed to include a region in contact with the top surface of the conductive layer 115a. Thus, the conductive layer 111b and the conductive layer 115a can be electrically connected to each other. The conductive layer 111b can be formed by a method similar to that for the conductive layer 111a.

Next, the insulating layer 103b functioning as an interlayer insulating layer is formed over the insulating layer 131 and the conductive layer 111b, and a conductive film 112B is formed over the insulating layer 103b (FIG. 54A to FIG. 54C). The insulating layer 103b can be formed by a method similar to that for the insulating layer 103a, and the conductive film 112B can be formed by a method similar to that for the conductive film 112A.

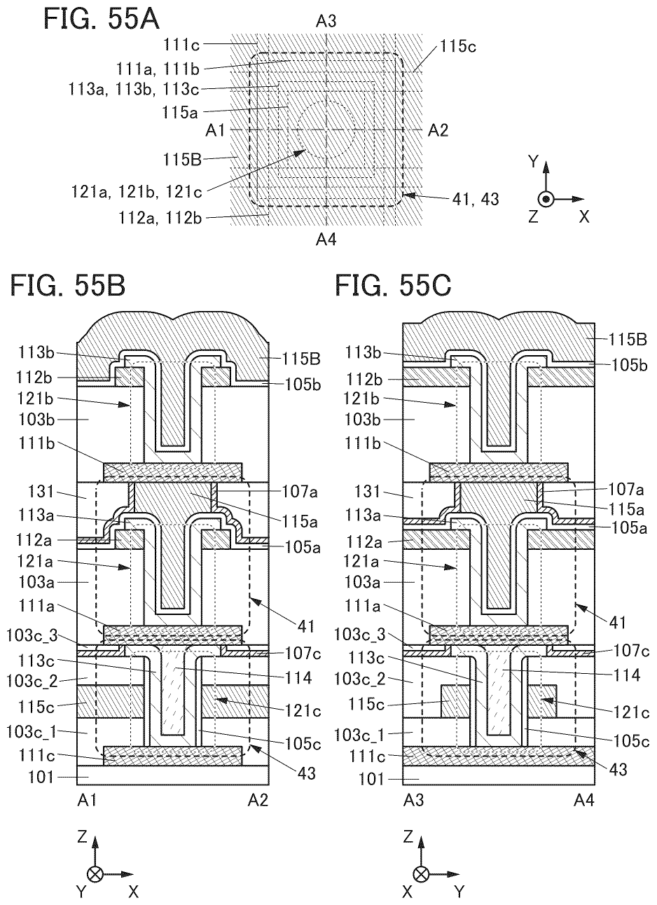

Then, the conductive layer 112b, the opening 121b, the semiconductor layer 113b, the insulating layer 105b, and a conductive film 115B are formed by methods similar to the respective methods for forming the conductive layer 112a, the opening 121a, the semiconductor layer 113a, the insulating layer 105a, and the conductive film 115A (FIG. 55A to FIG. 55C).

Next, part of the conductive film 115B is processed, thereby forming the conductive layer 115b. The conductive layer 115b can be formed by a method similar to that for the conductive layer 115a. The conductive layer 115b is formed over the insulating layer 105b to include a region overlapping with the semiconductor layer 113b (FIG. 4A to FIG. 4C).

Subsequently, the insulating layer 107b is formed over the conductive layer 115b and the insulating layer 105b (FIG. 4A to FIG. 4C). The insulating layer 107b can be formed using the same material and the same formation method as those for the insulating layer 107a.

In the above manner, the transistor 42 including the conductive layer 111b, the conductive layer 112b, the semiconductor layer 113b, the insulating layer 105b, and the conductive layer 115b can be formed. As described above, the conductive layer 111b functions as the one of the source electrode and the drain electrode of the transistor 42 (and the other of the source electrode and the drain electrode of the transistor 41), the conductive layer 112b functions as the other of the source electrode and the drain electrode of the transistor 42, the insulating layer 105b functions as the gate insulating layer of the transistor 42, and the conductive layer 115b functions as the gate electrode of the transistor 42.

In the above manner, the semiconductor device 10 including the memory cells 21 in each of which the transistor 43, the transistor 41, and the transistor 42 illustrated in FIG. 4A to 4C are provided can be manufactured.

As described above, in the method for manufacturing the semiconductor device of one embodiment of the present invention, the transistor 43, the transistor 41, and the transistor 42 are formed to be stacked in this order. Thus, the area occupied by the memory cells in a plan view can be reduced. Accordingly, the memory cells can be reduced in size and highly integrated; hence, a memory device that can be reduced in size and increased in resolution can be provided. Each of the transistor 43, the transistor 41, and the transistor 42 in the semiconductor device of one embodiment of the present invention has a structure in which the source electrode and the drain electrode are provided at different heights from the substrate surface to overlap with each other and a drain current flows in the height direction (vertical direction). Thus, these transistors can be reduced in size as compared with a transistor having a structure in which a source electrode and a drain electrode are provided on the same plane. By including the transistor having the above-described structure, the memory device of one embodiment of the present invention can be further reduced in size and increased in resolution.

This embodiment can be combined with the other embodiments as appropriate. In this specification, in the case where a plurality of structure examples are shown in one embodiment, the structure examples can be combined as appropriate.

### EMBODIMENT 3

In this embodiment, a structure example of a semiconductor device in which a plurality of layers each including the memory cells 21 described in the above embodiment are stacked will be described with reference to drawings.

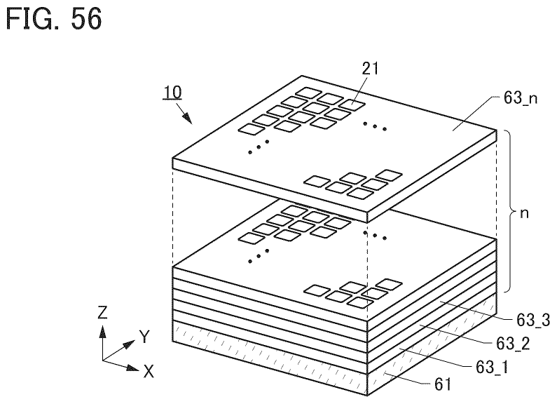

FIG. 56 is a perspective view illustrating a structure example of the semiconductor device 10. The semiconductor device 10 includes a driver circuit layer 61 and n (n is a integer of 1 or more) memory layers 63. The driver circuit layer 61 is provided with the word line driver circuit 11 and the bit line driver circuit 13 described in the above embodiment. In addition, the driver circuit layer 61 may be provided with the power supply circuit 15 described in the above embodiment. In each of the memory layers 63, the memory cells 21 are arranged in a matrix. In this embodiment, the n memory layers 63 are differentiated by being expressed as a memory layer 63_1 to a memory layer 63_n. In FIG. 56, the memory layer 63_1, the memory layer 63_2, the memory layer 63_3, and the memory layer 63_n are illustrated as the memory layers 63.

In the semiconductor device 10 illustrated in FIG. 56, the n memory layers 63 are provided over the driver circuit layer 61. Thus, the area occupied by the semiconductor device 10 can be reduced. Furthermore, the memory capacity per unit area can be increased.

FIG. 57 is a cross-sectional view illustrating a structure example of the memory layer 63_1 and the memory layer 63_2 illustrated in FIG. 56 and shows the XZ plane. As illustrated in FIG. 57, the memory layer 63_1 is provided over the insulating layer 101, and the memory layer 63_2 is provided over the memory layer 63_1. As described above, the memory cells 21 are provided in the memory layers 63. FIG. 57 illustrates a structure example of the memory cells 21 in two rows and two columns.

The memory cell 21 includes the transistor 43, the transistor 41, and the transistor 42. In this embodiment, for example, the transistor 43, the transistor 41, and the transistor 42 included in the memory layer 63_1 are referred to as a transistor 43_1, a transistor 41_1, and a transistor 42_1, respectively, and the transistor 43, the transistor 41, and the transistor 42 included in the memory layer 63_2 are referred to as a transistor 43_2, a transistor 41_2, and a transistor 42_2, respectively. The transistor 43_1, the transistor 41_1, and the transistor 42_1 form a memory cell 21_1 in the memory layer 63_1. The transistor 43_2, the transistor 41_2, and the transistor 42_2 form a memory cell 21_2 in the memory layer 63_2. As described above, the insulating layer 107b is provided over the transistor 42. In this embodiment, for example, the insulating layer 107b provided over the transistor 42_1 is referred to as an insulating layer 107b_1, and the insulating layer 107b provided over the transistor 42_2 is referred to as an insulating layer 107b_2.

Here, an insulating layer 139 functioning as an interlayer insulating layer is provided over the insulating layer 107b. In this embodiment, for example, the insulating layer 139 provided in the memory layer 63_1 is referred to as an insulating layer 139_1, and the insulating layer 139 provided in the memory layer 63_2 is referred to as an insulating layer 139_2. The transistor 43_2 is provided over the insulating layer 139_1, for example. For the insulating layer 139, a material similar to the material that can be used for the interlayer insulating layer described in the above embodiment can be used.

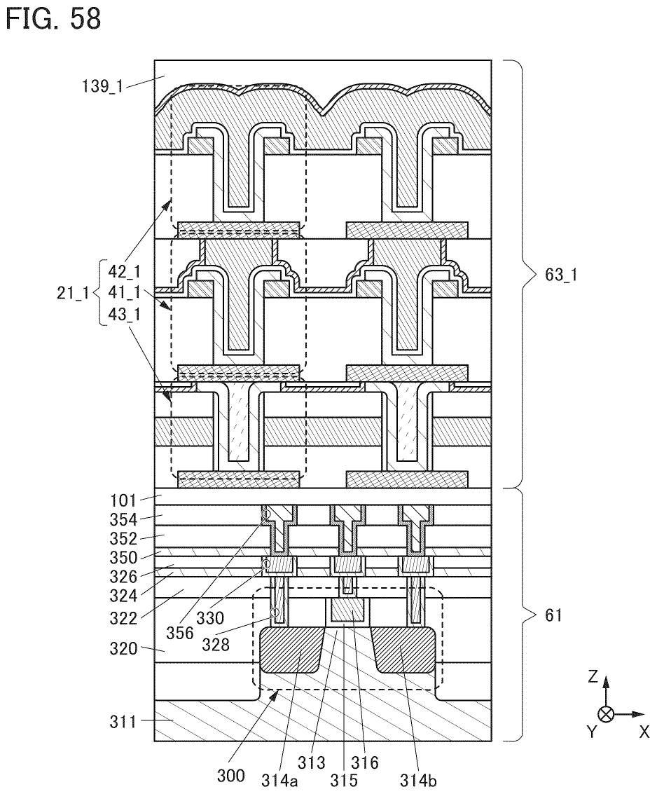

FIG. 58 is a cross-sectional view illustrating a structure example of the driver circuit layer 61 and the memory layer 63_1 over the driver circuit layer 61. FIG. 58 is a cross-sectional view obtained by eliminating the memory layer 63_2 from FIG. 57 and adding the driver circuit layer 61 thereto. In FIG. 58, a transistor 300 is illustrated as a transistor included in the driver circuit layer 61.

The transistor 300 is provided on a substrate 311 and includes a conductive layer 316 functioning as a gate electrode, an insulating layer 315 functioning as a gate insulating layer, a semiconductor region 313 including part of the substrate 311, and a low-resistance region 314a and a low-resistance region 314b functioning as a source region and a drain region. The transistor 300 may be a p-channel transistor or an n-channel transistor. As the substrate 311, a single crystal silicon substrate can be used, for example.

Here, in the transistor 300 illustrated in FIG. 58, the semiconductor region 313 (part of the substrate 311) in which a channel is formed has a protruding shape. The conductive layer 316 is provided to cover a side surface and the top surface of the semiconductor region 313 with the insulating layer 315 therebetween. Note that a material adjusting the work function may be used for the conductive layer 316. Such a transistor 300 is also referred to as a FIN-type transistor because it utilizes the projecting portion of the semiconductor substrate. Note that an insulator functioning as a mask for forming the protruding portion may be included in contact with an upper portion of the protruding portion. Although the case where the projecting portion is formed by processing part of the semiconductor substrate is described here, a semiconductor film having a projecting shape may be formed by processing an SOI substrate.

Note that the transistor 300 illustrated in FIG. 58 is an example and the structure is not limited thereto; an appropriate transistor can be used in accordance with a circuit structure or a driving method.

A wiring layer provided with an interlayer insulating layer, a wiring, a plug, and the like may be provided between components. A plurality of wiring layers can be provided in accordance with the design. Moreover, in this specification and the like, a wiring and a plug electrically connected to the wiring may be a single component. That is, in some cases, part of a conductor functions as a wiring or part of a conductor functions as a plug.

For example, an insulating layer 320, an insulating layer 322, an insulating layer 324, and an insulating layer 326 are sequentially stacked over the transistor 300 as interlayer insulating layers. In addition, for example, a conductive layer 328 is embedded in the insulating layer 320 and the insulating layer 322. Furthermore, for example, a conductive layer 330 is embedded in the insulating layer 324 and the insulating layer 326. Note that the conductive layer 328 and the conductive layer 330 function as contact plugs or wirings.

The insulating layers functioning as interlayer insulating layers may also function as planarization films that cover uneven shapes therebelow. For example, the top surface of the insulating layer 322 may be planarized through planarization treatment using a CMP method or the like to increase the planarity.

A wiring layer may be provided over the insulating layer 326 and the conductive layer 330. For example, in FIG. 58, an insulating layer 350, an insulating layer 352, and an insulating layer 354 are stacked sequentially over the insulating layer 326 and the conductive layer 330. A conductive layer 356 is provided in the insulating layer 350, the insulating layer 352, and the insulating layer 354. The conductive layer 356 functions as a contact plug or a wiring.

This embodiment can be combined with the other embodiments as appropriate. In this specification, in the case where a plurality of structure examples are shown in one embodiment, the structure examples can be combined as appropriate.

### EMBODIMENT 4

In this embodiment, application examples of the semiconductor device of one embodiment of the present invention will be described with reference to drawings. The semiconductor device of one embodiment of the present invention can be used for an electronic component, an electronic appliance, a large computer, space equipment, and a data center (also referred to as DC), for example. An electronic component, an electronic appliance, a large computer, space equipment, and a data center each using the semiconductor device of one embodiment of the present invention are effective in achieving high performance, e.g., reducing power consumption.

### [Electronic Component]

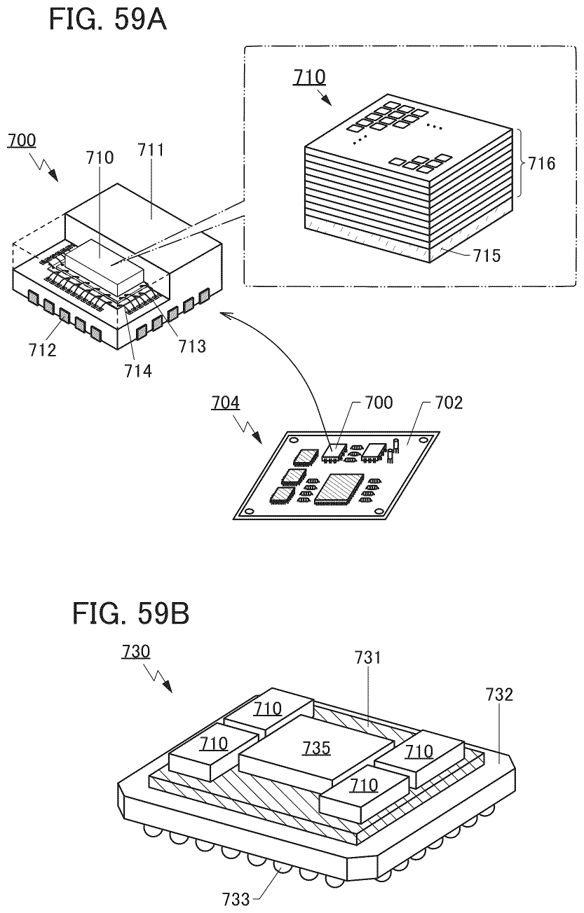

FIG. 59A is a perspective view of a substrate (a mounting board 704) on which an electronic component 700 is mounted. The electronic component 700 illustrated in FIG. 59A includes a semiconductor device 710 in a mold 711. Some components are omitted in FIG. 59A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the mounting board 704.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the size of a connection wiring, for example, can be smaller than that in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a disc-like substrate (also referred to as a wafer) into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 59B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for obtaining a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

An electrode 733 may be provided on the bottom portion of the package substrate 732 to mount the electronic component 730 on another substrate. FIG. 59B illustrates an example where the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods other than BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Appliance]

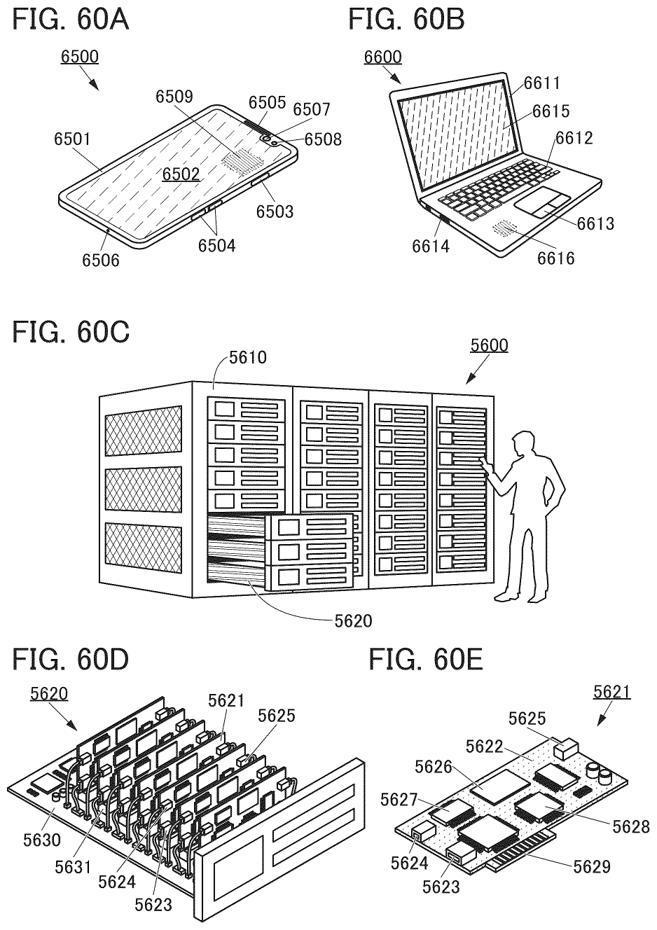

FIG. 60A is a perspective view of an electronic appliance 6500. The electronic appliance 6500 illustrated in FIG. 60A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like.

An electronic appliance 6600 illustrated in FIG. 60B is an information terminal that can be used as a notebook personal computer. The electronic appliance 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### [Large Computer]

FIG. 60C is a perspective view of a large computer 5600. In the large computer 5600 illustrated in FIG. 60C, a plurality of rack mount computers 5620 are stored in a rack 5610. Note that the large computer 5600 may be referred to as a supercomputer.

The computer 5620 can have a structure in a perspective view of FIG. 60D, for example. In FIG. 60D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 60E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 60E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply and signal input to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of the thermosphere, mesosphere, and stratosphere.

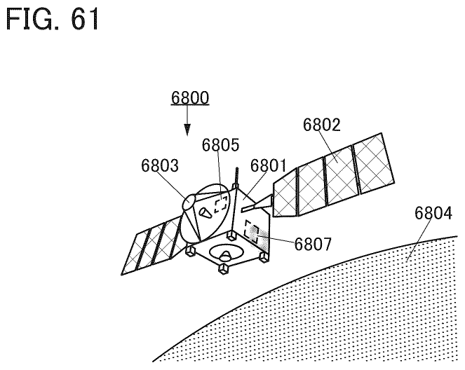

FIG. 61 illustrates an artificial satellite 6800 as an example of space equipment. The artificial satellite 6800 includes a body 6801, a solar panel 6802, an antenna 6803, a secondary battery 6805, and a control device 6807. Note that FIG. 61 illustrates a planet 6804 in outer space, for example.

Although not illustrated in FIG. 61, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited to this example. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device of one embodiment of the present invention for the storage system used in the data center, electric power required for data retention can be reduced and a semiconductor device that retains data can be downsized. Accordingly, downsizing of the storage system, downsizing of a power source for data retention, downscaling of cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

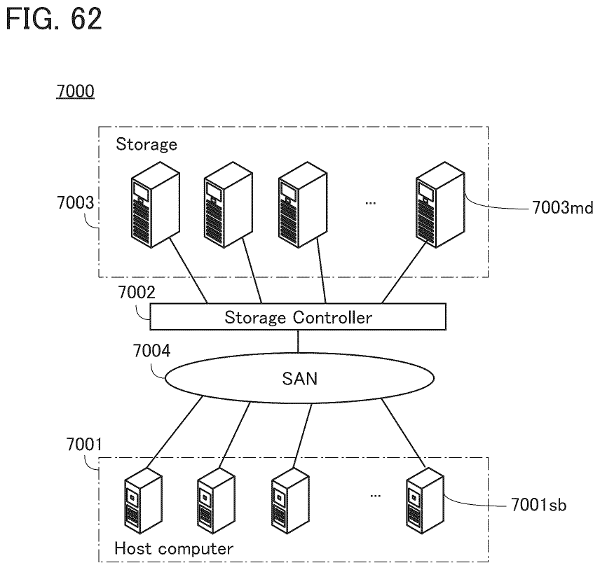

FIG. 62 illustrates a storage system that can be used in a data center. A storage system 7000 illustrated in FIG. 62 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for data storage and output, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on the data, the frequency of refreshing can be decreased, so that power consumption can be reduced. Furthermore, downsizing is possible by stacking memory cell arrays.

The use of the semiconductor device of one embodiment of the present invention for one or more selected from an electronic component, an electronic appliance, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO2) can be reduced with the use of the semiconductor device of one embodiment of the present invention. The semiconductor device of one embodiment of the present invention can be effectively used as one of the global warming countermeasures because of its low power consumption.

This embodiment can be combined with the other embodiments as appropriate.

### REFERENCE NUMERALS

10: semiconductor device, 11: word line driver circuit, 13: bit line driver circuit, 15: power supply circuit, 20: memory portion, 21_1: memory cell, 21_2: memory cell, 21: memory cell, 31R: wiring, 31W: wiring, 31a: wiring, 31b: wiring, 31c: wiring, 31: wiring, 33R: wiring, 33W: wiring, 33: wiring, 35: wiring, 36: wiring, 37: wiring, 38: wiring, 41_1: transistor, 41_2: transistor, 41: transistor, 42_1: transistor, 42_2: transistor, 42: transistor, 43_1: transistor, 43_2: transistor, 43: transistor, 44: transistor, 51: capacitor, 53: transistor, 58: capacitor, 61: driver circuit layer, 63_1: memory layer, 63_2: memory layer, 63_3: memory layer, 63_n: memory layer, 63: memory layer, 70: display device, 71: scan line driver circuit, 73: signal line driver circuit, 75: power supply circuit, 77: reference potential generator circuit, 80: display portion, 81: pixel, 83B: subpixel, 83G: subpixel, 83R: subpixel, 83: subpixel, 90: pixel circuit, 91: light-emitting element, 101: insulating layer, 103a: insulating layer, 103b: insulating layer, 103c: insulating layer, 103c_1: insulating layer, 103c_2: insulating layer, 103c_3: insulating layer, 103c_4: insulating layer, 103C: insulating film, 103: insulating layer, 105a: insulating layer, 105b: insulating layer, 105c: insulating layer, 105C: insulating film, 105: insulating layer, 107a: insulating layer, 107A: insulating film, 107b_1: insulating layer, 107b_2: insulating layer, 107b: insulating layer, 107c: insulating layer, 107C: insulating film, 107: insulating layer, 111a: conductive layer, 111b: conductive layer, 111c: conductive layer, 111: conductive layer, 112a: conductive layer, 112A: conductive film, 112b: conductive layer, 112B: conductive film, 112c: conductive layer, 112: conductive layer, 113a: semiconductor layer, 113b: semiconductor layer, 113c: semiconductor layer, 113C: metal oxide film, 113i: region, 113na: region, 113nb: region, 113: semiconductor layer, 114f: film, 114: layer, 115a: conductive layer, 115A: conductive film, 115b: conductive layer, 115B: conductive film, 115c: conductive layer, 115: conductive layer, 118: conductive layer, 120: opening, 121a: opening, 121b: opening, 121c: opening, 121: opening, 122: opening, 123: opening, 125: opening, 126: opening, 131: insulating layer, 132: insulating layer, 133: insulating layer, 135: insulating layer, 137: insulating layer, 139_1: insulating layer, 139_2: insulating layer, 139: insulating layer, 141: conductive layer, 143: conductive layer, 300: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 700: electronic component, 702: printed circuit board, 704: mounting board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
a first transistor; a second transistor; a third transistor; a first wiring; a second wiring; a third wiring; a fourth wiring; and a fifth wiring,
wherein in each of the first transistor, the second transistor, and the third transistor, a source and a drain are at different heights from a substrate surface,
wherein the first transistor is over the second transistor to overlap with the second transistor,
wherein the second transistor is over the third transistor to overlap with the third transistor,
wherein a gate of the first transistor is electrically connected to the first wiring,
wherein one of the source and the drain of the first transistor is electrically connected to a gate of the second transistor,
wherein the other of the source and the drain of the first transistor is electrically connected to the second wiring,
wherein one of the source and the drain of the second transistor is electrically connected to one of the source and the drain of the third transistor,
wherein the other of the source and the drain of the second transistor is electrically connected to the third wiring,
wherein a gate of the third transistor is electrically connected to the fourth wiring, and
wherein the other of the source and the drain of the third transistor is electrically connected to the fifth wiring.

2. The semiconductor device according to claim 1,
wherein at least one of the first transistor, the second transistor, and the third transistor comprises a metal oxide.

3. The semiconductor device according to claim 1, further comprising:
a node electrically connecting the one of the source and the drain of the first transistor and the gate of the second transistor,
wherein the first transistor is configured to write, to the node, data corresponding to a potential supplied from the second wiring when a first potential is supplied from the first wiring, and is configured to retain the data at the node when a second potential is supplied from the first wiring,
wherein the second transistor and the third transistor are each configured to read the data retained at the node when a fifth potential is supplied to the fourth wiring while a third potential is supplied to the third wiring and a fourth potential is supplied to the fifth wiring,
wherein the first potential is a potential at which the first transistor is turned on,
wherein the second potential is a potential at which the first transistor is turned off,
wherein the fourth potential is higher than the third potential, and
wherein the fifth potential is a potential at which the third transistor is turned on.

4-6. (canceled)

7. A semiconductor device comprising:
a first transistor; a second transistor; a third transistor; a first insulating layer; a second insulating layer; a third insulating layer; and a fourth insulating layer,
wherein the first transistor, the second transistor, and the third transistor are stacked in this order,
wherein the first transistor comprises a first conductive layer, a second conductive layer, a third conductive layer, a fifth insulating layer, and a first semiconductor layer,
wherein the first insulating layer, the third conductive layer, and the second insulating layer are stacked in this order over the first conductive layer,
wherein a first opening reaching the first conductive layer is in the first insulating layer, the third conductive layer, and the second insulating layer, wherein the fifth insulating layer is in contact with a sidewall of the first opening,
wherein the first semiconductor layer is in contact with a top surface of the first conductive layer in the first opening, a side surface of the fifth insulating layer in the first opening, and a top surface of the second insulating layer,
wherein the second conductive layer is in contact with a top surface of the first semiconductor layer to comprise a region overlapping with the first conductive layer,
wherein the second transistor comprises the second conductive layer, a fourth conductive layer, a fifth conductive layer, a sixth insulating layer, and a second semiconductor layer,
wherein the third insulating layer and the fourth conductive layer are stacked in this order over the second conductive layer,
wherein a second opening reaching the second conductive layer is in the third insulating layer and the fourth conductive layer,
wherein the second semiconductor layer is in contact with a top surface of the second conductive layer in the second opening, a side surface of the third insulating layer in the second opening, a first side surface of the fourth conductive layer in the second opening, and a first top surface of the fourth conductive layer,
wherein the sixth insulating layer is in contact with a top surface and a side surface of the second semiconductor layer, a second top surface of the fourth conductive layer, a second side surface of the fourth conductive layer, and a top surface of the third insulating layer,
wherein the fifth conductive layer is over and in contact with the sixth insulating layer to fill the second opening,
wherein the third transistor comprises a sixth conductive layer, a seventh conductive layer, an eighth conductive layer, a seventh insulating layer, and a third semiconductor layer,
wherein the sixth conductive layer is in contact with a top surface of the fifth conductive layer,
wherein the fourth insulating layer and the seventh conductive layer are stacked in this order over the sixth conductive layer,
wherein a third opening reaching the sixth conductive layer is in the fourth insulating layer and the seventh conductive layer,
wherein the third semiconductor layer is in contact with a top surface of the sixth conductive layer in the third opening, a side surface of the fourth insulating layer in the third opening, a first side surface of the seventh conductive layer in the third opening, and a first top surface of the seventh conductive layer,
wherein the seventh insulating layer is in contact with a top surface of the third semiconductor layer, a side surface of the third semiconductor layer, a second top surface of the seventh conductive layer, a second side surface of the seventh conductive layer, and a top surface of the fourth insulating layer, and
wherein the eighth conductive layer is over and in contact with the seventh insulating layer to fill the third opening.

8. The semiconductor device according to claim 7,
wherein at least one of the first semiconductor layer, the second semiconductor layer, and the third semiconductor layer comprises a metal oxide.

9. The semiconductor device according to claim 7,
wherein the second conductive layer comprises a ninth conductive layer and a tenth conductive layer,
wherein the ninth conductive layer is in contact with the top surface of the first semiconductor layer to comprise a region overlapping with the first conductive layer,
wherein the tenth conductive layer is in contact with a top surface of the ninth conductive layer to comprise a region overlapping with the first conductive layer, and
wherein the second semiconductor layer is in contact with a top surface of the tenth conductive layer.

10. The semiconductor device according to claim 7,
wherein the second conductive layer comprises a ninth conductive layer, a tenth conductive layer, and an eleventh conductive layer,
wherein the ninth conductive layer is in contact with the top surface of the first semiconductor layer to comprise a region overlapping with the first conductive layer,
wherein the tenth conductive layer is in contact with a top surface of the ninth conductive layer,
wherein the eleventh conductive layer is in contact with a top surface of the tenth conductive layer to comprise a region overlapping with the first conductive layer, and
wherein the second semiconductor layer is in contact with a top surface of the eleventh conductive layer.

11. The semiconductor device according to claim 7, further comprising:
a capacitor between the second transistor and the third transistor,
wherein the first transistor, the second transistor, the capacitor, and the third transistor are stacked in this order,
wherein the capacitor comprises a ninth conductive layer, a tenth conductive layer, and an eighth insulating layer,
wherein the eighth insulating layer comprises a region in contact with a side surface of the ninth conductive layer,
wherein the tenth conductive layer surrounds at least part of the side surface of the ninth conductive layer with the eighth insulating layer therebetween,
wherein the ninth conductive layer is in contact with the top surface of the fifth conductive layer, and
wherein the sixth conductive layer is in contact with a top surface of the ninth conductive layer.

12. A semiconductor device comprising:
a first transistor; a second transistor; a third transistor; a first insulating layer; a second insulating layer; a third insulating layer; and a fourth insulating layer,
wherein the first transistor, the second transistor, and the third transistor are stacked in this order,
wherein the first transistor comprises a first conductive layer, a second conductive layer, a third conductive layer, a fifth insulating layer, and a first semiconductor layer,
wherein the first insulating layer, the third conductive layer, and the second insulating layer are stacked in this order over the first conductive layer,
wherein a first opening reaching the first conductive layer is in the first insulating layer, the third conductive layer, and the second insulating layer,
wherein the fifth insulating layer is in contact with a sidewall of the first opening,
wherein the first semiconductor layer is in contact with a top surface of the first conductive layer in the first opening, a side surface of the fifth insulating layer in the first opening, and a top surface of the second insulating layer,
wherein the second conductive layer is in contact with a top surface of the first semiconductor layer to comprise a region overlapping with the first conductive layer,
wherein the third conductive layer surrounds the first semiconductor layer with the fifth insulating layer therebetween in a plan view,
wherein the second transistor comprises the second conductive layer, a fourth conductive layer, a fifth conductive layer, a sixth insulating layer, and a second semiconductor layer,
wherein the third insulating layer and the fourth conductive layer are stacked in this order over the second conductive layer,
wherein a second opening reaching the second conductive layer is in the third insulating layer and the fourth conductive layer,
wherein the second semiconductor layer is in contact with a top surface of the second conductive layer in the second opening, a side surface of the third insulating layer in the second opening, a first side surface of the fourth conductive layer in the second opening, and a first top surface of the fourth conductive layer and surrounds the fifth conductive layer with the sixth insulating layer therebetween in the plan view,
wherein the sixth insulating layer is in contact with a top surface of the second semiconductor layer, a side surface of the second semiconductor layer, a second top surface of the fourth conductive layer, a second side surface of the fourth conductive layer, and a top surface of the third insulating layer,
wherein the fifth conductive layer is over and in contact with the sixth insulating layer to fill the second opening,
wherein the third transistor comprises a sixth conductive layer, a seventh conductive layer, an eighth conductive layer, a seventh insulating layer, and a third semiconductor layer,
wherein the sixth conductive layer is in contact with a top surface of the fifth conductive layer,
wherein the fourth insulating layer and the seventh conductive layer are stacked in this order over the sixth conductive layer,
wherein a third opening reaching the sixth conductive layer is in the fourth insulating layer and the seventh conductive layer,
wherein the third semiconductor layer is in contact with a top surface of the sixth conductive layer in the third opening, a side surface of the fourth insulating layer in the third opening, a first side surface of the seventh conductive layer in the third opening, and a first top surface of the seventh conductive layer and surrounds the eighth conductive layer with the seventh insulating layer therebetween in the plan view,
wherein the seventh insulating layer is provided in contact with a top surface of the third semiconductor layer, a side surface of the third semiconductor layer, a second top surface of the seventh conductive layer, a second side surface of the seventh conductive layer, and a top surface of the fourth insulating layer, and
wherein the eighth conductive layer is over and in contact with the seventh insulating layer to fill the third opening.

13. The semiconductor device according to claim 12,
wherein at least one of the first semiconductor layer, the second semiconductor layer, and the third semiconductor layer comprises a metal oxide.

14. The semiconductor device according to claim 12,
wherein the second conductive layer comprises a ninth conductive layer and a tenth conductive layer,
wherein the ninth conductive layer is in contact with the top surface of the first semiconductor layer to comprise a region overlapping with the first conductive layer,
wherein the tenth conductive layer is in contact with a top surface of the ninth conductive layer to comprise a region overlapping with the first conductive layer, and
wherein the second semiconductor layer is in contact with a top surface of the tenth conductive layer.

15. The semiconductor device according to claim 12,
wherein the second conductive layer comprises a ninth conductive layer, a tenth conductive layer, and an eleventh conductive layer,
wherein the ninth conductive layer is in contact with the top surface of the first semiconductor layer to comprise a region overlapping with the first conductive layer,
wherein the tenth conductive layer is in contact with a top surface of the ninth conductive layer,
wherein the eleventh conductive layer is provided in contact with a top surface of the tenth conductive layer to comprise a region overlapping with the first conductive layer, and
wherein the second semiconductor layer is in contact with a top surface of the eleventh conductive layer.

16. The semiconductor device according to claim 12, further comprising:
a capacitor between the second transistor and the third transistor, wherein the first transistor, the second transistor, the capacitor, and the third transistor are stacked in this order,
wherein the capacitor comprises a ninth conductive layer, a tenth conductive layer, and an eighth insulating layer,
wherein the eighth insulating layer comprises a region in contact with a side surface of the ninth conductive layer,
wherein the tenth conductive layer surrounds at least part of the side surface of the ninth conductive layer with the eighth insulating layer therebetween,
wherein the ninth conductive layer is in contact with the top surface of the fifth conductive layer, and
wherein the sixth conductive layer is in contact with a top surface of the ninth conductive layer.

17. (canceled)
